(19) United States
(12) Patent Application Publication
(10) Pub. No.: US 2013/0073930 A1
(43) Pub. Date: Mar. 21, 2013

(54) PARITY PREDICTOR, CARRY-LESS MULTIPLIER AND ARITHMETIC OPERATION PROCESSING APPARATUS

(71) Applicants: Kazushige Yazaki, Nishitokyo (JP); Kenichi Kitamura, Kawasaki (JP)

(72) Inventors: Kazushige Yazaki, Nishitokyo (JP); Kenichi Kitamura, Kawasaki (JP)

(73) Assignee: FUJITSU LIMITED, Kawasaki-shi (JP)

(21) Appl. No.: 13/598,908

(22) Filed: Aug. 30, 2012

(30) Foreign Application Priority Data
Sep. 20, 2011 (JP) 2011-205302

(51) Int. Cl. H03M 13/09; G06F 11/10

(52) U.S. Cl. 714/803; 714/E11.032

(57) ABSTRACT

A predictor configured to predict a parity value of a Carry-Less multiplication result of a multiplicand data string and a multiplier data string being two data strings in which q (q is a natural number) data units being p-bit (p is a natural number equal to two or above) data, includes a unit configured to predict a parity value of a first data unit from lower order in a result data string representing the multiplication result based on a value and a parity value of a first data unit from lower order in each of the two data strings; and a unit configured to predict a parity value for data at a high-order p−1 bit of the result data string based on a value and a parity value for a q-th data unit from lower order in each of the two data strings.

### CROSS-REFERENCE TO RELATED APPLICATION

This application is based upon and claims the benefit of priority of the prior Japanese Patent Application No. 2011-205302, filed on Sep. 20, 2011, the entire contents of which are incorporated herein by reference.

### FIELD

The embodiments discussed herein are related to a parity predictor, a Carry-Less multiplier and an arithmetic operation processing apparatus.

### BACKGROUND

The Carry-Less multiplier that performs Carry-Less multiplication used in CRC (Cyclic Redundancy Check) and the like to detect an error in a data stream has been known. First, the Carry-Less multiplication is explained.

In the normal multiplication to multiply multiplicand data by multiplier data, first, the multiplier data is broken down into every bit, and the partial product of the multiplicand data and the partial multiplier data of each bit is obtained. Then, with respect to the obtained partial product, digit alignment according to the position of the bit of the partial multiplier data used to calculate the partial product is performed. Then, the partial products of the same digits are added to each other to obtain the multiplication result. By contrast, in the Carry-Less multiplication, instead of the addition, the multiplication result is obtained by calculating the XOR of the partial products of the same digits.

The Carry-Less multiplication is further explained.

Meanwhile, in the explanation below, the logical AND (AND operation) of value a and value b is represented as “a*b”, the XOR (XOR operation) of value a and value b is represented as “a+b”, and the logical sum (OR operation) of value a and value b is represented as “âb”.

FIG. 1 presents the Carry-Less multiplication of the multiplicand A and multiplier Y that are both 4-bit data. Meanwhile, in FIG. 1, “a b c d” represents the respective bit of the multiplicand A, and “y3 y2 y1 y0” represent the respective bit of the multiplier Y.

In FIG. 1, the line “a*y0 b*y0 c*y0 d*y0” represents the logical AND of the respective bits a, b, c and d of the multiplicand A and the first bit y0 from the lower order in the multiplier Y, that is, the partial product of the multiplicand A and the multiplier Y. In addition, the other lines are in a similar way. Each of these lines represents the middle result of the arithmetic operation in the Carry-Less multiplication.

Furthermore, Z represents the multiplication result of the Carry-Less multiplication of the multiplicand A and the multiplier Y, and “z6 z5 z4 z3 z2 z1 z0” represents the respective bit of the multiplication result Z. Meanwhile, in the Carry-Less multiplication, the bit z7 being the upper digit of the bit z6 is always “0”.

In the Carry-Less multiplication, the respective bit of the multiplication result Z is calculated according to formula [1] below.

z0=d*y0

z1=c*yo+d*y1

z2=b*y0+c*y1+d*y2

z3=a*y0+b*y1+c*y2+d*y3

z4=a*y1+b*y2+c*y3

z5=a*y2+b*y3

z6=a*y3 [1]

Meanwhile, as another background art, a technique to detect an error in an operation result due to a soft error that occurs in an operation circuit with radiation such as alpha ray and the like entering the operation circuit. In this technique, first, a register holds a first numerical value in the gray code format. Next, numerical operation means obtains and outputs, from the first numerical value held in the register, a second numerical value being the result of a prescribed numerical operation with respect to the first numerical value in the gray code format. Next, parity operation means generates a second parity value being the parity value with respect to the second value, using a first parity value being the parity value with respect to the first numerical value held in the register to perform a prescribed logical operation corresponding to the numerical operation. Then, parity check means performs parity check with respect to the second numerical value output from the numerical operation means, using the second parity value generated by the parity operation means.

Meanwhile, techniques described in the following documents have been known.
Document 1: U.S. Pat. No. 7,590,930
Document 2: U.S. Pat. No. 7,707,483
Document 3: Japanese Laid-open Patent Publication No. 2010-205135

Incidentally, in recent years, there has been an increasing possibility of malfunction of an arithmetic operation unit due to a soft error and the like with semiconductor miniaturization, raising a need for a mechanism such as parity check and circuit redundancy for ensuring reliability. However, the conventional Carry-Less multiplier is not equipped with a mechanism such as parity check and circuit redundancy, and for this reason, it is impossible to detect the malfunction of the multiplier.

### SUMMARY

According to an aspect of the embodiments, a parity predictor configured to predict a parity value of a Carry-Less multiplication result of a multiplicand data string and a multiplier data string being two data strings in which q (q is a natural number) data units being p-bit (p is a natural number equal to two or above) data, the parity predictor includes a low-order parity prediction unit configured to predict a parity value of a first data unit from lower order in a multiplication result data string representing the Carry-Less multiplication result based on a value and a parity value of a first data unit being a first data unit from lower order in each of the multiplicand data string and the multiplier data string; and a high-order parity prediction unit configured to predict a parity value for data at a high-order p−1 bit of the multiplication result data string being data following 2q−1-th data unit from lower order in the multiplication result data string, based on a value and a parity value for a q-th data unit being a q-th data unit from lower order in each of the multiplicand data string and the multiplier data string.

The object and advantages of the embodiment will be realized and attained by means of the elements and combinations particularly pointed out in the claims.

It is to be understood that both the foregoing general description and the following detailed description are exemplary and explanatory and are not restrictive of the embodiment, as claimed.

### BRIEF DESCRIPTION OF DRAWINGS

FIG. 1 is an explanation diagram of Carry-Less multiplication.

FIG. 2 is a diagram presenting a configuration diagram of an example of a parity predictor.

FIG. 3 is an explanation diagram (part 1) of parity prediction for each data unit of a multiplication result data string.

FIG. 4 is an explanation diagram (part 2) of parity prediction for each data unit of a multiplication result data string.

FIG. 5 is an explanation diagram (part 3) of parity prediction for each data unit of a multiplication result data string.

FIG. 6 is an explanation diagram (part 4) of parity prediction for each data unit of a multiplication result data string.

FIG. 7 is an explanation diagram (part 5) of parity prediction for each data unit of a multiplication result data string.

FIG. 8 is a configuration diagram of an example of an arithmetic operation processing apparatus.

FIG. 9 is a configuration diagram of a first example of a Carry-Less multiplier.

FIG. 10A is a configuration diagram (part 1) of a Carry-Less multiplication circuit in FIG. 9.

FIG. 10B is a configuration diagram (part 2) of a Carry-Less multiplication circuit in FIG. 9.

FIG. 10C is a configuration diagram (part 3) of a Carry-Less multiplication circuit in FIG. 9.

FIG. 10D is a configuration diagram (part 4) of a Carry-Less multiplication circuit in FIG. 9.

FIG. 10E is a configuration diagram (part 5) of a Carry-Less multiplication circuit in FIG. 9.

FIG. 10F is a configuration diagram (part 6) of a Carry-Less multiplication circuit in FIG. 6.

FIG. 10G is a configuration diagram (part 7) of a Carry-Less multiplication circuit in FIG. 9.

FIG. 11A is a configuration diagram of a first example of a Carry-Less multiplication parity prediction in FIG. 9.

FIG. 11B is a configuration diagram of a second example of a Carry-Less multiplication parity prediction in FIG. 9.

FIG. 12A is a configuration diagram of a first example of a parity check circuit in FIG. 9.

FIG. 12B is a configuration diagram of a second example of a parity check circuit in FIG. 9.

FIG. 13 is a configuration diagram of a second example of a Carry-Less multiplier.

FIG. 14A is a configuration diagram (part 1) of a first example of a Carry-Less multiplication parity prediction circuit in FIG. 13.

FIG. 14B is a configuration diagram (part 2) of a first example of a Carry-Less multiplication parity prediction circuit in FIG. 13.

FIG. 14C is a configuration diagram (part 1) of a second example of a Carry-Less multiplication parity prediction circuit in FIG. 13.

FIG. 14D is a configuration diagram (part 2) of a second example of a Carry-Less multiplication parity prediction circuit in FIG. 13.

FIG. 15A is a configuration diagram of a first example of a parity check circuit in FIG. 13.

FIG. 15B is a configuration diagram of a second example of a parity check circuit in FIG. 13.

FIG. 16 is a configuration diagram of a third example of a Carry-Less multiplier.

FIG. 17A is a configuration diagram (part 1) of a first example of a Carry-Less multiplication parity prediction circuit in FIG. 16.

FIG. 17B is a configuration diagram (part 2) of a first example of a Carry-Less multiplication parity prediction circuit in FIG. 16.

FIG. 17C is a configuration diagram (part 3) of a first example of a Carry-Less multiplication parity prediction circuit in FIG. 16.

FIG. 17D is a configuration diagram (part 4) of a first example of a Carry-Less multiplication parity prediction circuit in FIG. 16.

FIG. 17E is a configuration diagram (part 5) of a first example of a Carry-Less multiplication parity prediction circuit in FIG. 16.

FIG. 17F is a configuration diagram (part 6) of a first example of a Carry-Less multiplication parity prediction circuit in FIG. 16.

FIG. 17G is a configuration diagram (part 7) of a first example of a Carry-Less multiplication parity prediction circuit in FIG. 16.

FIG. 17H is a configuration diagram (part 8) of a first example of a Carry-Less multiplication parity prediction circuit in FIG. 16.

FIG. 17I is a configuration diagram (part 1) of a second example of a Carry-Less multiplication parity prediction circuit in FIG. 16.

FIG. 17J is a configuration diagram (part 2) of a second example of a Carry-Less multiplication parity prediction circuit in FIG. 16.

FIG. 17K is a configuration diagram (part 3) of a second example of a Carry-Less multiplication parity prediction circuit in FIG. 16.

FIG. 17L is a configuration diagram (part 4) of a second example of a Carry-Less multiplication parity prediction circuit in FIG. 16.

FIG. 17M is a configuration diagram (part 5) of a second example of a Carry-Less multiplication parity prediction circuit in FIG. 16.

FIG. 17N is a configuration diagram (part 6) of a second example of a Carry-Less multiplication parity prediction circuit in FIG. 16.

FIG. 17O is a configuration diagram (part 7) of a second example of a Carry-Less multiplication parity prediction circuit in FIG. 16.

FIG. 17P is a configuration diagram (part 8) of a second example of a Carry-Less multiplication parity prediction circuit in FIG. 16.

FIG. 18 is a configuration diagram of a fourth example of a Carry-Less multiplier.

FIG. 19 is a configuration diagram of a Carry-Less multiplication parity prediction circuit in FIG. 18.

FIG. 20A is a configuration diagram of a first example of a low-order parity prediction circuit in FIG. 19.

FIG. 20B is a configuration diagram of a second example of a low-order parity prediction circuit in FIG. 19.

FIG. 21A is a configuration diagram of a first example of a high-order parity prediction circuit in FIG. 19.

FIG. 21B is a configuration diagram of a second example of a high-order parity prediction circuit in FIG. 19.

FIG. 22 is a configuration diagram of a partial multiplication result parity prediction circuit.

FIG. 23A is a configuration diagram of a first example of a first partial parity prediction circuit in FIG. 22.

FIG. 23B is a configuration diagram of a second example of a first partial parity prediction circuit in FIG. 22.

FIG. 24A is a configuration diagram of a first example of a q+1-th partial parity prediction circuit in FIG. 22.

FIG. 24B is a configuration diagram of a second example of a q+1-th partial parity prediction circuit in FIG. 22.

FIG. 25A is a configuration diagram of a first example of a k-th partial parity prediction circuit.

FIG. 25B is a configuration diagram of a second example of a k-th partial parity prediction circuit.

FIG. 26A is a configuration diagram of a first example of an s-th middle-order parity prediction circuit.

FIG. 26B is a configuration diagram of a first example of a t-th middle-order parity prediction circuit.

FIG. 26C is a configuration diagram of a second example of an s-th middle-order parity prediction circuit.

FIG. 26D is a configuration diagram of a second example of a t-th middle-order parity prediction circuit.

### DESCRIPTION OF EMBODIMENTS

Preferred embodiments of the present invention will be explained with reference to accompanying drawings.

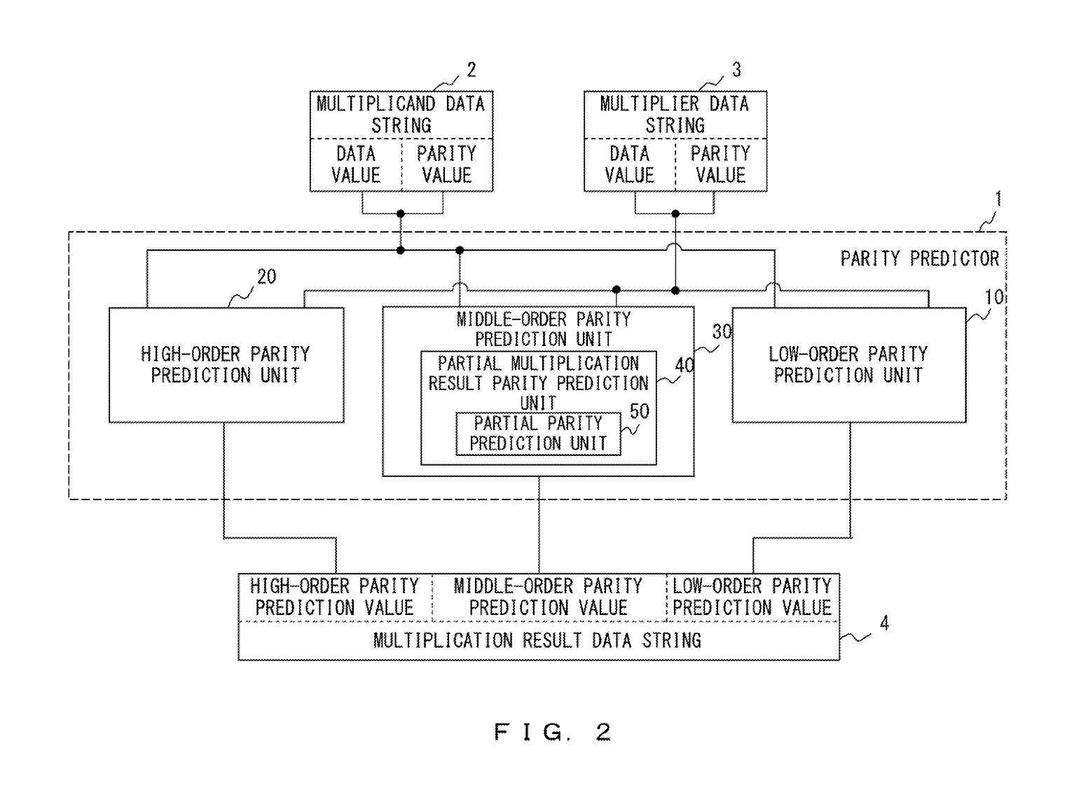

First, FIG. 2 is explained. FIG. 2 is a configuration diagram of an example of a parity predictor.

The parity predictor 1 predicts the parity value of multiplication result data string 4 output from a multiplication circuit that performs Carry-Less multiplication of a multiplicand data string 2 and a multiplier data string 3. When performing a malfunction detection of a Carry-Less multiplier, the parity value of the multiplication result data string 4 that is output when the multiplicand data string 2 and the multiplier data string 3 are input to the Carry-Less multiplier being the target of detection is compared with the prediction result of the parity value by the parity predictor 1. By the comparison of the parity value and the prediction result of the parity value, when a mismatch of them is detected, it is determined that a malfunction has occurred in the Carry-Less multiplier being the detection target.

Meanwhile, in the present embodiment, the multiplicand data string 2 and the multiplier data string 3 are both a data string in which q (here, q is a natural number) data units are lined up.

However, in the explanation below, the number of data units of a multiplicand data string and the number of a multiplier data string are the same q just for the convenience of explanation, and they may be different.

Meanwhile, in this specification, a “data unit” is a p-bit data configured by lining up p (here, p is a natural number equal to or larger than 2) 1-bit data.

In addition, in the explanation below, also for the convenience of explanation, the number of bits of the data unit about the multiplication result data string is q bits being the same as the number of bits of the data unit of the multiplicand data string and the multiplier data string, but the number of bits of the data string about the multiplication result data string may be an integral multiple of p bits. The value of the parity of the part being an integral multiple of p bits, either the value calculated from the multiplication result data string or a the value of the predicted value, may be calculated using the value of the parity of the respective p bit of each.

The parity predictor 1 has a low-order parity prediction unit 10 and a high-order parity prediction unit 20.

The low-order parity prediction unit 10 predicts the parity value of the first data unit from the lower order in the multiplication result data string 4. The low-order parity prediction unit 10 predicts the parity value (low-order parity predicted value) based on the value of the first data unit being the first data unit from the lower order and the parity value in each of the multiplicand data string 2 and the multiplier data string 3.

The high-order parity prediction unit 20 predicts the parity value if the data following the 2q−1-th data unit from the lower order in the multiplication result data string 4, that is, the parity value of the high-order p−1th bit data of the multiplication result data string 4. The high-order parity prediction unit 20 predicts the parity value (high-order parity predicted value) of the p−1-th bit data based on the value of the q-th data unit being the q-th data unit from the lower order and the parity value in the multiplicand data string 2 and the multiplier data string 3.

In addition, the parity predictor 1 further has a middle-order parity prediction unit 30. The middle-order parity prediction unit 30 predicts the parity value of each data unit from the second to 2q−1-th from the lower order in the multiplication result data string 4, when the multiplicand data string 2 and the multiplier data string 3 are a data string in which the plurality of data units described above are lined up. The middle-order parity prediction unit 30 predicts the parity value (middle-order parity predicted value) based on the value and the parity value about each data unit from the first (first data unit) to the q-th (q-th data unit) from the lower order in the multiplicand data string 2 and the multiplier data string 3.

In this embodiment, the middle-order parity prediction unit 30 has a partial multiplication result parity prediction unit 40. The partial multiplication result parity prediction unit 40 predicts the parity value of each data unit for the partial multiplication result data string being the result of the Carry-Less multiplication of the multiplicand data string 2 and a partial multiplier data being one of data units constituting the multiplier data string 3. The middle-order parity prediction unit 30 performs the prediction of the middle-order parity predicted value based on the prediction result be the partial multiplication result parity prediction unit 40.

In the present embodiment, the partial multiplication result parity prediction unit 40 has a partial parity prediction unit 50. The partial parity prediction unit 50 predicts, for each data unit of the partial multiplication result data string described above, the parity value of the data unit.

The parity predictor 1 has the configuration described above. Details of the constituent elements are described later.

Next, the method of prediction of the parity value for the multiplication result data string 4 being the result of the Carry-Less multiplication of the multiplicand data string 2 and multiplier data string 3 used in the parity predictor 1 is described.

Meanwhile, a case in which even-number parity is used for the parity value is used is explained here, and a case in which odd-number parity is used is described later.

### 1. Parity Prediction of a Multiplication Result Data String without Considering the Data Unit

In order to facilitate the understanding of the method of prediction in a case in which prediction of the parity value of the multiplication result data string 4 described later, first, the prediction method in a case in which prediction of the parity value of the multiplication result data string 4 is performed without considering the data unit is explained.

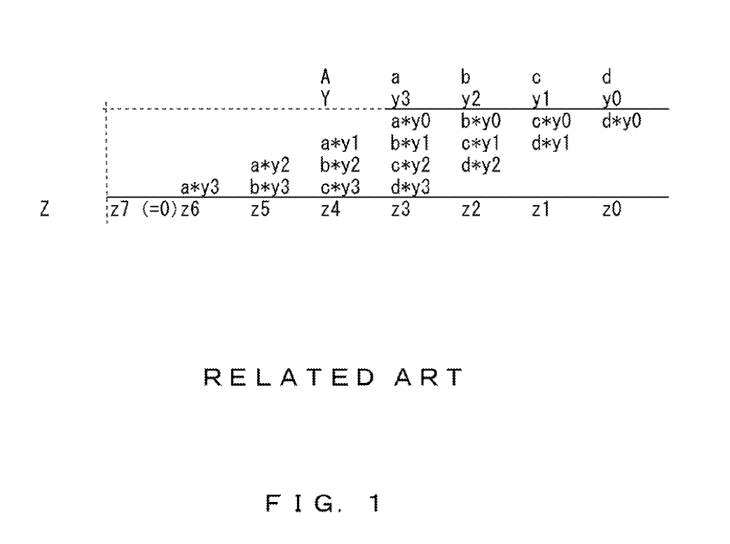

Meanwhile, the parity prediction is explained here using the data example in FIG. 1 used for the explanation of the Carry-Less multiplication described above.

The data example in FIG. 1 assumes the multiplication result of the Carry-Less multiplication of the multiplicand A and the multiplier Y as Z. Assuming the parity value of the multiplication result Z as P_Z, according to the definition of the parity value,

P_{—}Z=z6+z5+z4+z3+z2+z1+z0 [2]

is obtained.

Incidentally, substituting the formula [1] presented above into the formula [2],

P_{—}Z=a*y0+b*y0+c*y0+d*y0+a*y1+b*y1+c*y1+d*y1+a*y2+b*y2+c*y2+d*y2+a*y3+b*y3+c*y3+d*y3 [3]

is obtained.

In addition, the formula [3] may be transformed into the formula [4] below.

P_{—}Z=(a+b+c+d)*(y3+y2+y1+y0) [4]

In the right-hand side of the [4], focusing on the two terms (the terms of XOR) combined by the “*” symbol, “a+b+c+d” is the parity value of the multiplicand A, and “y3+y2+y1+y0” is the parity value of the multiplier Y. That is, assuming the parity value of the multiplicand A as P_A and the parity value of the multiplier Y as P_Y, the formula [5] below is obtained.

P_{—}Z=P_{—}A*P_{—}Y [5]

Then, the value of P_A obtained from the multiplicand A and the value of P_Y obtained from the multiplier Y are substituted into the formula [5] to obtain the value of P_Z. The value is the predicted value of the parity value of the multiplication result Z.

When performing detection of the malfunction of the Carry-Less multiplier, the multiplicand A and the multiplier Y are input to the Carry-Less multiplier, to obtain the multiplication result Z being its output. Then, the parity value P_Z of the multiplication result Z is obtained by the formula [2]. Here, whether or not the parity value P_Z obtained by the formula [2] matches the predicted value obtained by the formula [5] is judged. Here, when they do not match, it is determined that the Carry-Less multiplier has malfunctioned. The malfunction of the Carry-Less multiplier is detected in this way.

### 2. Parity Prediction for Each Data Unit of the Multiplication Result Data String

Next, the method of prediction in a case in which prediction of the parity of the multiplication result data string 4 is performed for each data unit is explained.

### 2.1. Case in which Both the Multiplicand Data String and the Multiplier Data String are One Data Unit

Here, 4-bit data in which four 1-bit data units are lined up is assumed to be a data unit.

First, the prediction method of the parity value for each data unit of the multiplication result data string 4 in a case in which both the multiplicand data string 2 and the multiplier data string 3 are composed of one data unit (that is, in a case in which they are 4-bit data) is explained.

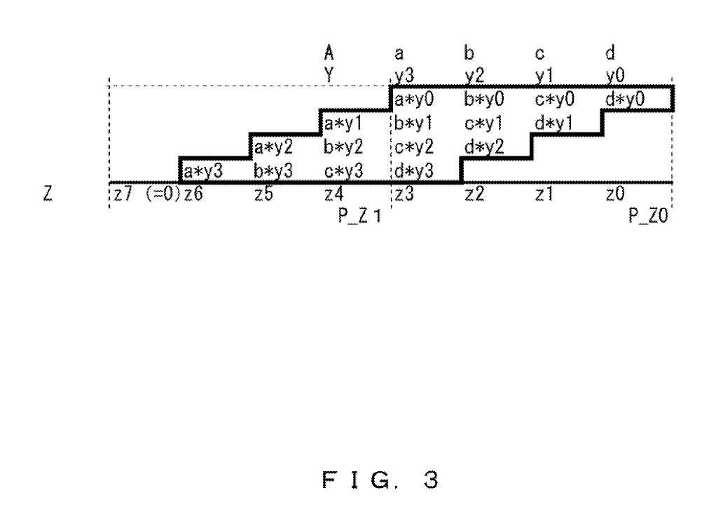

FIG. 3 represents the Carry-Less multiplication of the multiplicand A and the multiplier Y that are both 4-bit data. Meanwhile, in FIG. 3, “a b c d” represents the respective bit of the multiplicand A, and “y3 y2 y1 y0” represents the respective bit of the multiplier Y.

In FIG. 3, the line “a*y0 b*y0 c*y0 d*y0” represents the logical AND of the respective bits a, b, c and d of the multiplicand A and the first bit y0 from the lower order in the multiplier Y, that is, the partial product of the multiplicand A and the multiplier Y. In addition, the other lines are in a similar way. Each of these lines represents the middle result of the arithmetic operation in the Carry-Less multiplication.

Furthermore, Z represents the multiplication result of the Carry-Less multiplication of the multiplicand A and the multiplier Y, and “z6 z5 z4 z3 z2 z1 z0” represents the respective bit of the multiplication result Z. Meanwhile, in the Carry-Less multiplication, the bit z7 being the upper digit of the bit z6 is always “0”.

In a similar manner to the case in FIG. 1, in the Carry-Less multiplication, the respective bit of the multiplication result Z is calculated according to the formula [1] presented above.

Here, the parity value of the respective data units of the multiplication result Z is assumed as P_Z0 and P_Z1. Here, P_Z0 is the parity value of the first data unit from the lower order in the (that is, “z3 z2 z1 z0”) multiplication result Z. In addition, P_Z1 is the parity value of the data following the first data unit from the lower order in the multiplication result Z, that is, the parity value of the high-order 3-bit data (“z6 z5 z4”) of the multiplication result Z.

At this time, the parity values P_Z0 and P_Z1 are respectively, according to the definition of the parity value,

P_{—}Z0=z3+z2+z1+z0=(a*y0+b*y1+c*y2+d*y3)+(b*y0+c*y1+d*y2)+(c*y0+d*y0+d*y0 [6]

P_{—}Z1=z6+z5+z4=a*y3+(a*y2+b*y3)+(a*y1+b*y2+c*y3) [7].

Incidentally, it has already been explained that the parity value P_Z of the multiplication result Z in the case without consideration of the data unit is obtained by the formula [2]. Comparing the formula [2] with the formula [6] and the formula [7], the formula [8] below is obtained.

P_{—}Z=P_{—}Z0+P_{—}Z1 [8]

Here, considering the definition of XOR, it is obvious that the formula [8] may be transformed into the formula [9] and the formula [10] below.

P_{—}Z0=P_{—}Z+P_{—}Z1 [9]

P_{—}Z1=P_{—}Z+P_{—}Z0 [10]

Here, substituting the formula [7] into the formula [9] and substituting the formula [5] and the formula [6] into the formula [10], the formula [11] and the formula [12] below are obtained.

P_{—}Z0=P_{—}A*P_{—}Y+a*y1+(a*y2+b*y2)+(a*y3+b*y3+c*y3)=P_{—}A*P_{—}Y+a*y1+(a+b)*y2+(a+b+c)*y3 [11]

P_{—}Z1=P_{—}A*P_{—}Y+(a*y0+b*y1+c*y2+d*y3)+(b*y0+c*y1+d*y2)+(c*y0+d*y0+d*y0=P_{—}A*P_{—}Y+(a+b+c+d)*y0+(b+c+d)*y1+(c+d)*y2+d*y3 [12]

Then, the respective values of a, b, c, and d constituting the multiplicand A, the respective values of y0, y1, y2 and the y3 constituting the multiplier Y, and the value of P_Y obtained from these values are substituted into the formula [11] and the formula [12] respectively. Then, the values of the P_Z0 and the P_Z1 obtained from the formula [11] and the formula [12] at this time are assumed as the predicted value of the parity value of the multiplication result Z.

When performing detection of the malfunction of the Carry-Less multiplier, the multiplicand A and the multiplier Y are input to the Carry-Less multiplier, to obtain the multiplication result Z being its output. Then, the parity values P_Z0 and the P_Z1 of the multiplication result Z are obtained by the formula [6] and the formula [7]. Here, whether or not the parity values P_Z0 and the P_Z1 obtained by the formula [6] and the formula [7] match the predicted values obtained by the formula [11] and the formula [12] is judged. Here, when they do not match, it is determined that the Carry-Less multiplier has malfunctioned. The malfunction of the Carry-Less multiplier is detected in this way.

Meanwhile, the formula [11] may also be viewed as follows.

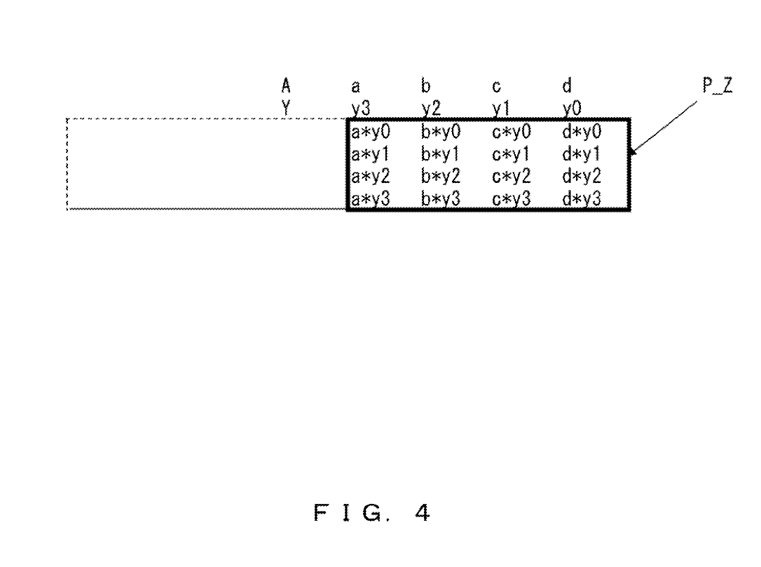

First, in FIG. 3, the respective lines representing the middle result of the arithmetic operation in the Carry-Less multiplication are moved to the right according to the relationship with the respective bits of the multiplicand A, and placed in the position of the first data unit from the lower order in the multiplication result Z being the target of the parity value P_Z0. This is presented in FIG. 4.

Here, in an opposite manner, FIG. 3 is viewed as a transformation from FIG. 4. Viewed in this way, it is understood that the parity value P_Z0 of the first data unit from the lower order of the multiplication result Z may be obtained by compensating the influence of each term that protrudes from the digit of the data unit, with respect to the XOR of the respective terms included in the part enclosed by the thick line in FIG. 4.

Here, it is apparent from the formula [3] that the XOR of the respective terms included in the part enclosed by the thick line in FIG. 4 is equal to the parity value value P_Z of the multiplication result Z in the case without consideration of the data unit. Therefore, it is understood that the calculation of the formula [11] may be performed, as the formula in obtaining the predicted value of the parity value P_Z0 in this case.

In addition, the formula [12] may also be viewed as follows.

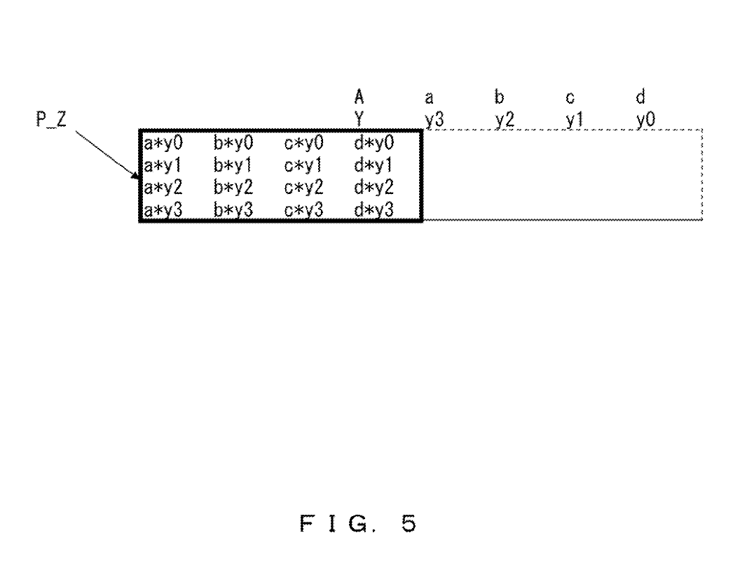

First, in FIG. 3, the respective lines representing the middle result of the arithmetic operation in the Carry-Less multiplication are moved to the left according to the relationship with the respective bits of the multiplicand A, This is presented in FIG. 5.

Here, in an opposite manner, FIG. 3 is viewed as a transformation from FIG. 5. Viewed in this way, it is understood that the parity value P_Z1 of the second data unit from the lower order of the multiplication result Z may be obtained by compensating the influence of each term that sticks out to the lower order from the digit of the data unit, with respect to the XOR of the respective terms included in the part enclosed by the thick line in FIG. 5.

Here, it is apparent from the formula [3] that the XOR of the respective terms included in the part enclosed by the thick line in FIG. 5 is equal to the parity value P_Z of the multiplication result Z in the case without consideration of the data unit. Therefore, it is understood that the calculation of the formula [12] may be performed, as the formula in obtaining the predicted value of the parity value P_Z1 in this case.

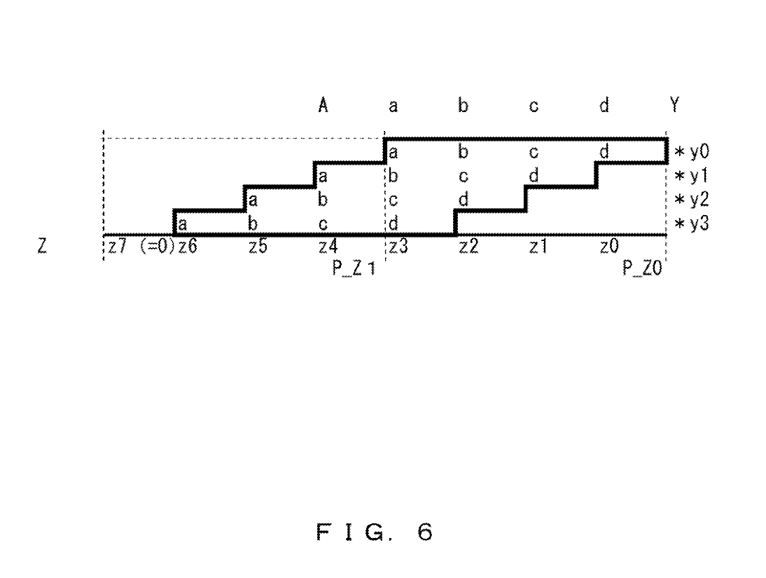

Meanwhile, in the explanation below, it is assumed that the Carry-Less multiplication is illustrated as in FIG. 6.

In FIG. 6, the expression of the respective lines representing the middle result of the Carry-Less multiplication is changed from FIG. 3, with the logical AND of the respective bit y0, y1, y2 and y3 of the multiplier Y with respect to the respective bit a, b, c and d of the multiplicand A is extracted and displayed on the right end.

### 2.2. Case in which Both the Multiplicand Data String and the Multiplier Data String are Two Data Units

Here, 4-bit data in which four 1-bit data are lined up is assumed as the data unit as well.

Next, the prediction method of the parity value for each data unit of the multiplication result data string 4 in a case in which both the multiplicand data string 2 and the multiplier data string 3 are composed of two data units (that is, in a case in which they are 8-bit data) is explained.

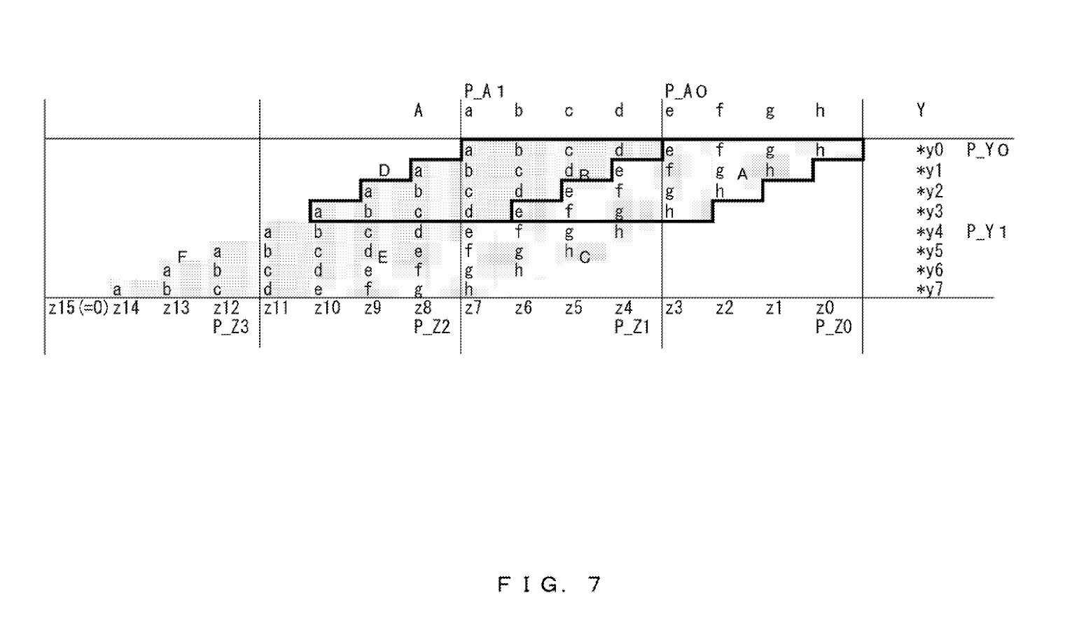

FIG. 7 represents the Carry-Less multiplication of the multiplicand A and the multiplier Y that are both 8-bit data. Meanwhile, in FIG. 7, “a b c d e f g h” represents the respective bit of the multiplicand A, and “y7 y6 y5 y4 y3 y2 y1 y0” represents the respective bit of the multiplier Y.

In addition, in FIG. 7, Z represents the multiplication result of the Carry-Less multiplication of the multiplicand A and the multiplier Y, and “z14 z13 z12 z11 z10 z9 z8 z7 z6 z5 z4 z3 z2 z1 z0┘” represents the respective bit of the multiplication result Z. Meanwhile, in the Carry-Less multiplication, the bit z15 being the upper digit of the bit z14 is always “0”. Furthermore, the parity value of the respective data units of the multiplication result Z is assumed as P_Z0 and P_Z1 P_Z2, and the P_Z3, respectively. Here, P_Z0 is the parity value of the first data unit from the lower order (that is, “z3 z2 z1 z0”) in the multiplication result Z. In addition, P_Z1 is the parity value of the second data unit from the lower order (that is, “z7 z6 z5 z4”) in the multiplication result Z. Furthermore, P_Z2 is the parity value of the third data unit from the lower order (that is, “z11 z10 z9 z8”) in the multiplication result Z. Meanwhile, P_Z3 is the parity value of the data following the third data unit from the lower order in the multiplication result Z, that is, the parity value of the high-order 3-bit data (“z14 z13 z12”) of the multiplication result Z.

In FIG. 7, the middle result of the arithmetic operation in the Carry-Less multiplication is represented in the respective blocks from block A through block F. Here, the blocks A, B and D represent the middle result of the arithmetic operation in the partial multiplication being the Carry-Less multiplication of the multiplicand A and the first data unit from the lower order (that is, “y3 y2 y1 y0”) in the multiplier Y. In addition, the blocks C, E and F represent the middle result of the arithmetic operation in the partial multiplication being the Carry-Less multiplication of the multiplicand A and the second data unit from the lower order (that is, “y7 y6 y5 y4”) in the multiplier Y. Here, prediction of the parity value is performed for each of the blocks first.

Meanwhile, in the explanation below, the data unit “y3 y2 y1 y0” is referred to as a “data unit Y0”, and the data unit “y7 y6 y5 y4” is referred to as “data unit Y1”. In addition, the parity value of the data unit Y0 is assumed as P_Y0, and the parity value of the data unit Y1 is assumed as P_Y1.

First, a focus is put on the block A. In the block A, a part (the part excluding the protrusion to the block B) of the partial multiplication of the first data unit “e f g h” from the lower order in the multiplicand A and the data unit Y0 are represented. As the prediction formula of the parity value P_ZA of the multiplication result about the block A, a, b, c and d in the formula [11] that is the prediction formula of the parity value P_Z0 in the case of FIG. 3 presented above may be replaced with e, f, g and h. That is, the parity value P_ZA may be predicted using the formula [13] below.

P_{—}ZA=P_{—}A0*P_{—}Y0+e*y1+(e+f)*y2+(e+f+g)*y3 [13]

Meanwhile, the parity value P_A0 is the parity value of the data unit “e f g h”. In the explanation below, the data unit “e f g h” is referred to as a “data unit AO”.

Next, a focus is put on the block D. In the block D, a part (the part excluding the protrusion to the block B) of the partial multiplication of the second data unit “a b c d” from the lower order in the multiplicand A and the data unit Y0 are represented. As the prediction formula of the parity value P_ZD of the multiplication result about the block D, the formula [12] that is the prediction formula of the parity value P_Z1 in the case of FIG. 3 presented above may be used without change. That is, the parity value P_ZD may be predicted using the formula [14] below.

P_{—}ZD=P_{—}A1*P_{—}Y0+(a+b+c+d)*y0+(b+c+d)*y1+(c+d)*y2+d*y3 [14]

Meanwhile, the parity value P_A1 is the parity value of the data unit “a b c d”. In the explanation below, the data unit “a b c d” is referred to as a “data unit A1”.

Next, a focus is put on the block B. The block B may be viewed as an overlap between a part (the part excluding the protrusion to the block D) of the partial multiplication of the data units A1 and Y0 and a part (the part excluding the protrusion from the block A) of the partial multiplication of the data units A0 and Y0. In other words, prediction of the parity value P_ZB is performed as follows.

First, the parity value P_ZBD about a part (the part excluding the protrusion to the block D) of the partial multiplication of the data units A1 and Y0 is predicted. As the prediction formula of the parity value P_ZBD, the formula [11] being the prediction formula of the parity value P_Z0 in the case in FIG. 3 described above may be used without change. That is, the parity value P_ZBD may be predicted using the formula [15] below.

P_{—}ZBD=P_{—}A1*P_{—}Y0+a*y1+(a+b)*y2+(a+b+c)*y3 [15]

Next, with respect to the predicted parity value P_ZBD, the influence due to the overlap of a part (the protruding part from the block A) of the partial multiplication of the data unit A0 and Y0 in the block B is compensated. Therefore, the parity value Z_B may be predicted using the formula [16] below.

P_{—}ZB=P_{—}ZBD+e*y1+(e+f)*y2+(e+f+g)*y3=P_{—}A1*P_{—}Y0+a*y1+(a+b)*y2+(a+b+c)*y3+e*y1+(e+f)*y2+(e+f+g)*y3 [16]

Next, a focus is put on the blocks C, F and E representing the middle results of the arithmetic operation in the partial multiplication of the multiplicand A and the data unit Y1. For prediction of the parity value about the blocks C, F and E, considering the correspondence relationship between these blocks and the blocks A, D and B, the formula [13], the formula [14], and the formula [16] being the prediction formulas of the parity value of the blocks A, D and B are used. That is, prediction of the parity values P_ZC, P_ZF, and P_ZE is performed using the formulas below in which y0, y1, y2, and y3 in the formula [13], formula [14], and the formula [16] are replaced with y4, y5, y6, and y7, respectively.

P_{—}ZC=P_{—}A0*P_{—}Y1+e*y5+(e+f)*y6+(e+f+g)*y7 [17]

P_{—}ZF=P_{—}A1*P_{—}Y1+(a+b+c+d)*y4+(b+c+d)*y5+(c+d)*y6+d*y7 [18]

P_{—}ZE=P_{—}A1*P_{—}Y1+a*y5+(a+b)*y6+(a+b+c)*y7+e*y5+(e+f)*y6+(e+f+g)*y7 [19]

Once the parity value for each block is obtained, the parity values P_Z0, P_Z1, P_Z2, and P_Z3 for each data unit of the multiplication result Z may be obtained respectively by the formulas below.

P_{—}Z0=P_{—}ZA [20]

P_{—}Z1=P_{—}ZB+P_{—}ZC [21]

P_{—}Z2=P_{—}ZD+P_{—}ZE [22]

P_{—}Z3=P_{—}ZF [23]

When performing detection of the malfunction of the Carry-Less multiplier, the multiplicand A and the multiplier Y are input to the Carry-Less multiplier, to obtain the multiplication result Z being its output. Then, parity values P_Z0, P_Z1, P_Z2, and P_Z3 for each data unit of the of the multiplication result Z are obtained, using the respective value of the bit z0 to the bit z14 in the multiplication result Z, according to the definition of the parity value. Here, whether or not the parity values P_Z0, P_Z1, P_Z2, and P_Z3 in this way match the predicted values obtained respectively by the formula [20], the formula [21], the formula [22], and the formula [23] is judged. Here, when they do not match, it is determined that the Carry-Less multiplier has malfunctioned. The malfunction of the Carry-Less multiplier is detected in this way.

### 2.3. Case in which the Size of the Multiplicand Data String and the Multiplier Data String is Generalized

Here, the prediction method of the parity value for each data unit of the multiplication result data string 4 in a case in which [2.2] described above is generalized, that is, a case in which the size of the data unit and the size of the multiplicand data string 2 and the multiplier data string 3 are generalized.

First, the data unit is assumed as a p-bit data in which p (here, p is a natural number equal to or larger than 2) 1-bit data are lined up. Then, it is assumed that both the multiplicand A and the multiplier Y are composed of q (here, q is a natural number) data units (that is, they are q×p bit data). The multiplication result Z obtained by the Carry-Less multiplication of the multiplicand A and the multiplier Y becomes 2q×p−1 bit data.

Meanwhile, in the explanation below, the data unit composed of the first data unit from the lower order in the multiplicand A, that is, the data unit composed of the first through p-th bit data from the lower order is referred to as the “first multiplicand data unit”. In addition, each of the second data unit through the q-th data unit in the multiplicand A is referred to as the “second multiplicand data unit”, . . . , the “q-th multiplicand data unit”, respectively. In a similar manner, the data unit composed of the first data unit from the lower order in the multiplier Y, that is, the data unit composed of the first through p-th bit data from the lower order is referred to as the “first multiplier data unit”. In addition, each of the second data unit through the q-th data unit in the multiplier Y is referred to as the “second multiplier data unit”, . . . , the “q-th multiplier data unit”, respectively.

Furthermore, in the explanation below, the data unit composed of the first data unit from the lower order in the multiplication result Z, is referred to as the “first multiplication result data unit”. In addition, each of the second data unit through the 2q−1-th data unit in the multiplication result Z is also referred to as the “second multiplication result unit”, . . . , the “2q−1-th multiplication result data unit”, respectively. In addition, the p−1 bit data following the 2q−1-th multiplication result in the multiplication result Z, that is, the data of the p−1-th bit from the higher order in the multiplication result is referred to as the “second multiplication result data unit” for convenience.

### 2.3.1. Prediction of Low-Order Parity

First, the prediction method for the parity value of the first multiplication result data unit (hereinafter, the parity value is referred to as the “low-order parity value”) is explained. The prediction of the low-order parity value may be viewed in a similar manner as the prediction of the parity value P_Z0 in FIG. 7. That is, the prediction of the low-order parity value is performed according to the following procedure, for example, based on the value for each of the first multiplicand data unit and the first multiplier data unit and their parity value and expanding the formula [20] and the formula [13].

First, the logical AND of the parity value of the first multiplicand data unit and the parity value of the first multiplier data unit is obtained. The value of the logical AND is referred to as the “low-order parity logical AND”. Meanwhile, this procedure corresponds to, in the formula [13], the logical operation of the first term among the terms connected by “+” symbol in the righthand side.

Next, the logical AND of the value of the highest order bit in the first multiplicand data unit and the value of the second digit from the lower order in the first multiplier data unit is obtained. The value of the logical AND is referred to as the “low-order first logical AND”. Meanwhile, this procedure corresponds to the logical operation of the second term on the righthand side in the formula [13].

Next, the logical AND of the XOR of the values of the respective bits for i digits (here, i is a natural number from 2 to p−1) from the higher order in the first multiplicand unit and the value of the bit at the i+1 digit from the lower order is obtained respectively. Since there are p−2 values that i mentioned above may take, there are p−2 values of the logical AND as well. The value of the logical AND is referred to as the “low-order second logical AND”. Meanwhile, this procedure corresponds to, in the formula [13], the logical operation of each term from the third term to the fourth term on the righthand side.

Meanwhile, the order for calculating the low-order parity logical AND, the low-order first logical AND, and the p−2 low-order second logical ANDs may not be the order described above.

Next, the XOR of the low-order parity logical AND, low-order first logical AND and p−2 low-order second logical ANDs obtained as described above is obtained. The value of the XOR obtained in this way is the prediction result of the low-order parity value. This procedure corresponds to, in the formula [13], the XOR operation of each term from the first term to the fourth term on the righthand side.

### 2.3.2. Prediction of High-Order Parity

Next, the prediction method of the parity value of the 2q-th multiplication result data unit (the parity value is referred to as the “high-order parity value”) is explained. The prediction of the high-order parity value may be viewed in a similar manner as the prediction of the parity value P_Z3 in FIG. 7 presented above. That is, the prediction of the high-order parity value is performed according to the following procedure, based on the value for each of the q-th multiplicand data unit and the q-th multiplier data unit and their parity value and expanding the formula [23] and the formula [18].

First, the logical AND of the parity value of the q-th multiplicand data unit and the parity value of the q-th multiplier data unit is obtained. The value of the logical AND is referred to as the “high-order parity logical AND”. Meanwhile, this procedure corresponds to, in the formula [18], the logical operation of the first term in the respective terms connected by the “+” symbol on the righthand side.

Next, the logical AND of the value of the lowest-order bit in the q-th multiplicand data unit and the value of the highest-order bit in the q-th multiplier data unit is obtained. The value of the logical AND is referred to as the “high-order first logical AND”. Meanwhile, this procedure corresponds to, in the formula [18], the logical operation of the fifth term on the righthand side.

Next, the logical and of the XOR of the value of the respective bits for j digits (here, j is a natural number from 2 through p from the lower order in the q-th multiplicand data unit and the value of the bit at the j-th digit from the higher order in the q-th multiplier data unit is obtained respectively. Since there are p−1 values that j may take, p−1 values of the logical AND are obtained as well. The value of the logical and is referred to as the “high-order second logical AND”. Meanwhile, this procedure corresponds to, in the formula [18], the logical operation of each term from the second term to the fourth term on the righthand side.

Meanwhile, the order for calculating the high-order parity logical AND, the high-order first logical AND, and the p−1 high-order second logical ANDs may not be the order described above.

Next, the XOR of the high-order parity logical AND, high-order first logical AND and p−1 high-order second logical ANDs obtained as described above is obtained. The value of the XOR obtained in this way is the prediction result of the high-order parity value.

This procedure corresponds to, in the formula [18], the XOR operation of each term from the first term to the fifth term on the righthand side.

### 2.3.3. Prediction of Middle-Order Parity

Next, the parity value of each multiplication result data unit from the second multiplication result data unit to the 2q−1-th multiplication data unit (the parity value is referred to as the “middle-order parity value”) is explained, The prediction of the middle-order parity value is performed based on the value and the parity of each data unit from the first data unit to the q-th data unit in each of the multiplicand A and the multiplier Y.

### 2.3.3.1. Prediction of the Parity Value for Each Data Unit of the Partial Multiplication Result

In the prediction of the middle-order parity value, prediction of the parity value for each data unit of the partial multiplication result data unit is performed, and based on the prediction result of the parity value for each data unit of the partial multiplication data unit, prediction of the middle-order parity value is performed. Meanwhile, the partial multiplication result is the result of the Carry-Less multiplication with one of the data units constituting the multiplicand A and the multiplier Y.

Here, the result of the Carry-Less multiplication of the multiplicand A and the r-th multiplier data unit (here, r is a natural number from 1 through q) is referred to as the “r-th partial multiplication result”. Therefore, in the example in FIG. 7, for example, the result of the Carry-Less multiplication of the multiplicand A (that is, “a b c d e f g h”) and the first multiplier data unit (that is, “y3 y2 y1 y0”) is the first partial multiplication result. In addition, the Carry-Less multiplication of the multiplicand A and the second multiplier data unit (that is, “y7 y6 y5 y4”) is the second partial multiplication result.

The first data unit from the lower order in the r-the partial the first data unit from the lower order in the r-th partial multiplication result is referred to as the “first partial”. In a similar manner, each data unit from the second data unit through the q-th data unit from the lower order in the r-th partial multiplication result is referred to as the “second partial”, . . . “q-th partial”, respectively. Furthermore, the data of the high-order p−1-th bit in the r-partial multiplication result being the data following the q-th partial in the r-th partial multiplication result is referred to as the “q+1-th partial” for convenience.

Hereinafter, the prediction method of the parity value of each of the first partial through the q+1-th partial is explained.

### 2.3.3.1.1. Prediction of the Parity Value for the First Partial

The prediction of the parity value of the first partial may be viewed in a similar manner to the prediction of the parity value P_ZA for the block A or the prediction of the parity value P_ZC for the block C in FIG. 7 presented above. That is, the prediction of first partial is performed, for example, according to the following procedure, based on the value of each of the first multiplicand data unit and the r-th multiplier data unit and their parity value, and extending the formula [13] or the formula [17].

First, the logical AND of the parity value of the first multiplicand data unit and the parity value of the r-th multiplier data unit is obtained. The value of the logical AND is referred to as the “low-order partial parity logical AND”. Meanwhile, this procedure corresponds to, in the formula [13], the logical operation of the first term among the terms connected by “+” symbols in the righthand side.

Next, the logical and of the value of the highest order bit in the first multiplicand data unit and the value of the second digit from the lower order in the r-th multiplier data unit is obtained. The value of the logical AND is referred to as the “low-order partial first logical AND”. Meanwhile, this procedure corresponds to the logical operation of the second term on the righthand side in the formula [13].

Next, the logical AND of the XOR of the values of the respective bits for g digits (here, g is a natural number from 2 to p−1) from the higher order in the first multiplicand unit and the value of the bit at the g+1 digit from the lower order in the r-th multiplier data unit is obtained respectively. Since there are p−2 values that g mentioned above may take, there are p−2 values of the logical AND as well. The value of the logical AND is referred to as the “low-order partial second logical AND”. Meanwhile, this procedure corresponds to, in the formula [13], the logical operation of each term from the third term to the fourth term on the righthand side.

Meanwhile, the order for calculating the low-order partial parity logical AND, the low-order partial first logical AND, and the p−2 low-order partial second logical ANDs may not be the order described above.

Next, the XOR of the low-order partial parity logical AND, low-order partial first logical AND and p−2 low-order partial second logical ANDs obtained as described above is obtained. The value of the XOR obtained in this way is the prediction result of the parity value for the first partial. This procedure corresponds to, in the formula [13], the XOR operation of each term from the first term to the fourth term on the righthand side.

### 2.3.3.1.2. Prediction of the Parity Value for the q+1-th Partial

The prediction of the parity value of the q+1-th partial may be viewed in a similar manner as the prediction of the parity value P_ZD for the block D in FIG. 7 presented above or the prediction of the parity value P_ZF for the block F. That is, the prediction of the parity value for the q+1-th partial is performed, for example, according to the following procedure, based on the value for each of the q-th multiplicand data unit and the r-th multiplier data unit and their parity value, and expanding the formula [14] or the formula [18].

First, the logical AND of the parity value of the q-th multiplicand data unit and the parity value of the r-th multiplier data unit is obtained. The value of the logical AND is referred to as the “high-order partial parity logical AND”. Meanwhile, this procedure corresponds to, in the formula [14], the logical operation of the first term in the respective terms connected by the “+” symbol on the righthand side.

Next, the logical AND of the value of the lowest-order bit in the q-th multiplicand data unit and the value of the highest-order bit in the r-th multiplier data unit is obtained. The value of the logical AND is referred to as the “high-order partial first logical AND”. Meanwhile, this procedure corresponds to, in the formula [14], the logical operation of the fifth term on the righthand side.

Next, the logical and of the XOR of the value of the respective bits for h digits (here, h is a natural number from 2 through p from the lower order in the q-th multiplicand data unit and the value of the bit at the h-th digit from the higher order in the q-th multiplier data unit is obtained respectively. Since there are p−1 values, that h may take, p−1 values of the logical AND are obtained as well. The value of the logical and is referred to as the “high-order partial second logical AND”. Meanwhile, this procedure corresponds to, in the formula [14], the logical operation of each term from the second term to the fourth term on the righthand side.

Meanwhile, the order for calculating the high-order partial parity logical AND, the high-order partial first logical AND, and the p−1 high-order partial second logical ANDs may not be the order described above.

Next, the XOR of the high-order partial parity logical AND, high-order partial first logical AND and p−1 high-order partial second logical ANDs obtained as described above is obtained. The value of the XOR obtained in this way is the prediction result of the parity value for the q+1-th partial. This procedure corresponds to, in the formula [14], the XOR operation of each term from the first term to the fifth term on the righthand side.

### 2.3.3.1.3. Prediction of the Parity Value for the Middle Partial

Next, the parity value of each data unit from the second partial through the q-th partial (the parity value is referred to as the “middle-order partial parity value”) is explained. The prediction of the middle-order partial parity value is may be viewed in a similar manner to the prediction of the parity value P_ZB for the block B in FIG. 7 presented above, or the prediction of the parity value P_ZE for the block E. The prediction of the middle-order partial parity value is performed, for example, in the following procedure, based on the value and the parity of each data unit from the first multiplicand data unit to the q-th multiplier data unit and the r-th multiplier data unit, and expanding the formula [16] or the formula [19].

Meanwhile, the procedure of predicting the parity value for the k-th partial (here, k is a natural number from 2 through q) is explained here.

First, the logical AND of the parity value of the k-th multiplicand data unit and the parity value of the r-th multiplier data unit is obtained. The value of the logical AND is referred to as the “middle-order partial parity logical AND”. Meanwhile, this procedure corresponds to, in the formula [16], the logical operation of the first term among the terms connected by “+” symbols in the righthand side.

Next, the logical and of the value of the highest order bit in the k-th multiplicand data unit and the value of the second digit from the lower order in the r-th multiplier data unit is obtained. The value of the logical AND is referred to as the “middle-order partial first logical AND”. Meanwhile, this procedure corresponds to the logical operation of the second term on the righthand side in the formula [16].

Next, the logical AND of the XOR of the values of the respective bits for m digits (here, m is a natural number from 2 to p−1) from the higher order in the k-th multiplicand unit and the value of the bit at the m+1 digit from the lower order in the r-th multiplier data unit is obtained respectively. Since there are p−2 values that m mentioned above may take, there are p−2 values of the logical AND as well. The value of the logical AND is referred to as the “middle-order partial second logical AND”. Meanwhile, this procedure corresponds to, in the formula [16], the logical operation of each term from the third term to the fourth term on the righthand side.

Next, the logical AND of the value of the highest-order bit in the k−1-th multiplicand data unit and the value of the bit at the second digit from the lower order in the r-th multiplier data unit is obtained. The value of the logical AND is referred to as the “middle-order partial third logical AND”. Meanwhile, this procedure corresponds to, in the formula [16], the logical operation of the fifth term on the righthand side.

Next, the logical AND of the XOR of the values of the respective bits for n digits (here, n is a natural number from 2 to p−1) from the higher order in the k-th multiplicand unit and the value of the bit at the n+1 digit from the lower order in the r-th multiplier data unit is obtained respectively. Since there are p−2 values that n mentioned above may take, there are p−2 values of the logical AND as well. The value of the logical AND is referred to as the “middle-order partial fourth logical AND”. Meanwhile, this procedure corresponds to, in the formula [16], the logical operation of each term from the sixth term to the seventh term on the righthand side.

Meanwhile, the order for calculating the middle-order partial parity logical AND, the middle-order partial first logical AND, p−2 middle-order partial second logical ANDs, the middle-order partial third logical AND and the p−2 middle-order partial fourth logical ANDs may not be the order described above.

Next, the XOR of the middle-order partial parity logical AND, the middle-order partial first logical AND, p−2 middle-order partial second logical ANDs, the middle-order partial third logical AND and the p−2 middle-order partial fourth logical ANDs described as descried above is obtained. The value of the XOR obtained in this way is the prediction result of the parity value for the k-th partial. Meanwhile, this procedure corresponds to, in the formula [16], the XOR operation of each term from the first term through the seventh term on the righthand side.

### 2.3.3.2. Prediction of the Middle-Order Parity Based on the Prediction Result of the Parity Value for Each Data Unit of the Partial Multiplication Result

By executing the procedure described so far for all the values that the variable r may take, the parity predicted value for each data unit of the first partial multiplication result through the r-th partial multiplication result is obtained. The prediction of the middle-order parity value for each data unit constituting the multiplication result Z is performed by selecting parity predicted values for each data unit of these partial multiplication results according to a prescribed rule and obtaining the XOR of the selected parity predicted values.

First, among the data units constituting the multiplication result Z, the prediction method of the parity value of the s-th multiplication result (here, s is a natural number from 2 through q) is explained.

The prediction of the parity value of the s-th multiplication result data unit may be viewed in a similar manner to the prediction of the parity value P_Z1 performed using the parity predicted value for the block B and the parity predicted value for the block C in FIG. 7 presented above. That is, the prediction of the parity value of the s-th multiplication result data unit is performed, for example, in the following procedure, expanding the formula [21].

First, the parity predicted value of the s-u+1 partial of the u-th partial multiplication result (here, u is a natural number from 1 through s) is selected. Since there are s values that u mentioned above may take, s parity predicted values are selected. Then, the XOR of the s parity predicted values is obtained. The value of the XOR obtained in this way is the predicted result of the parity value of the s-th multiplication result data unit.

Next, among the data units constituting the multiplication result Z, the prediction method of the parity value of the t-th multiplication result (here, t is a natural number from q+1 through 2q−1) is explained.

The prediction of the parity value of the t-th multiplication result data unit may be viewed in a similar manner to the prediction of the parity value P_Z2 performed using the parity predicted value for the block D and the parity predicted value for the block E in FIG. 7 presented above. That is, the prediction of the parity value of the t-th multiplication result data unit is performed, for example, in the following procedure, expanding the formula [22].

First, the parity predicted value of the t-v+1 partial of the u-th partial multiplication result (here, v is a natural number from t-q through q) is selected. Since there are 2q-t+1 values that v mentioned above may take, 2q-t+1 parity predicted values are selected. Then, the XOR of the s parity predicted values is obtained. The value of the XOR obtained in this way is the predicted result of the parity value of the t-th multiplication result data unit.

The prediction of the middle-order parity value for each data unit from the second multiplication result data unit through the 2q−1 multiplication result data is performed as described above.

### 2.4. Parity Prediction for Odd-Number Parity

Even-number parity is used as the parity value in the prediction method of the parity value described above. Here, the prediction method in a case using odd-number parity is explained.

Even-number parity is for setting the value (parity value) of the parity bit so that the number of bit whose value is “1” in the respective bits constituting certain data and the parity bit of the data is an even number. For this purpose, as the parity value of certain data in even-number parity, the value of the XOR of the respective bits constituting the data is set.

In contrast, odd-number parity is for setting the value (parity value) of the parity bit so that the number of bit whose value is “1” in the respective bits constituting certain data and the parity bit of the data is an odd number. For this purpose, as the parity value of certain data in odd-number parity, the value obtained by XORing the value of the XOR of the respective bits constituting the data (that is, the parity value in the case of even-number parity) further and the value “1” is set.

In consideration of this relationship, the prediction formula of the parity value in the case of odd-number parity is derived.

First, the prediction formula in the case of odd-number parity used for the prediction in [1. parity prediction of a multiplication result data string without considering the data unit] is derived.

In the data example in FIG. 1 presented above, the formula to derive the parity value of the multiplication result Z of the Carry-Less multiplication of the multiplicand A and the multiplier Y being 4-bit data is, in the case of odd-number parity, the formula [24] below.

P_{—}Z_odd=z6+z5+z4+z3+z2+z1+z0+1 [24]

In the formula [24], P_Z_odd is the parity value of the multiplication result Z in the case of odd-number parity. In the explanation above, the parity value in the case of odd-number parity is described in this way, to distinguish it from the parity value in the case of even-number parity described above.

The formula [1] is substituted into the formula [24] to modify it.

P_{—}Z_odd=(a+b+c+d)*(y3+y2+y1+y0)+1 [25]

In the formula [25], P_Z_odd becomes “1” when at least one of the values (a+b+c+d) and (y3+y2+y1+y0) is “0”.

Incidentally, assuming the parity value of the multiplicand A in the case of odd-number parity as P_A_odd and the parity value of the multiplier Y as P_Y_odd, according to the definition of the parity value,

P_{—}A_odd=a+b+c+d+1

P_{—}Y_odd=y3+y2+y1+y0+1 [26].

In the formula [26], when the value of (a+b+c+d) is “0”, the value of P_A_odd is “1”, and when the value of (y3+y2+y1+y0) is “0”, the value of P_Y_odd is “1”. Therefore, when at least one of (a+b+c+d) and (y3+y2+y1+y0) becomes “0”, at least one of the values of P_A_odd and P_Y_odd is “1”. According to this, the formula [27] is obtained.

P_{—}Z_odd=P_{—}A_odd̂P_{—}Y_odd [27]

Meanwhile, as described above, the symbol “̂” represents OR. In the case of odd-number parity, the value of P_Z_odd is obtained by substituting the value of P_A_odd obtained from the multiplicand A and the value of P_Y_odd obtained from the multiplier Y into the formula [27]. The value is the predicted value of the parity value of the multiplication result Z.

When performing the detection of the malfunction of the Carry-Less multiplier, the multiplicand A and the multiplayer Y is input into the Carry-Less multiplier, to obtained the multiplication result Z being its output. Then, the parity value P_Z_odd of the multiplication result Z is obtained by the formula [25]. Here, whether or not the parity value P_Z_odd obtained by the formula [25] match the predicted value obtained by the formula [27] is judged. Here, when they do not match, it is determined that the Carry-Less multiplier has malfunctioned. The malfunction of the Carry-Less multiplier is detected in this way.

Next, the prediction formula in the case of odd-number parity used for the prediction in [2. parity prediction for each data unit of the multiplication result data string] is derived.

First, [2.1. Case in which both the multiplicand data string and the multiplier data string are one data unit] is explained.

In the data example in FIG. 3 presented above, the parity values P_Z0_odd and P_Z1-odd are, according the definition of the parity value, in odd-number parity for each data unit of the multiplication result Z,

P_{—}Z0_odd=z3+z2+z1+z0+1=(a*y0+b*y1+c*y2+d*y3)+(b*y0+c*y1+d*y2)+(c*y0+d*y1)+d*y0+1 [28]

P_{—}Z1_odd=z6+z5+z4+1=a*y3+(a*y2+b*y3)+(a*y1+b*y2+c*y3)+1 [29]

respectively.

Next, in a similar manner to the case of even-number parity, FIG. 3 is viewed as a modification from FIG. 4. That is, the parity value P_Z0_odd in odd-number parity of the first data unit from the lower order in the multiplication result Z is obtained by compensating the influence of the respective terms protruding to the higher order from the position of the data unit, with respect to the odd-number parity value in the part enclosed by the thick line in FIG. 4.

It is apparent from the formula [28] that the odd-number parity value in the part enclosed by the thick line in FIG. 4 is equal to the parity value P_Z_odd of the multiplication result Z in the case without consideration of the data unit. Therefore, it is understood that, as the formula to obtain the predicted value of the parity value P_Z_odd in this case, the formula [30] below in which the first term in the respective terms connected by the symbol “+” on the righthand side of the formula [11] is replaced using the formula [27] may be used.

P_{—}Z0_odd=P_{—}A_odd̂P_{—}Y_odd+a*y1+(a+b)*y2+(a+b+c)*y3 [30]

In addition, in a similar manner to the case of even-number parity described above, FIG. 3 presented above is viewed as a modification from FIG. 5. That is, the parity value P_Z1_odd in odd-number parity of the second data unit from the lower order in the multiplication result Z is obtained by compensating the influence of the respective terms protruding the lower order from the position of the data unit, with respect to the odd-number parity value in the part enclosed by a thick line in FIG. 5.

It is apparent from the formula [28] that the odd-number parity value in the part enclosed by the thick line in FIG. 5 is equal to the parity value P_Z_odd of the multiplication result Z in the case without consideration of the data unit. Therefore, it is understood that, as the formula to obtain the predicted value of the parity value P_Z1_odd in this case, the formula [31] below in which the first term in the respective terms connected by the symbol “+” on the righthand side of the formula [12] is replaced using the formula [27] may be used.

P_{—}Z1_odd=P_{—}A_odd̂P_{—}Y_odd+(a+b+c+d)*y0+(b+c+d)*y1+(c+d)*y2+d*y3 [31]

When performing the detection of the malfunction of the Carry-Less multiplier, the multiplicand A and the multiplayer Y is input into the Carry-Less multiplier, to obtained the multiplication result Z being its output. Then, the parity values P_Z0_odd and P_Z1_odd in odd-number parity for each data unit of the multiplication result Z are obtained by the formula [28] and the formula [29]. Here, whether or not the parity values P_Z0_odd and P_Z1_odd obtained by the formula [28] and the formula [29] match the predicted values obtained by the formula [30] and the formula [31] respectively is judged. Here, when they do not match, it is determined that the Carry-Less multiplier has malfunctioned. The malfunction of the Carry-Less multiplier is detected in this way.

Next, [2.2. Case in which both the multiplicand data string and the multiplier data string are two data units] is explained.

As the prediction formula of the parity value P_ZA_odd in odd-number parity of the multiplication result for the block A in the data example in FIG. 7 presented above, a, b, c, and d in the formula [30] presented above may be replaced by e, f, g, and h. That is, the parity value P_ZA_odd may be predicted using the formula [32] below.

P_{—}ZA_odd=P_{—}A0_odd̂P_{—}Y0_odd+e*y1+(e+f)*y2+(e+f+g)*y3 [32]

Meanwhile, P_Y0_odd is the parity value in odd-number parity of the data unit Y0, and P_Y1_odd is the parity value in odd-number parity of the data unit Y1.

Next, as the prediction formula of the parity value P_ZD_odd in odd-number parity of the multiplication result for the block D in the data example in FIG. 7 presented above, the formula [31] presented above may be used without change. That is, the parity value P_ZD_odd may be predicted using the formula [33] below.

P_{—}ZD_odd=P_{—}A1_odd̂P_{—}Y0_odd+(a+b+c+d)*y0+(b+c+d)*y1+(c+d)*y2+d*y3 [33]

Next, the prediction formula of the parity value P_ZB_odd in odd-number parity of the multiplication result for the block B in the data example in FIG. 7 presented above may be derived by considering it in a similar manner to the formula [30] and the formula [31] presented above. That is, as the formula in obtaining the predicted value of the parity value P_ZB_odd, the formula [34] in which the first term in the respective terms connected by the symbol “+” is replaced using the formula [27] may be used.

P_{—}ZB_odd=P_{—}A1_odd̂P_{—}Y0_odd+a*y1+(a+b)*y2+(a+b+c)*y3+e*y1+(e+f)*y2+(e+f+g)*y3 [34]

Next, for the prediction of the parity values for the blocks C, F and E in FIG. 7, the formula [32], the formula [33], and the formula [34] are used in consideration of the correspondence relationship between these blocks and the blocks A, D and B. That is, for the prediction of these parity values, the following formulas in which y0, y1, y2, and y3 in the formula [32], formula [33], and the formula [34] are replaced by y4, y5, y6, and y7 are used.

P_{—}ZC_odd=P_{—}A0_odd̂P_{—}Y1_odd+e*y5+(e+f)*y6+(e+f+g)*y7 [35]

P_{—}ZF_odd=P_{—}A1_odd̂P_Y1_odd+(a+b+c+d)*y4+(b+c+d)*y5+(c+d)*y6+d*y7 [36]

P_{—}ZE_odd=P_{—}A1_odd̂P_{—}Y1_odd+a*y5+(a+b)*y6+(a+b+c)*y7+e*y5+(e+f)*y6+(e+f+g)*y7 [37]

Meanwhile, P_ZC_odd, P_ZF_odd, and P_ZE_odd are the parity values in odd-number parity of the multiplication result for the blocks C, F, and E, respectively.

Once the parity value for each block is obtained as descried above, parity value P_Z0_odd, P_Z1_odd, P_Z2_odd, and P_Z3_odd in odd-number parity for each data unit of the multiplication result may be respectively obtained by the following formulas.

P_{—}Z0_odd=P_{—}ZA_odd [38]

P_{—}Z1_odd=P_{—}ZB_odd+P_{—}ZC_odd+1 [39]

P_{—}Z2_odd=P_{—}ZD_odd+P_{—}ZE_odd+1 [40]

P_{—}Z3_odd=P_{—}ZF_odd [41]

Meanwhile, it is noted that in the formula [39] and the formula [40] presented above, “+1” is added, that is, the XOR with the value “1” is added, to the end of the righthand side.

For example, in FIG. 7, in obtaining P_Z1_odd according to the definition of the parity value, with respect to the XOR of the respective terms included in the block B and the respective terms in the block C, the XOR with the value “1” is further obtained once. In contrast, P_ZB_odd is the XOR of the XOR of the respective terms included in the block B and the value “1”, and P_ZC_odd is the XOR of the XOR of the respective terms included in the block C and the value “1”. Therefore, in obtaining the XOR of P_ZB_odd and P_ZC_odd, the XOR with the value “1” is performed twice. Therefore, the XOR with the value “1” is added in the formula [39], to cancel this influence. This applies to the formula [40] as well.

Thus, in odd-number parity, when the parity value in odd-number parity for each data unit of the multiplication result Z is obtained from the XOR of even numbers of blocks, with respect to the XOR, the XOR with the value “1” further needs to be obtained.

When performing the detection of the malfunction of the Carry-Less multiplier, the multiplicand A and the multiplayer Y is input into the Carry-Less multiplier, to obtained the multiplication result Z being its output. Then, the parity values P_Z0_odd, P_Z1_odd, P_Z2_odd, and P_Z3_odd in odd-number parity for each data unit of the multiplication result Z are obtained according to the definition of the parity value, using each value of the bit z0 through the bit Z14 in the multiplication result Z. Here, whether or not the parity values P_Z0_odd, P_Z1_odd, P_Z2_odd, and P_Z3_odd obtained in this way match the predicted values obtained by the formula [38], formula [39], formula [40], and the formula [41] respectively is judged. Here, when they do not match, it is determined that the Carry-Less multiplier has malfunctioned. The malfunction of the Carry-Less multiplier is detected in this way.

Next, [2.3. Case in which the size of the multiplicand data string and the multiplier data string is generalized] is explained.

First, [2.3.1. Prediction of low-order parity] may be viewed in a similar manner to the case [2.2] described above.

That is, the prediction of the low-order parity value is performed, for example, according to the following procedure, based on the value and of the first multiplicand data unit and the first multiplier data unit and their parity value and expanding the formula [38] and the formula [32].

First, the OR of the parity value of the first multiplicand data unit and the parity value of the first multiplier data unit is obtained. The value of the OR is referred to as the “low-order parity OR”. Meanwhile, this procedure corresponds to, in the formula [32], the logical operation of the first term among the terms connected by “+” symbol in the righthand side.

Next, the logical AND of the value of the highest order bit in the first multiplicand data unit and the value of the second digit from the lower order in the first multiplier data unit is obtained.

The value of the logical AND is referred to as the “low-order first logical AND”. Meanwhile, this procedure corresponds to the logical operation of the second term on the righthand side in the formula [32].

Next, the logical AND of the XOR of the values of the respective bits for i digits (here, i is a natural number from 2 to p−1) from the higher order in the first multiplicand unit and the value of the bit at the i+1 digit from the lower order is obtained respectively. Since there are p−2 values that i mentioned above may take, there are p−2 values of the logical AND as well. The value of the logical AND is referred to as the “low-order second logical AND”. Meanwhile, this procedure corresponds to, in the formula [32], the logical operation of each term from the third term to the fourth term on the righthand side.

Meanwhile, the order for calculating the low-order parity OR, the low-order first logical AND, and the p−2 low-order second logical ANDs may not be the order described above.

Next, the XOR of the low-order parity OR, low-order first logical AND and p−2 low-order second logical ANDs obtained as described above is obtained. The value of the XOR obtained in this way is the prediction result of the low-order parity value. This procedure corresponds to, in the formula [32], the XOR operation of each term from the first term to the fourth term on the righthand side.

Next, [2.3.2. Prediction of high-order parity] may be viewed in a similar manner to the case [2.2.] described above, That is, the prediction of the high-order parity value is performed according to the following procedure, based on the value for each of the q-th multiplicand data unit and the q-th multiplier data unit and their parity value and expanding the formula [41] and the formula [36].

First, the OR of the parity value of the q-th multiplicand data unit and the parity value of the q-th multiplier data unit is obtained. The value of the OR is referred to as the “high-order parity OR”. Meanwhile, this procedure corresponds to, in the formula [36], the logical operation of the first term in the respective terms connected by the “+” symbol on the righthand side.

Next, the logical AND of the value of the lowest-order bit in the q-th multiplicand data unit and the value of the highest-order bit in the q-th multiplier data unit is obtained. The value of the logical AND is referred to as the “high-order first logical AND”. Meanwhile, this procedure corresponds to, in the formula [36], the logical operation of the fifth term on the righthand side.

Next, the logical and of the XOR of the value of the respective bits for j digits (here, j is a natural number from 2 through p from the lower order in the q-th multiplicand data unit and the value of the bit at the j-th digit from the higher order in the q-th multiplier data unit is obtained respectively. Since there are p−1 values that j may take, p−1 values of the logical AND are obtained as well. The value of the logical and is referred to as the “high-order second logical AND”. Meanwhile, this procedure corresponds to, in the formula [36], the logical operation of each term from the second term to the fourth term on the righthand side.

Meanwhile, the order for calculating the high-order parity OR, the high-order first logical AND, and the p−1 high-order second logical ANDs may not be the order described above.

Next, the XOR of the high-order parity OR, high-order first logical AND and p−1 high-order second logical ANDs obtained as described above is obtained. The value of the XOR obtained in this way is the prediction result of the high-order parity value. This procedure corresponds to, in the formula [36], the XOR operation of each term from the first term to the fifth term on the righthand side.

Meanwhile, [2.3.3.1. Prediction of the parity value for each data unit of the partial multiplication result] in [2.3.3. Prediction of middle-order parity] may be viewed in a similar manner to the case [2.2] described above.

First, the prediction of first partial is performed, for example, according to the following procedure, based on the value of each of the first multiplicand data unit and the r-th multiplier data unit (here, r is a natural number from 1 through q) and their parity value and expanding the formula [32] or the formula [35].

First, the OR of the parity value of the first multiplicand data unit and the parity value of the r-th multiplier data unit is obtained. The value of the OR is referred to as the “low-order partial parity OR”. Meanwhile, this procedure corresponds to, in the formula [32], the logical operation of the first term among the terms connected by “+” symbols in the righthand side.

Next, the logical and of the value of the highest order bit in the first multiplicand data unit and the value of the second digit from the lower order in the r-th multiplier data unit is obtained. The value of the logical AND is referred to as the “low-order partial first logical AND”. Meanwhile, this procedure corresponds to the logical operation of the second term on the righthand side in the formula [32].

Next, the logical AND of the XOR of the values of the respective bits for g digits (here, g is a natural number from 2 to p−1) from the higher order in the first multiplicand unit and the value of the bit at the g+1 digit from the lower order in the r-th multiplier data unit is obtained respectively. Since there are p−2 values that g mentioned above may take, there are p−2 values of the logical AND as well. The value of the logical AND is referred to as the “low-order partial second logical AND”. Meanwhile, this procedure corresponds to, in the formula [32], the logical operation of each term from the third term to the fourth term on the righthand side.

Meanwhile, the order for calculating the low-order partial parity logical AND, the low-order partial first logical AND, and the p−2 low-order partial second logical ANDs may not be the order described above.

Next, the XOR of the low-order partial parity logical AND, low-order partial first logical AND and p−2 low-order partial second logical ANDs obtained as described above is obtained. The value of the XOR obtained in this way is the prediction result of the parity value for the first partial. This procedure corresponds to, in the formula [32], the XOR operation of each term from the first term to the fourth term on the righthand side.

Meanwhile, the parity value of the, q+1-th partial is performed according to the following procedure, based on the value for each of the q-th multiplicand data unit and the r-th multiplier data unit and their parity value and expanding the formula [33] or the formula [36].

First, the OR of the parity value of the q-th multiplicand data unit and the parity value of the r-th multiplier data unit is obtained. The value of the OR is referred to as the “high-order partial parity OR”. Meanwhile, this procedure corresponds to, in the formula [33], the logical operation of the first term in the respective terms connected by the “+” symbol on the righthand side.

Next, the logical AND of the value of the lowest-order bit in the q-th multiplicand data unit and the value of the highest-order bit in the r-th multiplier data unit is obtained. The value of the logical AND is referred to as the “high-order partial first logical AND”. Meanwhile, this procedure corresponds to, in the formula [33], the logical operation of the fifth term on the righthand side.

Next, the logical and of the XOR of the value of the respective bits for h digits (here, h is a natural number from 2 through p from the lower order in the q-th multiplicand data unit and the value of the bit at the h-th digit from the higher order in the q-th multiplier data unit is obtained respectively. Since there are p−1 values, that h may take, p−1 values of the logical AND are obtained as well. The value of the logical and is referred to as the “high-order partial second logical AND”. Meanwhile, this procedure corresponds to, in the formula [33], the logical operation of each term from the second term to the fourth term on the righthand side.

Meanwhile, the order for calculating the high-order partial parity logical AND, the high-order partial first logical AND, and the p−1 high-order partial second logical ANDs may not be the order described above.

Next, the XOR of the high-order partial parity logical AND, high-order partial first logical AND and p−1 high-order partial second logical ANDs obtained as described above is obtained. The value of the XOR obtained in this way is the prediction result of the parity value for the q+1-th partial. This procedure corresponds to, in the formula [33], the XOR operation of each term from the first term to the fifth term on the righthand side.

Furthermore, the prediction of the parity value of the k-th partial (here, k is a natural number from 2 through q) is performed, for example, according to the following procedure and expanding the formula [34] or the formula [37].

First, the OR of the parity value of the k-th multiplicand data unit and the parity value of the r-th multiplier data unit is obtained. The value of the OR is referred to as the “middle-order partial parity OR”. Meanwhile, this procedure corresponds to, in the formula [34], the logical operation of the first term among the terms connected by “+” symbols in the righthand side.

Next, the logical and of the value of the highest order bit in the k-th multiplicand data unit and the value of the second digit from the lower order in the r-th multiplier data unit is obtained. The value of the logical AND is referred to as the “middle-order partial first logical AND”. Meanwhile, this procedure corresponds to the logical operation of the second term on the righthand side in the formula [34].

Next, the logical AND of the XOR of the values of the respective bits for m digits (here, m is a natural number from 2 to p−1) from the higher order in the k-th multiplicand unit and the value of the bit at the m+1 digit from the lower order in the r-th multiplier data unit is obtained respectively. Since there are p−2 values that m mentioned above may take, there are p−2 values of the logical AND as well. The value of the logical AND is referred to as the “middle-order partial second logical AND”. Meanwhile, this procedure corresponds to, in the formula [34], the logical operation of each term from the third term to the fourth term on the righthand side.

Next, the logical AND of the value of the highest-order bit in the k−1-th multiplicand data unit and the value of the bit at the second digit from the lower order in the r-th multiplier data unit is obtained. The value of the logical AND is referred to as the “middle-order partial third logical AND”. Meanwhile, this procedure corresponds to, in the formula [34], the logical operation of the fifth term on the righthand side.

Next, the logical AND of the XOR of the values of the respective bits for n digits (here, n is a natural number from 2 to p−1) from the higher order in the k-th multiplicand unit and the value of the bit at the n+1 digit from the lower order in the r-th multiplier data unit is obtained respectively. Since there are p−2 values that n mentioned above may take, there are p−2 values of the logical AND as well. The value of the logical AND is referred to as the “middle-order partial fourth logical AND”. Meanwhile, this procedure corresponds to, in the formula [34], the logical operation of each term from the sixth term to the seventh term on the righthand side.

Meanwhile, the order for calculating the middle-order partial parity logical AND, the middle-order partial first logical AND, p−2 middle-order partial second logical ANDs, the middle-order partial third logical AND and the p−2 middle-order partial fourth logical ANDs may not be the order described above.

Next, the XOR of the middle-order partial parity logical AND, the middle-order partial first logical AND, p−2 middle-order partial second logical ANDs, the middle-order partial third logical AND and the p−2 middle-order partial fourth logical ANDs described as descried above is obtained. The value of the XOR obtained in this way is the prediction result of the parity value for the k-th partial. Meanwhile, this procedure corresponds to, in the formula [34], the XOR operation of each term from the first term through the seventh term on the righthand side.

Next, [2.3.3.2. Prediction of the middle-order parity based on the prediction result of the parity value for each data unit of the partial multiplication result] in the case of odd-number parity is explained.

First, by executing the procedure described so far for all the values that the variable r may take, the parity predicted value for each data unit of the first partial multiplication result through the r-th partial multiplication result is obtained. The prediction of the middle-order parity value for each data unit constituting the multiplication result Z is performed by selecting parity predicted values for each data unit of these partial multiplication results according to a prescribed rule and obtaining the XOR of the selected parity predicted values. However, as described above, it is noted that in odd-number parity, in obtaining the parity value in odd-number parity for each data unit of the multiplication result Z from the XOR of even numbers of the blocks, the XOR with the value “1” needs to be obtained further.

First, among the data units constituting the multiplication result Z, the prediction method of the parity value of the s-th multiplication result (here, s is a natural number from 2 through q) is explained.

The prediction of the parity value of the s-th multiplication result data unit may be viewed in a similar manner to the prediction of the parity value P_Z1 performed using the parity predicted value for the block B and the parity predicted value for the block C in FIG. 7 presented above. That is, the prediction of the parity value of the s-th multiplication result data unit is performed, for example, in the following procedure, in consideration of the formula [39].

First, the parity predicted value of the s-u+1 partial of the u-th partial multiplication result (here, u is a natural number from 1 through s) is selected. Since there are s values that u mentioned above may take, s parity predicted values are selected. Then, the XOR of the s parity predicted values is obtained. Here, when s is an odd number, the value of the XOR obtained in this way is the predicted result of the parity value of the s-th multiplication result data unit. In contrast, when s is an even number, the XOR operation result of the XOR obtained in this way and the value “1” is the prediction result of the parity value of the s-th multiplication result data unit.

Next, among the data units constituting the multiplication result Z, the prediction method of the parity value of the t-th multiplication result (here, t is a natural number from q+1 through 2q−1) is explained.

The prediction of the parity value of the t-th multiplication result data unit may be viewed in a similar manner to the prediction of the parity value P_Z2 performed using the parity predicted value for the block D and the parity predicted value for the block E in FIG. 7 presented above. That is, the prediction of the parity value of the t-th multiplication result data unit is performed, for example, in the following procedure, in consideration of the formula [40].

First, the parity predicted value of the t-v+1 partial of the u-th partial multiplication result (here, v is a natural number from t-q through q) is selected. Since there are 2q-t+1 values that v mentioned above may take, 2q-t+1 parity predicted values are selected. Then, the XOR of the s parity predicted values is obtained. When 2q-t+1 is an odd number, the value of the XOR obtained in this way is the predicted result of the parity value of the t-th multiplication result data unit. In contrast, when 2q-t+1 is an even number, the XOR operation result of the XOR obtained in this way and the value “1” is the prediction result of the parity value of the t-th multiplication result data unit.

The prediction of the middle-order parity value for each data unit from the second multiplication result data unit through the 2q−1 multiplication result data is performed as described above.

### 3. Configuration of an Arithmetic Operation Processing Apparatus Having the Malfunction Detection Function

Next, an arithmetic operation processing apparatus including a Carry-Less multiplier having the malfunction detection function is explained.

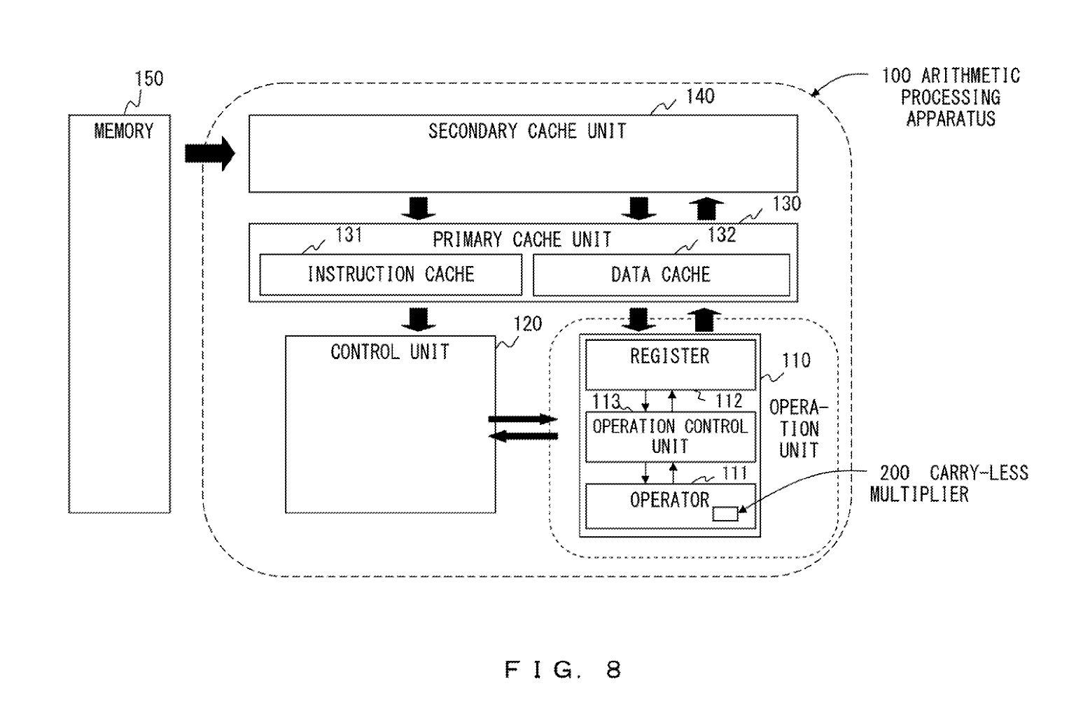

FIG. 8 is a configuration diagram of an example of an arithmetic operation processing apparatus. The arithmetic operation processing apparatus 100 includes an operation unit 110, a control unit 120, a primary cache unit 130, and a secondary cache unit 140, and is used while a memory 150 is connected.

The operation unit 110 performs various operations with respect to input data according to the control by the control unit 120, and outputs data obtained as a result of the arithmetic operation. The operation unit 110 includes an operator 111, a register 112, and the operation control unit 113.

The operator 111 is hardware that performs various arithmetic operations and logical operations. The operator 111 has a Carry-Less multiplier 200 described later.

The register 112 keeps data temporarily to give/receive data input to the operation unit 110 and data output from the operation unit 110 to/from the primary cache unit 130.

The operation control unit 113 controls the operation of the operator 111 and the register 112 according to the control by the control unit 120.

The control unit 120 reads out instruction data kept in the primary cache unit 130 in a prescribed order, and controls the operation unit 110 to make it perform various operations according to the read-out instruction data.

The primary cache unit 130 is a high-speed memory for accumulating frequently-used data. The primary cache unit 130 has an instruction cache 131 for accumulating instruction data and a data cache 132 for accumulating input data to the operator 111 and output data from the operator 111.

The secondary cache unit 140 is a low-speed memory with a larger capacity than that of the primary cache unit 130 for accumulating frequently-used data that are not accumulated in the primary cache unit 130 among data accumulated in the memory 150.

The memory data stores instruction data expressing an instruction of operation for the arithmetic operation processing apparatus and input data to the operator 111 and output data from the operator 111.

### 3.1. Configuration of the Carry-Less Multiplier in the Case without Consideration of the Data Unit

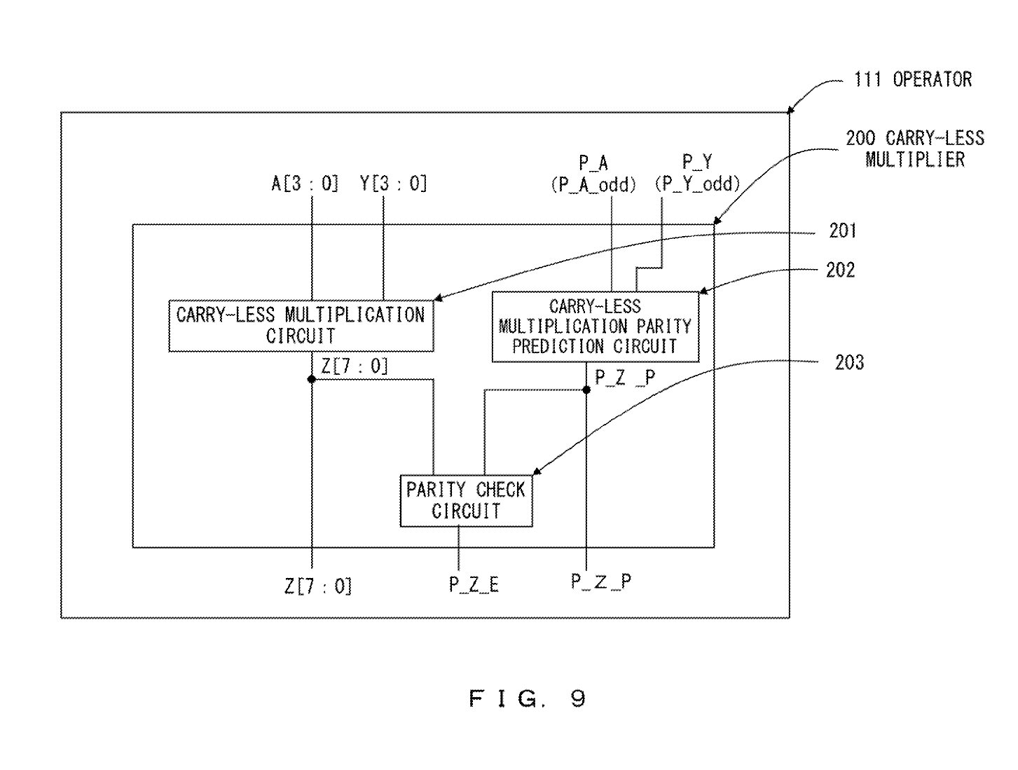

Next, FIG. 9 is explained. FIG. 9 is a configuration diagram of the first example of a Carry-Less multiplier provided as apart of the operator 111 in the arithmetic operation processing apparatus 100 in FIG. 8. The Carry-Less multiplier 200 has the malfunction detection function explained in [1. parity prediction of a multiplication result data string without considering the data unit].

The Carry-Less multiplier 200 in FIG. 9 has a Carry-Less multiplication circuit 201, a Carry-Less multiplication parity prediction circuit 202, and a parity check circuit 203.

The Carry-Less multiplication circuit 201 is a circuit that performs the Carry-Less multiplication of the multiplicand A and the multiplier Y that are both 4-bit data and outputs the multiplication result Z, which is a circuit that performs the operation of the formula [1].

The Carry-Less multiplication parity prediction circuit 202 is a circuit that performs, in the case of even-number parity, the prediction of the predicted value P_Z_P of the multiplication result Z from the even-parity value P_A of the multiplicand A and the even-parity value P_Y of the multiplier Y. In addition, it is a circuit that performs, in the case of odd-number parity, the prediction of the predicted value P_Z_P of the multiplication result Z from the odd-number parity value P_A_odd of the multiplicand A and the even-number parity value P_Y_odd.

The parity check circuit 203 is a circuit that obtains the parity value P_Z of the multiplication result Z that the Carry-Less multiplication circuit 201 outputs and judges whether or not it matches the prediction of the predicted value P_Z_P being the Carry-Less multiplication parity prediction circuit 202.

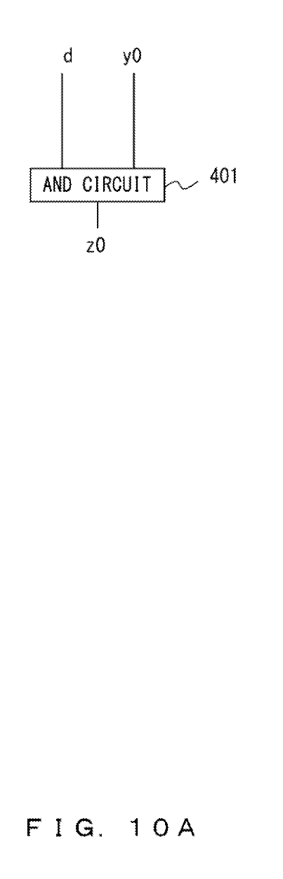

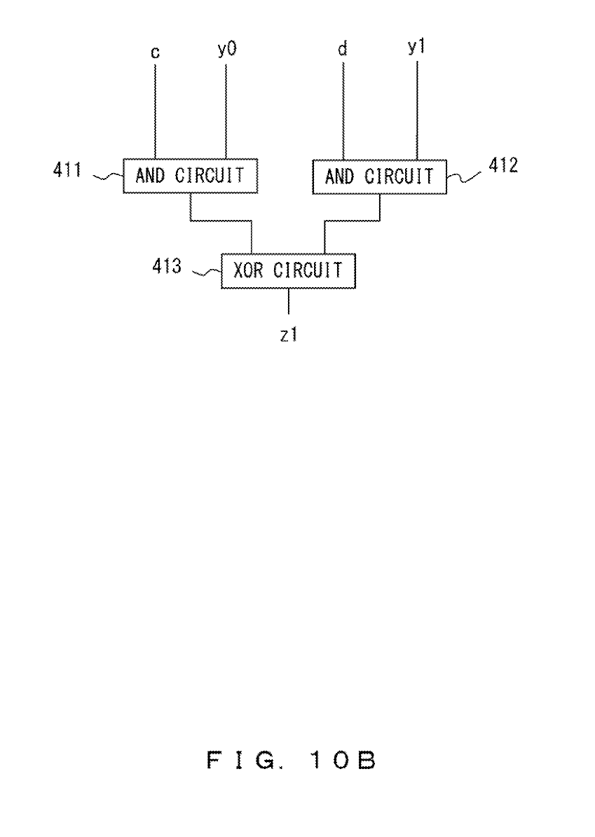

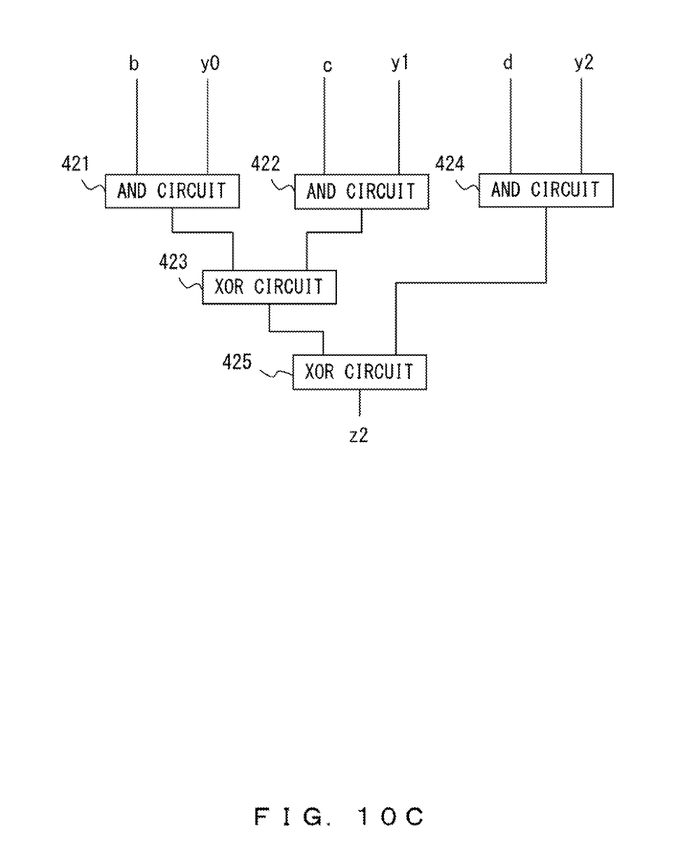

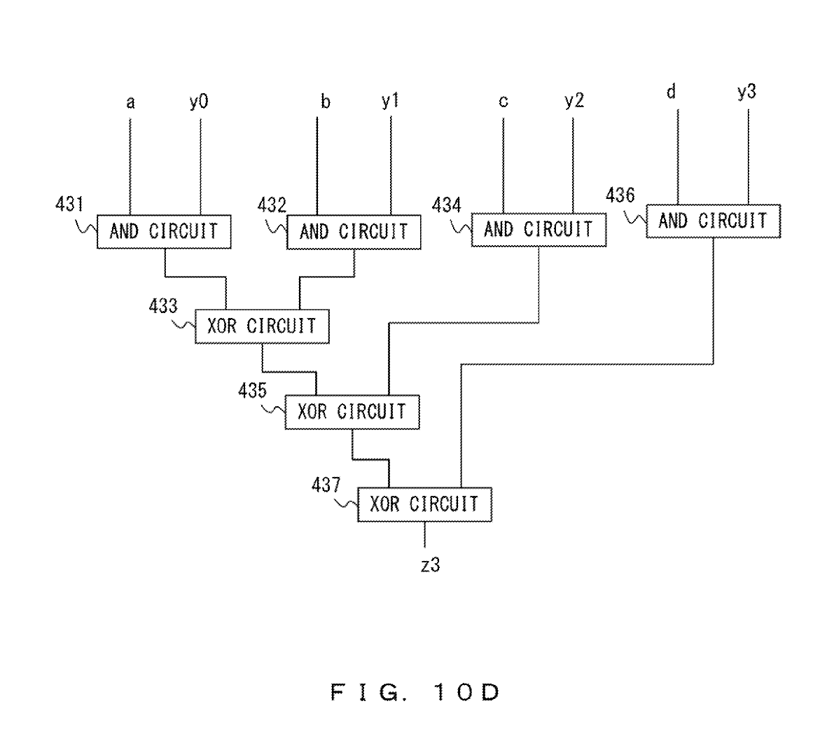

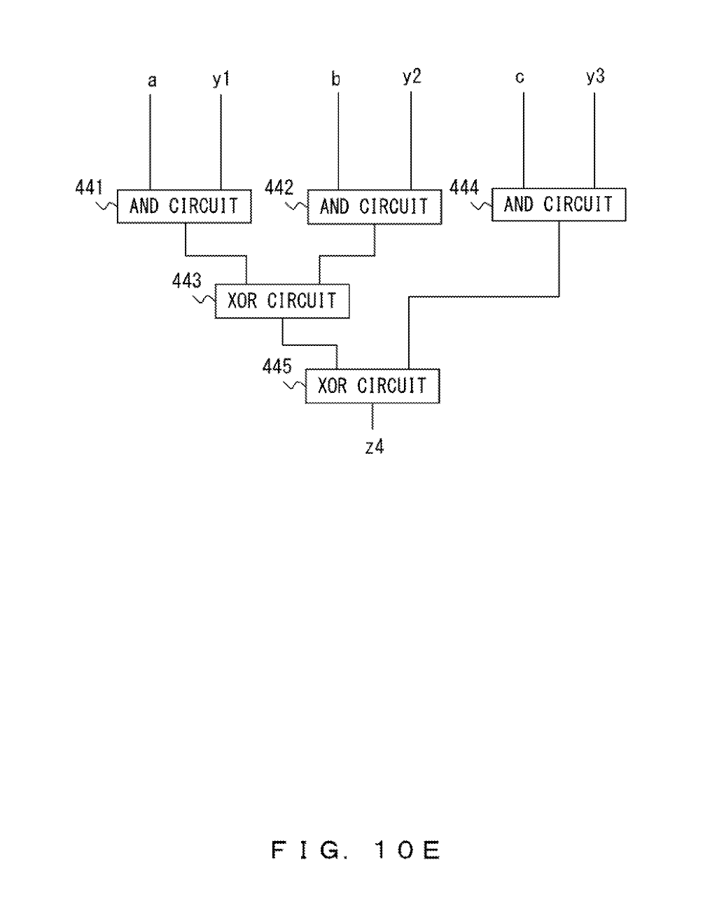

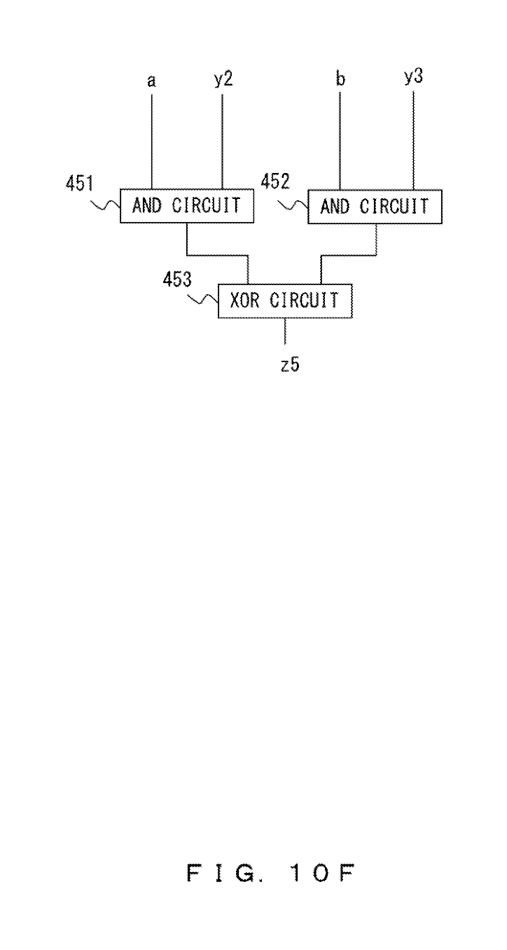

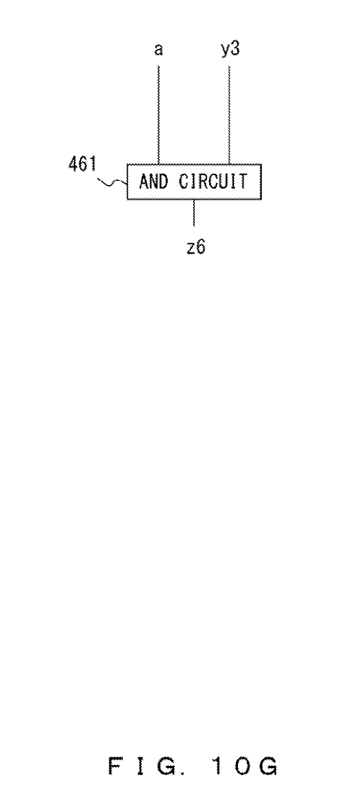

Next, the configuration of the Carry-Less multiplication circuit 201 is explained. The specific circuit configuration of the Carry-Less multiplication circuit 201 in FIG. 9 is presented in each diagram from FIG. 10A through FIG. 10G.

The circuit in each diagram from FIG. 10A through FIG. 10G is a circuit that performs the Carry-Less multiplication of the respective bits a, b, c, and d of the multiplicand A and the respective bits y3, y2, y1, and y0 of the multiplier Y to obtain the value of the respective bits z6, z5, z4, z3, z2, z1, and z0 the multiplication result Z. Meanwhile, the bit z7 of the multiplication result Z is omitted since its value is always “0”.

The circuit in FIG. 10A is a circuit that makes the output when the bit d and y0 are input respectively to the AND circuit (logical AND circuit) 401 become the value of the bit z0, which is a circuit that performs the operation of the first expression in the formula [1] presented above.

The circuit in FIG. 10B first obtains the output obtained by inputting the output obtained by inputting the values of the bit candy° respectively to the AND circuit 411, and the output obtained by inputting the values of the bit d and y1 respectively to the AND circuit 412 into the XOR circuit (exclusive OR circuit) 413. Then, the output of the XOR circuit 413 becomes the value of the bit z1. The circuit in FIG. 10B is a circuit that performs the second expression in the formula [1] presented above.

The circuit in FIG. 10C first obtains the output obtained by inputting the output obtained by inputting the values of the bit b and y0 respectively to the AND circuit 421, and the output obtained by inputting the values of the bit c and y1 respectively to the AND circuit 422 into the XOR circuit 423. Then, the value obtained by inputting the output of the XOR circuit 423 and the output obtained by inputting the values of the bit d and y2 respectively to the AND circuit 424 to the XOR circuit 425 becomes the value of the bit z2. The circuit is a circuit that performs the third expression in the formula [1] presented above.

The circuit in FIG. 10D first obtains the output obtained by inputting the output obtained by inputting the values of the bit a and y0 respectively to the AND circuit 431, and the output obtained by inputting the values of the bit b and y1 respectively to the AND circuit 432 into the XOR circuit 433. Then, the value obtained by inputting the output of the XOR circuit 433 and the output obtained by inputting the values of the bit c and y2 respectively to the AND circuit 434 to the XOR circuit 435 becomes the value of the bit z3. The circuit is a circuit that performs the fourth expression in the formula [1] presented above.

The circuit in FIG. 10E first obtains the output obtained by inputting the output obtained by inputting the values of the bit a and y1 respectively to the AND circuit 441, and the output obtained by inputting the values of the bit b and y2 respectively to the AND circuit 442 into the XOR circuit 443. Then, the value obtained by inputting the output of the XOR circuit 443 and the output obtained by inputting the values of the bit c and y3 respectively to the AND circuit 444 to the XOR circuit 445 becomes the value of the bit z4. The circuit is a circuit that performs the fifth expression in the formula [1] presented above.

The circuit in FIG. 10F first obtains the output obtained by inputting the output obtained by inputting the values of the bit a and y2 are respectively to the AND circuit 451, and the output obtained by inputting the values of the bit b and y3 respectively to the AND circuit 432 into the XOR circuit 453. Then, the outpour of the XOR circuit 435 becomes the value of the bit z5. The circuit is a circuit that performs the sixth expression in the formula [1] presented above.

FIG. 10G is a circuit that makes the output obtained by inputting the values of the bit a and y3 respectively to the AND circuit 461 become the value of the bit z6, which is a circuit that performs the operation of the seventh expression in the formula [1] presented above.

The Carry-Less multiplication circuit 201 in FIG. 9 is configured as described above.

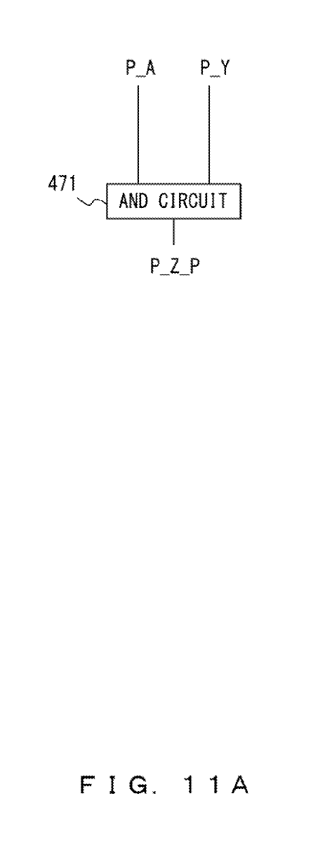

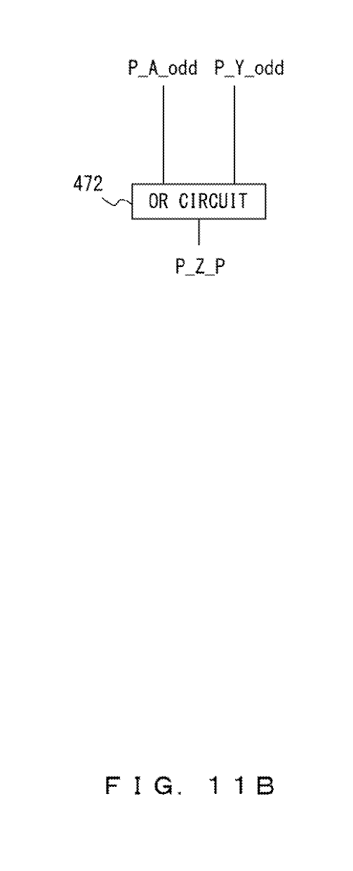

Next, the configuration of the Carry-Less multiplication parity prediction circuit 202 in FIG. 9 is explained. The specific circuit configuration of the Carry-Less multiplication parity prediction circuit 202 in FIG. 9 is presented in FIG. 11A and FIG. 11B.

The circuit in the first example illustrated in FIG. 11A is a circuit in a case in which even-number parity is used as the parity value, and the circuit in the second example illustrated in FIG. 11B is a circuit in a case in which odd-number parity is used as the parity value.

The circuit in FIG. 11A is a circuit that makes the output obtained by inputting the even-number parity value P_A of the multiplicand A and the even-number parity value P_Y of the multiplier Y are respectively input to the AND circuit 471 become the predicted value P_Z_P of the parity value for the multiplication result Z that the Carry-Less multiplication circuit 201. The circuit in FIG. 11A is the circuit that performs the operation in the formula [5] presented above.

The circuit in FIG. 11B is a circuit that makes the output obtained by inputting the odd-number parity value P_A_odd of the multiplicand A and the odd-number parity value P_Y_odd of the multiplier Y are respectively input to the OR circuit (logical addition circuit) 472 become the predicted value P_Z_P of the parity value for the multiplication result Z that the Carry-Less multiplication circuit 201. The circuit in FIG. 11A is the circuit that performs the operation in the formula [27] presented above.

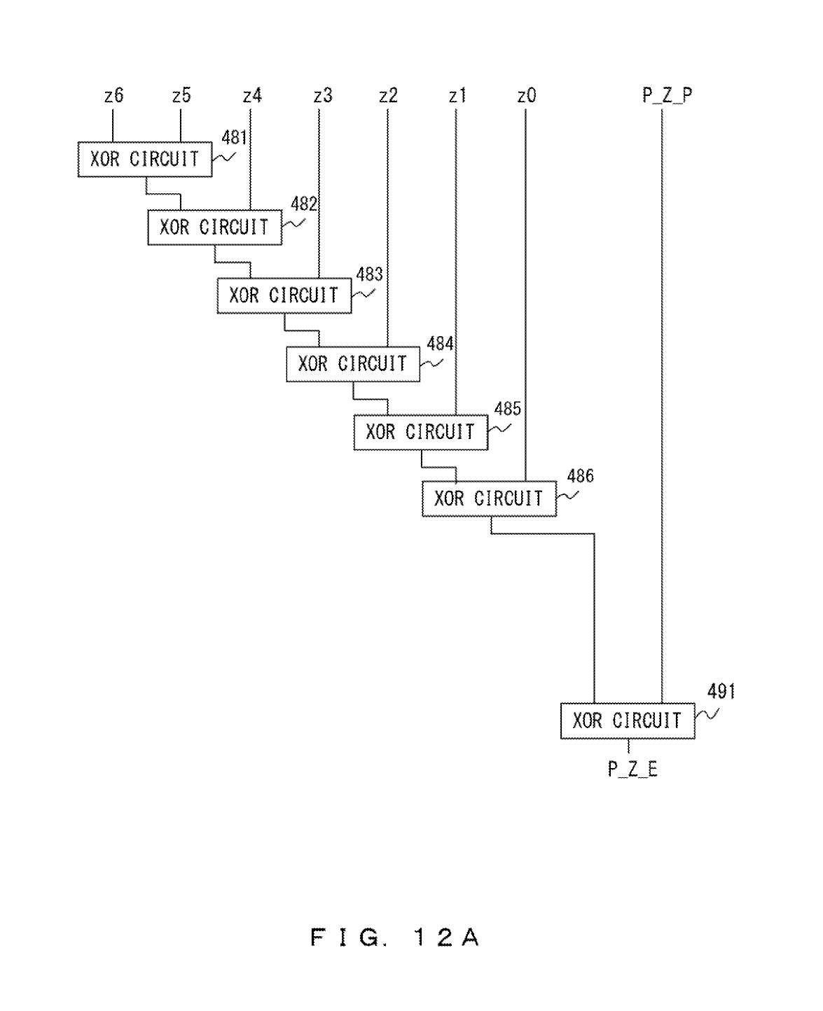

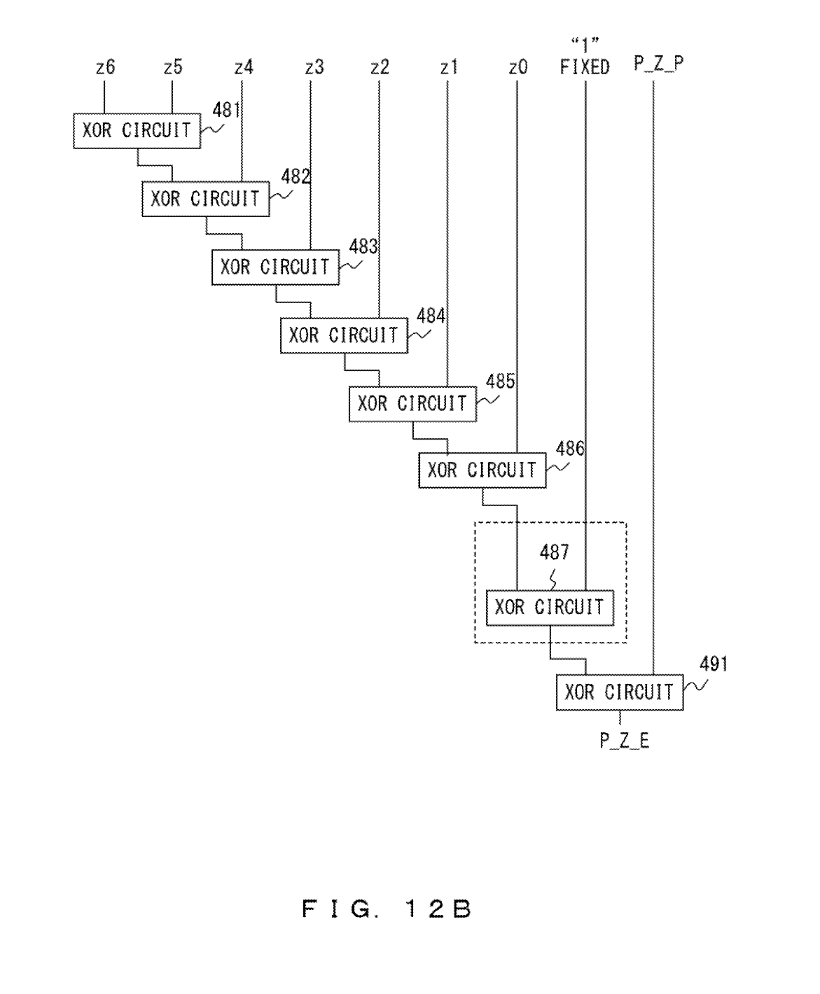

Next, the configuration of the parity check circuit 203 in FIG. 9 is explained. The specific circuit configuration of the parity check circuit 203 in FIG. 9 is presented in FIG. 12 and FIG. 12B.

The circuit in the first example illustrated in FIG. 12A is a circuit in a case in which even-number parity is used as the parity value, and the circuit in the second example illustrated in FIG. 121B is a circuit in a case in which odd-number parity is used as the parity value.

The circuit in FIG. 12A first obtains the parity value P_Z of the multiplication result Z that the Carry-Less multiplication circuit 201 outputs. For this purpose, first, the output by inputting the values of the bits z6 and z5 are respectively input to the XOR circuit 481 is obtained. Next, the output by inputting the output of the XOR circuit 481 and the value of the bit z4 respectively into the XOR circuit 482 is obtained. Next, the output by inputting the XOR circuit 482 and the value of the bit z3 respectively into the XOR circuit 483 is obtained. Next, the output by inputting the output of the XOR circuit 483 and the value of the bit z2 respectively into the XOR circuit 484 is obtained. Next, the output by inputting the output of the XOR circuit 484 and the value of the bit z1 respectively into the XOR circuit 485 is obtained. Then, the output by inputting the output of the XOR circuit 485 and the value of the bit z0 respectively into the XOR circuit 486 is obtained. The output of the XOR circuit 486 is the parity value P_Z. The circuit configuration so far is the circuit that performs the operation of the formula [2] presented above.

Meanwhile, instead of the configuration as described above using the 2-input XOR circuits 481-486, using a 7-input XOR circuit, the output by inputting the respective values of the bits z6-z0 to the XOR circuit may be the parity value P_Z.

In the circuit in FIG. 12A, whether or not the parity value P_Z obtained as described above matches the predicted value P_Z_P being the output of the Carry-Less multiplication parity prediction circuit 202 is judged. For this purpose, the output by inputting output of the XOR circuit 486 (that is, the parity value P_Z) and the predicted value P_Z_P into the XOR circuit 491 is obtained. Then, the output of the XOR circuit 491 is output as the check result P_Z_E. The check result P_Z_E takes the value “0” or “1”, and when the value is “1”, it represents that the malfunction of the Carry-Less multiplier has been detected.

Meanwhile, instead of the configuration as described above using the 2-input XOR circuits 481-486, using a 8-input XOR circuit, the output by inputting the respective values of the bits z6-z0 and the predicted value P_Z_P to the XOR circuit may be the check result P_Z_E.

Next, the circuit in FIG. 12B is explained. In the circuit in FIG. 12B, the configuration from the XOR circuit 481 to the XOR circuit 486 is similar to the configuration in FIG. 12A. However, in the circuit in FIG. 12B, the output by inputting the output of the XOR circuit 486 and the value “1” respectively into the XOR circuit 487 is obtained. The output of the XOR circuit 487 is the parity value P_Z. The circuit configuration so far is the circuit that performs the operation of the formula [24] presented above.

In the circuit in FIG. 12B, whether or not the parity value P_Z obtained as described above matches the predicted value P_Z_P being the output of the Carry-Less multiplication parity prediction circuit 202 is judged. For this purpose, the output by inputting output of the XOR circuit 487 (that is, the parity value P_Z) and the predicted value P_Z_P into the XOR circuit 491 is obtained. Then, the output of the XOR circuit 491 is output as the check result P_Z_E. The check result P_Z_E takes the value “0” or “1”, and when the value is “1”, it represents that the malfunction of the Carry-Less multiplier has been detected.

Meanwhile, instead of the configuration as described above using the 2-input XOR circuits 481-487 and 491, using a 9-input XOR circuit, the output by inputting the respective values of the bits z6-z0, the value “1” and the predicted value P_Z_P to the XOR circuit may be the check result P_Z_E.

Meanwhile, in the circuit in FIG. 12B, instead of using the XOR circuit 487, using a NOT circuit (negative circuit), the output by inputting the output of the XOR circuit 486 into the NOT circuit may be the parity value P_Z.

### 3.2. Configuration of the Carry-Less Multiplier in the Case in which Both the Multiplicand Data String and the Multiplier Data String are Composed of One Data Unit

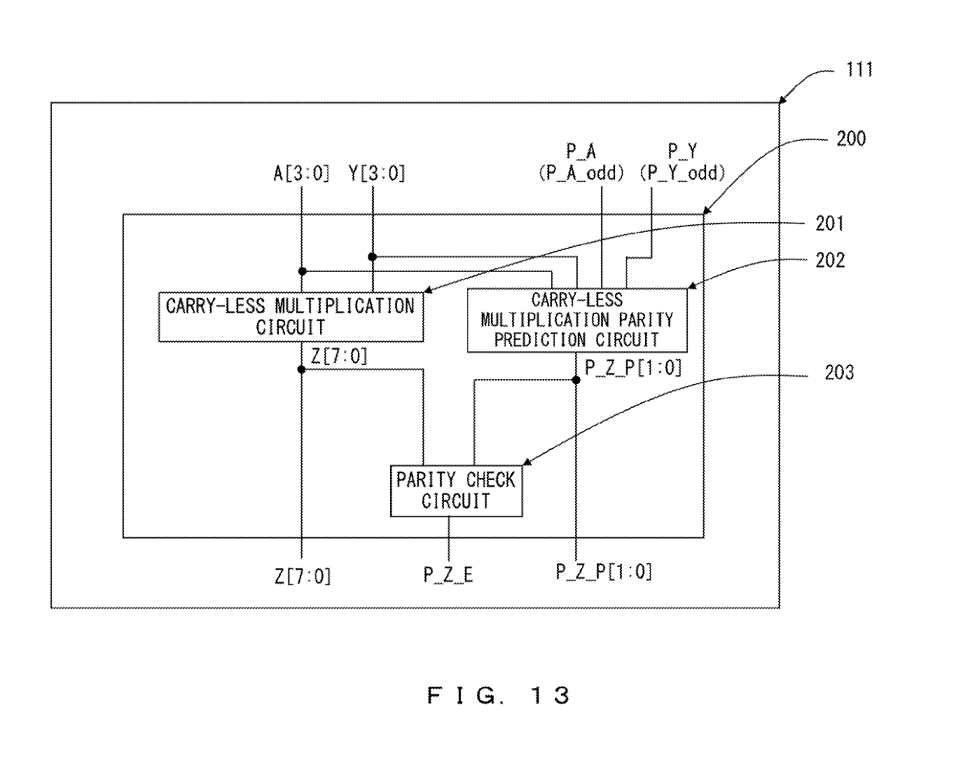

Next, FIG. 13 is explained. FIG. 13 is a configuration diagram of the second example of the Carry-Less multiplier provided as a part of the operator 111 in the arithmetic operation processing apparatus 100 in FIG. 8. The Carry-Less multiplier 200 has the malfunction detection function explained in [2.1. Case in which both the multiplicand data string and the multiplier data string are one data unit].

The configuration in FIG. 13 differs from the configuration of the first example illustrated in FIG. 9 in that the Carry-Less multiplication parity prediction circuit 202 performs the prediction of the parity value for each data unit of the multiplication result Z. That is, the Carry-Less multiplication parity prediction circuit 202 outputs the predicted value P_Z0_P of the first data unit from the lower order in the multiplication result Z, and the parity value P_Z1_P of the data following the first data unit from the lower order in the multiplication result Z. In addition, there is also a difference over the configuration of the first example illustrated in FIG. 9 that in the Carry-Less multiplication parity prediction circuit 202 in FIG. 13, for the prediction of the parity value, the respective values of the multiplicand A and the multiplier Y are used as well as the respective parity values of the multiplicand A and the multiplier Y.

The Carry-Less multiplication circuit 201 in FIG. 13 is the same as that in the first example illustrated in FIG. 9, and explanation for detailed configuration is omitted.

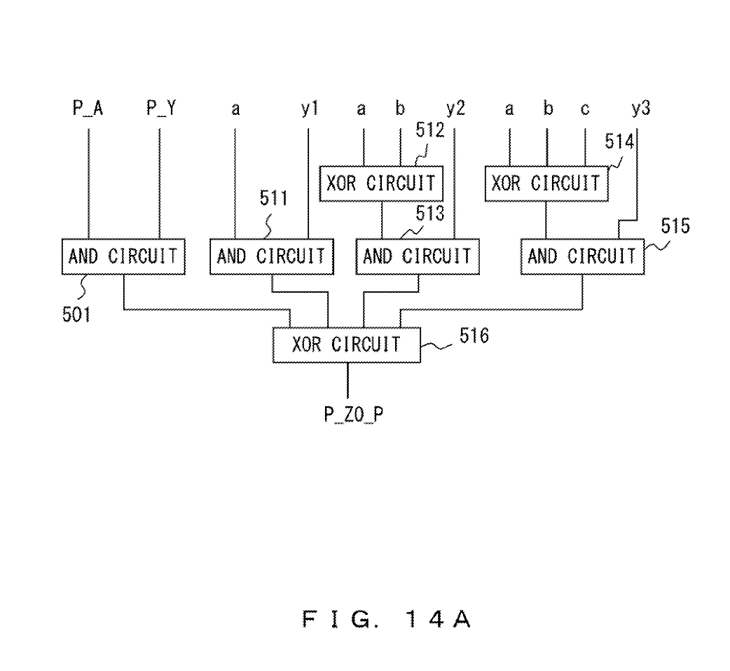

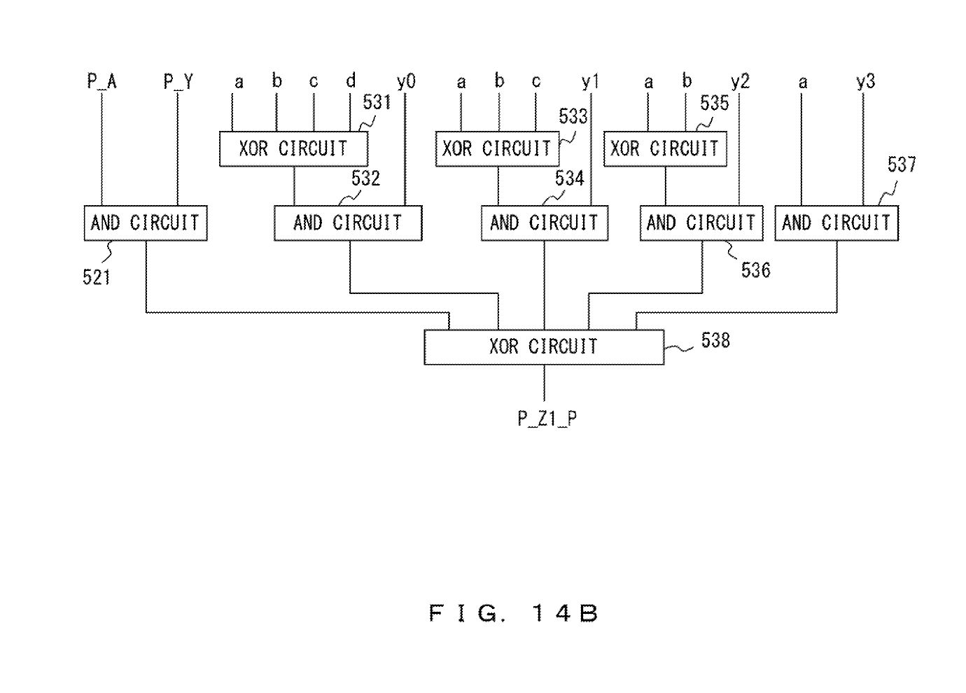

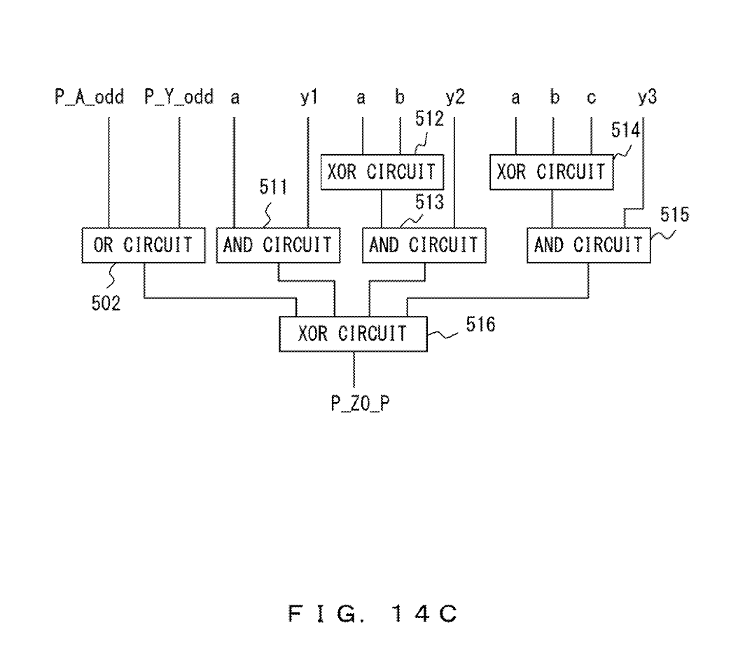

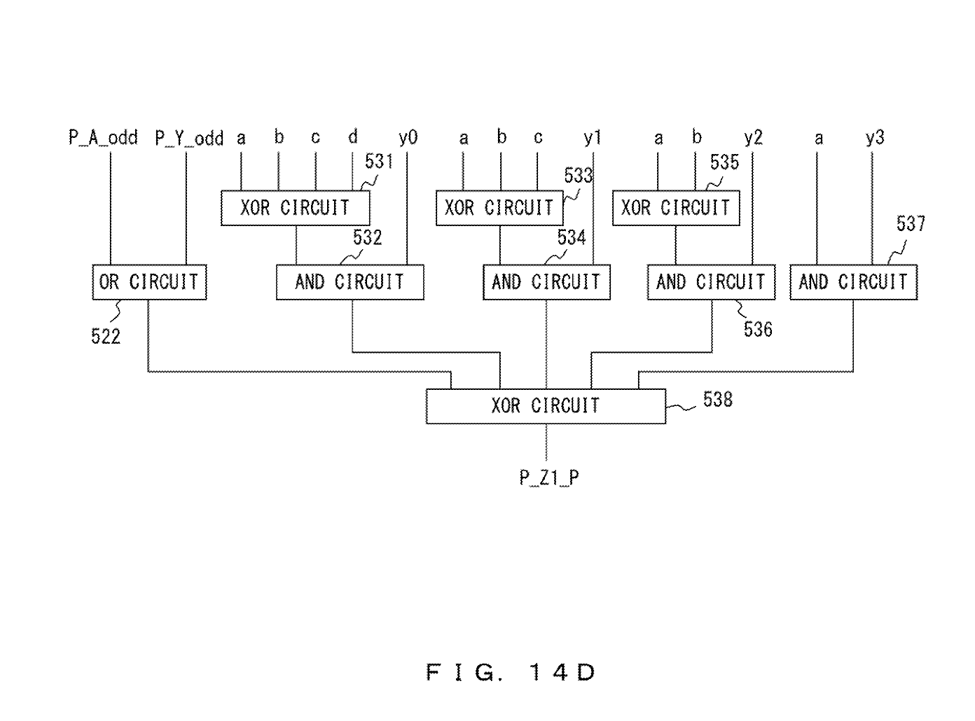

Next, the configuration of the Carry-Less multiplication parity prediction circuit 202 in FIG. 13 is explained. The specific circuit configuration of the Carry-Less multiplication parity prediction circuit 202 in FIG. 13 is presented in FIG. 14A, FIG. 14B, FIG. 14C, and FIG. 14D.

The circuit in the first example illustrated in FIG. 14A and FIG. 14B is a circuit in a case in which even-number parity is used as the parity value, and the circuit in the second example illustrated in FIG. 14C and FIG. 14D is a circuit in a case in which odd-number parity is used as the parity value.

The circuit in FIG. 14A obtains the predicted parity value P_Z0_P of the parity value of the first data unit from the lower order in the multiplication result Z that the Carry-Less multiplication circuit 201 outputs, from the value and the parity value and the multiplicand A and the value and the parity value of the multiplier Y.

In FIG. 14A, an AND circuit 501 is a circuit that performs the operation of the first term of the righthand side of the formula [11] connected by the “+” symbol, that is, P_A*P_Y. Meanwhile, the AND circuit 511 is a circuit that performs the operation of the second term of the righthand side of the formula [11], that is, a*y1. Furthermore, the XOR circuit 512 and the AND circuit 513 are circuits that perform the operation of the third term of the righthand side of the formula [11], that is, (a+b)*y2. Then, the XOR circuit 514 and the AND circuit 515 are circuits that perform the operation of the fourth term of the righthand side of the formula [11], that is, (a+b+c)*y3. Then, the XOR circuit 516 is a circuit that performs the operation of the XOR of the respective terms from the first term through the fourth term of the righthand side of the formula [11], to obtain the parity predicted value P_Z0_P.

The circuit in FIG. 14B is a circuit that obtains the predicted parity value P_Z1_P of the parity value of data following the first data unit from the lower order in the multiplication result Z that the Carry-Less multiplication circuit 201 outputs, from the value and the parity value and the multiplicand A and the value and the parity value of the multiplier Y. The circuit in FIG. 14B is a circuit that performs the operation of the formula [12] presented above.

In FIG. 14B, an AND circuit 521 is a circuit that performs the operation of the first term of the righthand side of the formula [12] connected by the “+” symbol, that is, P_A*P_Y. Meanwhile, the XOR circuit 531 and the AND circuit 532 are circuits that perform the operation of the second term of the righthand side of the formula [12], that is, (a+b+c+d)*y0. Furthermore, the OR circuit 533 and the AND circuit 534 are circuits that perform the operation of the third term of the righthand side of the formula [12], that is, (a+b+c)*y1. Then, the XOR circuit 534 and the AND circuit 515 are circuits that perform the operation of the fourth term of the righthand side of the formula [12], that is, (a+b+c)*y3. In addition, the AND circuit 537 is a circuit that performs the operation of the fifth term of the righthand side of the formula [12], that is, a*y3. Then, the XOR circuit 537 is a circuit that performs the operation of the XOR of the respective terms from the first term through the fourth term of the righthand side of the formula [11], to obtain the parity predicted value P_Z1_P.

The circuit in FIG. 14C is a circuit that obtains the predicted parity value P_Z0_P of the parity value of the first data unit from the lower order in the multiplication result Z that the Carry-Less multiplication circuit 201 outputs, from the value and the parity value and the multiplicand A and the value and the parity value of the multiplier Y. The circuit in FIG. 14C is a circuit that performs the operation of the formula [30] presented above.

In the circuit in FIG. 14C, the AND circuit 501 in the circuit in FIG. 14A is substituted with the OR circuit 502. The OR circuit 502 is a circuit that performs the operation of the first term of the righthand side of the formula [30] connected by the “+” symbol, that is, P_A_odd̂P_Y_odd. Therefore, the XOR circuit 516 is, in FIG. 14C, a circuit that performs the XOR operation of the respective values through the first term through the fourth term to obtain the parity predicted value P_Z0_P.

The circuit in FIG. 14D is a circuit that obtains the predicted parity value P_Z1_P of the parity value of data following the first data unit from the lower order in the multiplication result Z that the Carry-Less multiplication circuit 201 outputs, from the value and the parity value and the multiplicand A and the value and the parity value of the multiplier Y. The circuit in FIG. 14D is a circuit that performs the operation of the formula [31] presented above.

In the circuit in FIG. 14D, the AND circuit 521 in the circuit in FIG. 14B is substituted with the OR circuit 522. The OR circuit 522 is a circuit that performs the operation of the first term of the righthand side of the formula [31] connected by the “+” symbol, that is, P_A_odd̂P_Y_odd. Therefore, the XOR circuit 538 is, in FIG. 14D, a circuit that performs the XOR operation of the respective values through the first term through the fourth term to obtain the parity predicted value P_Z1_P.

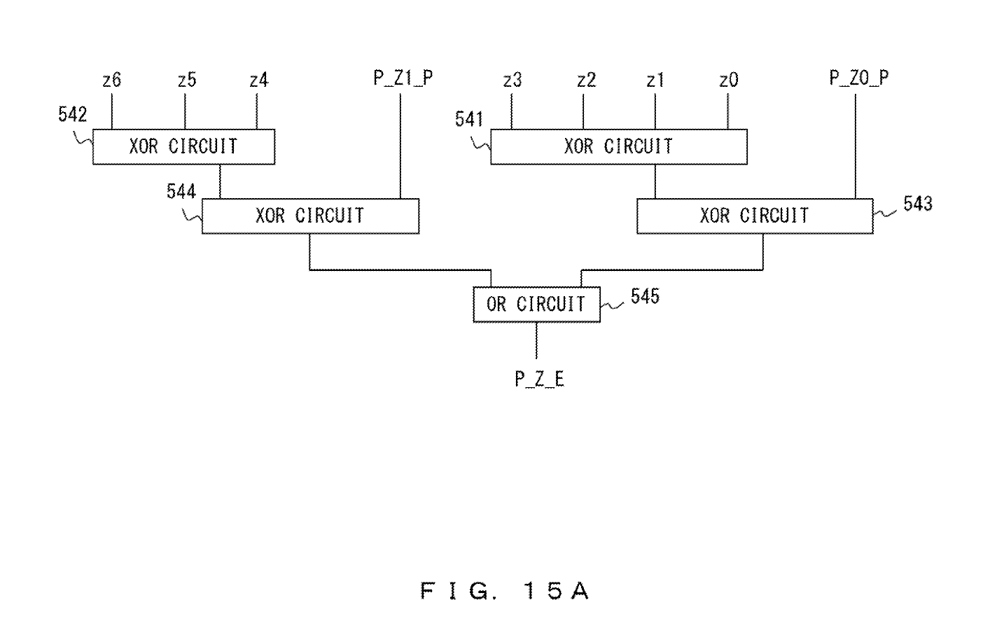

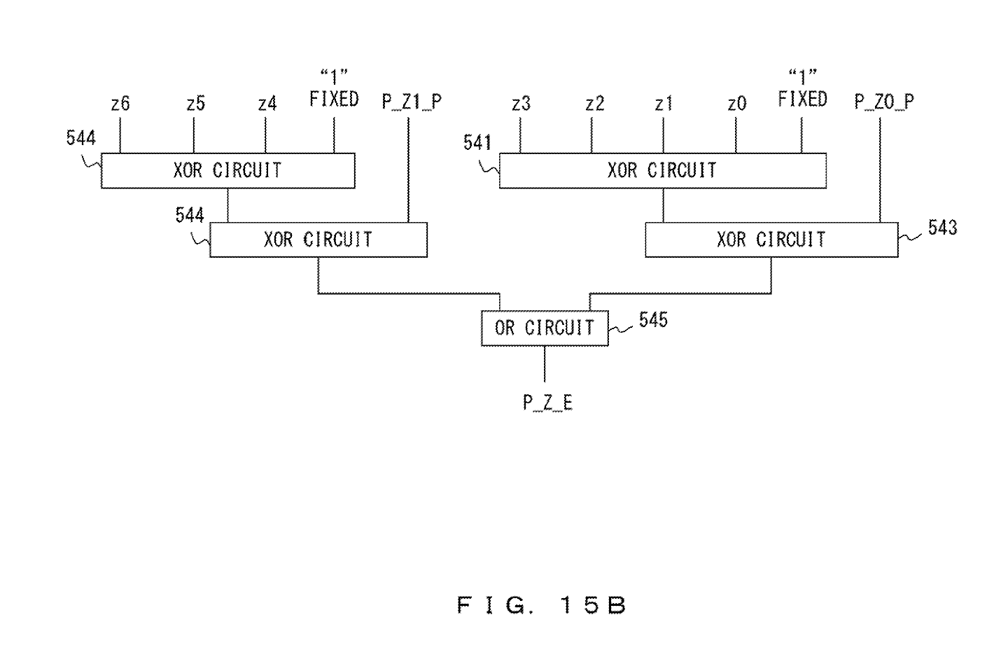

Next, the configuration of the parity check circuit 203 in FIG. 13 is explained. The specific circuit configuration of the parity check circuit 203 in FIG. 13 is presented in FIG. 15A and FIG. 15B.

The circuit in the first example illustrated in FIG. 15A is a circuit in a case in which even-number parity is used as the parity value, and the circuit in the second example illustrated in FIG. 15B is a circuit in a case in which odd-number parity is used as the parity value.

The circuit in FIG. 15A first obtains the parity value P_Z0 of the first data unit from the lower order and the parity value P_Z1 of the second data unit from the lower order of the multiplication result Z.

For this purpose, the circuit obtains the output by inputting the values of the bits z0, z1, z2, and z3 respectively into the XOR circuit 541. The output of the XOR circuit 541 is the parity value P_Z0. The circuit configuration is the circuit that performs the operation of the formula [6].

Meanwhile, the circuit in FIG. 15A obtains the output by inputting the values of the bits z4, z5, and z6 respectively into the XOR circuit 542. The output of the XOR circuit 542 is the parity value P_Z1. The circuit configuration is the circuit that performs the operation of the formula [7].

In the circuit in FIG. 15A, whether or not the parity value P_Z0 and P_Z1 obtained as described above respectively match the predicted values value P_Z0_P and P_Z1_P being the output of the Carry-Less multiplication parity prediction circuit 202 is judged. For this purpose, the output by inputting output of the XOR circuit 541 (that is, the parity value P_Z0) and the predicted value P_Z0_P into the XOR circuit 543 is obtained. Furthermore, the output by inputting output of the XOR circuit 542 (that is, the parity value P_Z1) and the predicted value P_Z1_P into the XOR circuit 544 is obtained. The output by inputting the output of the XOR circuit 543 and the XOR circuit 544 into the OR circuit 545 is obtained. Then, the output of the OR circuit is output as the check result P_Z_E. The check result P_Z_E takes the value “0” or “1”, and when the value is “1”, it represents that the malfunction of the Carry-Less multiplier has been detected.

Meanwhile, the circuit in FIG. 15B first obtains the odd-number parity value P_Z0_odd of the first data unit from the lower order of the multiplication result Z that the Carry-Less multiplication circuit 201 outputs and the odd-number parity value P_Z1_odd of the second data unit from the lower order of the multiplication result Z.

For this first, the circuit in FIG. 15B first obtains the output by inputting the values of the bits z0, z1, z2, and z3 and the value “1” respectively to the XOR circuit 541. The output of the XOR circuit 541 is the odd-number parity value P_Z0_odd. The circuit configuration is the circuit that performs the operation of the formula [28].

The circuit in FIG. 15B obtains the output by inputting the values of the bits z4, z5 and z6 and the value “1” respectively to the XOR circuit 542. The output of the XOR circuit 542 is the odd-number parity value P_Z1_odd. The circuit configuration is the circuit that performs the operation of the formula [29].

In the circuit in FIG. 15B, whether or not the parity value parity value P_Z0_odd and P_z1_odd obtained as described above respectively match the predicted values value P_Z0_P and P_Z1_P being the output of the Carry-Less multiplication parity prediction circuit 202 is judged. For this purpose, the output by inputting output of the XOR circuit 541 (that is, the parity value P_Z0_odd) and the predicted value P_Z0_P into the XOR circuit 543 is obtained. Furthermore, the output by inputting output of the XOR circuit 542 (that is, the parity value P_Z1) and the predicted value P_Z1_P into the XOR circuit 544 is obtained. The output by inputting the output of the XOR circuit 543 and the XOR circuit 544 into the OR circuit 545 is obtained. Then, the output of the OR circuit is output as the check result P_Z_E. The check result P_Z_E takes the value “0” or “1”, and when the value is “1”, it represents that the malfunction of the Carry-Less multiplier has been detected.

As described above, in this embodiment, the parity check circuit 203 obtains the parity value for each data unit of the multiplication result Z using the XOR circuit in either of the case using even-number parity and odd-number parity. Then, judgment of the match/mismatch of the obtained parity value of the multiplication result and the parity value of the multiplication result Z that the Carry-Less multiplication parity prediction circuit 202 outputs is performed for each data unit using the 2-input XOR circuit. Then the OR or the judgment results for each data unit is obtained using the OR circuit, which becomes the detection result of the malfunction of the Carry-Less multiplier 201.

### 3.3. Configuration of the Carry-Less Multiplier in a Case in which Both the Multiplicand Data String and the Multiplier Data String are Two Data

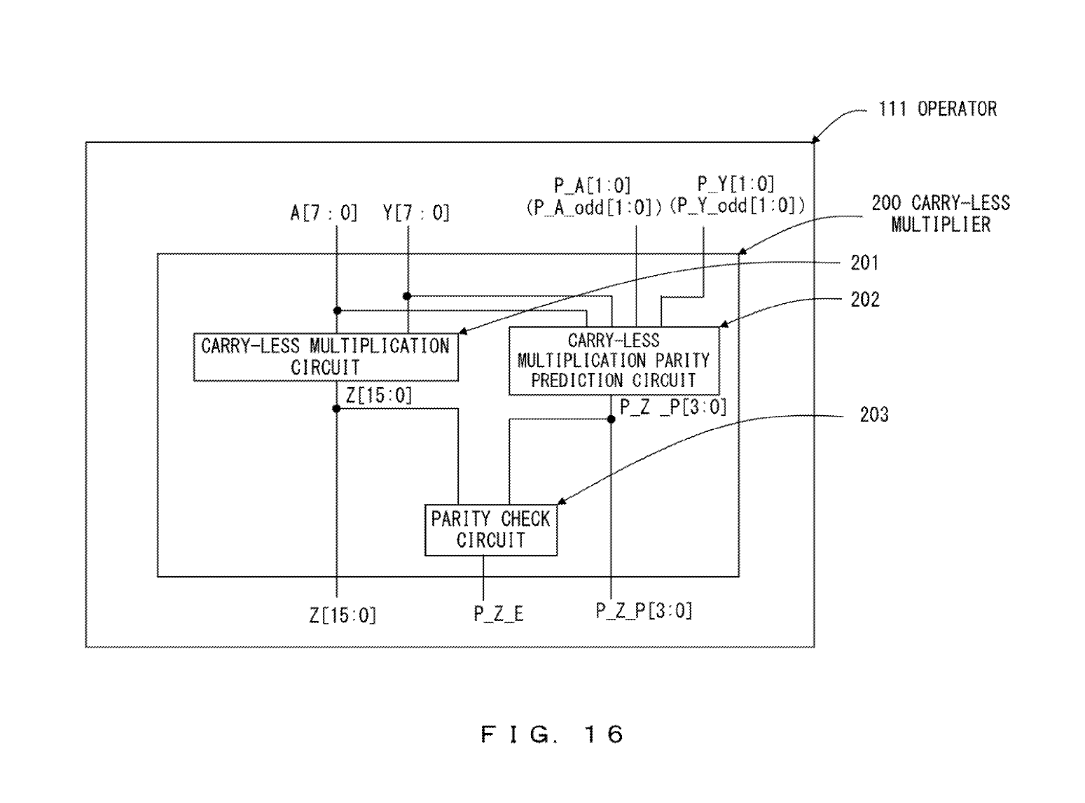

Next, FIG. 16 is explained. FIG. 16 is a configuration diagram of the third example of the Carry-Less multiplier provided as a part of the operation 11 in the arithmetic operation processing apparatus 100 in FIG. 8. The Carry-Less multiplier 200 has a malfunction detection function explained in [2.2. Case in which both the multiplicand data string and the multiplier data string are two data units].

In FIG. 16, the Carry-Less multiplication parity prediction circuit 202 outputs the predicted values P_Z0_P, P_Z1_P and P_Z2_P of the parity value of each data unit from the first to third from the lower value in the multiplication result Z. Furthermore, the Carry-Less multiplication parity prediction circuit 202 outputs the predicted value P_Z3_P of the parity value of the following data.

The Carry-Less multiplication parity prediction circuit 202 in FIG. 16 differs from the second example illustrated in FIG. 9 on this point. In addition, the Carry-Less multiplication parity prediction circuit 202 also differs from the one in the second example in that the value and the parity value for each data unit of the multiplicand A and the value and the parity value for each data unit of the multiplier Y are used.

The Carry-Less multiplication circuit 201 in FIG. 16 is a circuit that performs the Carry-Less multiplication of the multiplicand A and the multiplier Y and outputs the multiplication result Z. Here, the multiplicand A and the multiplier Y are both a data string in which two data units being 4-bit data are lined up. In addition, the multiplication result Z being the output of the Carry-Less multiplication circuit 201 is 15-bit data. Since the method of the Carry-Less multiplication has already been explained, the explanation of the detail configuration of the Carry-Less multiplication circuit 201 in the third example in FIG. 16 is omitted.

Meanwhile, the parity check circuit 203 is configured in a similar manner to the one in the second example in FIG. 15A and FIG. 15B. That is, first, the parity value for each unit of the multiplication result Z that the Carry-Less multiplication circuit 201 outputs is obtained using an XOR circuit according to the definition of the parity value. Then, match/mismatch of the obtained parity value for each data unit and the parity predicted value for each data unit that the Carry-Less multiplication parity prediction circuit 202 outputs is judged using an XOR circuit, and the OR of the output of the judgment result is obtained using an OR circuit. The output of the OR circuit is the check result P_Z_E. The check result P_Z_E takes the value “0” or “1”, and when the value is “1”, it represents that the malfunction of the Carry-Less multiplier has been detected.

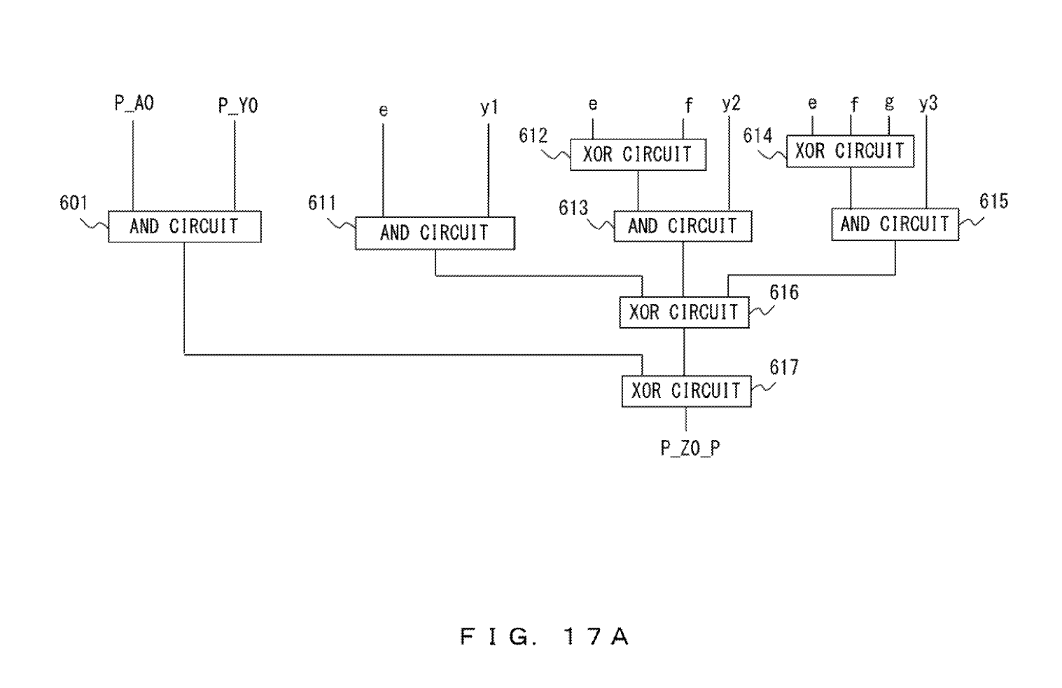

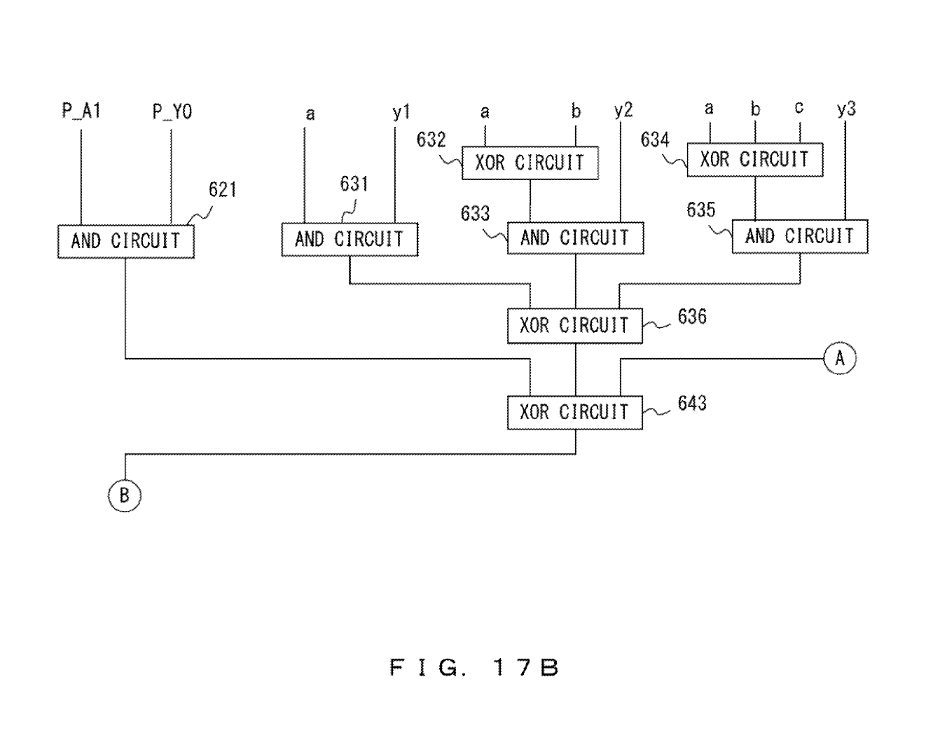

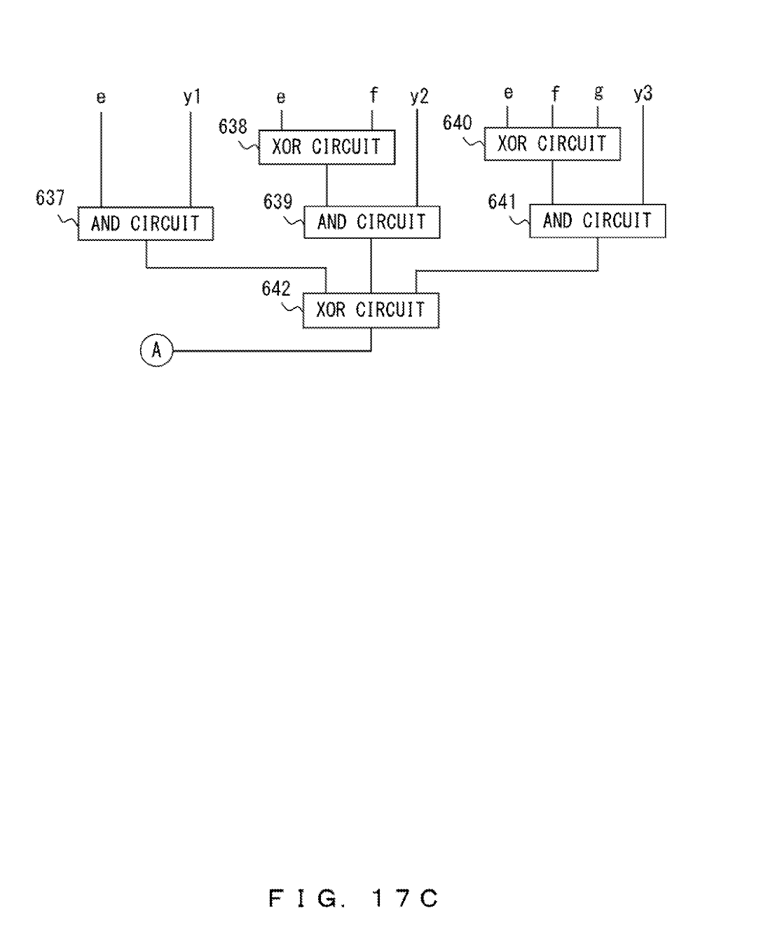

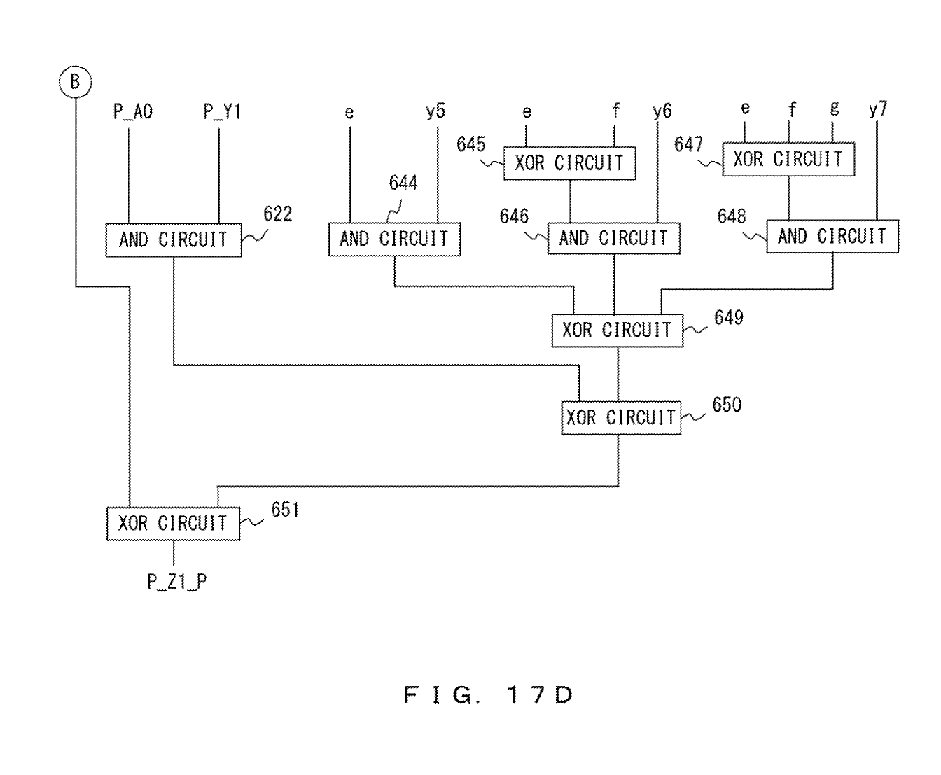

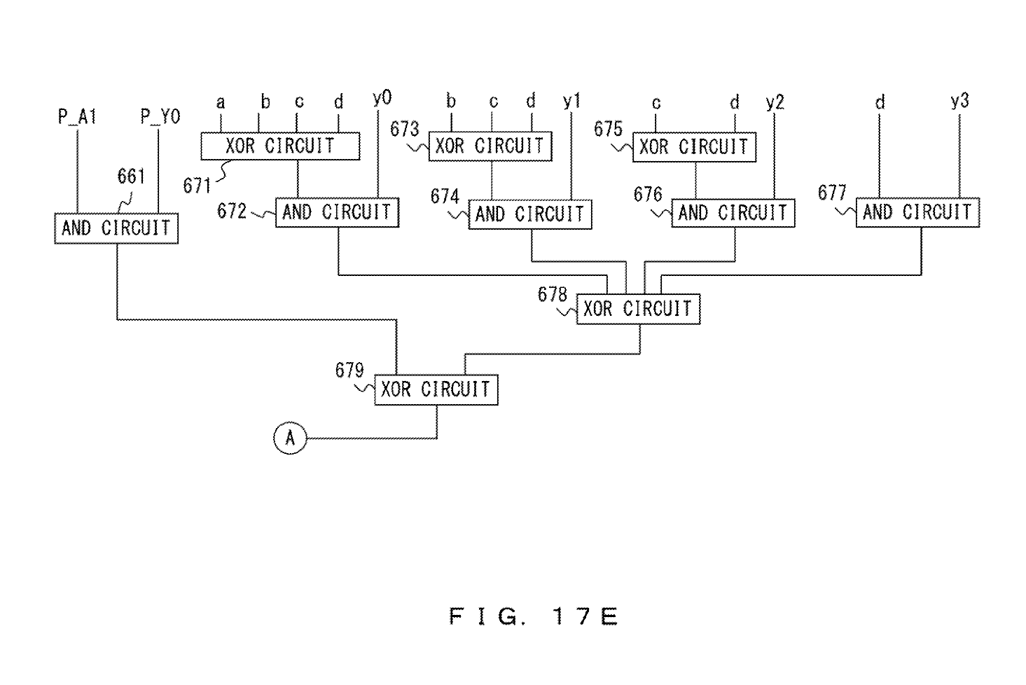

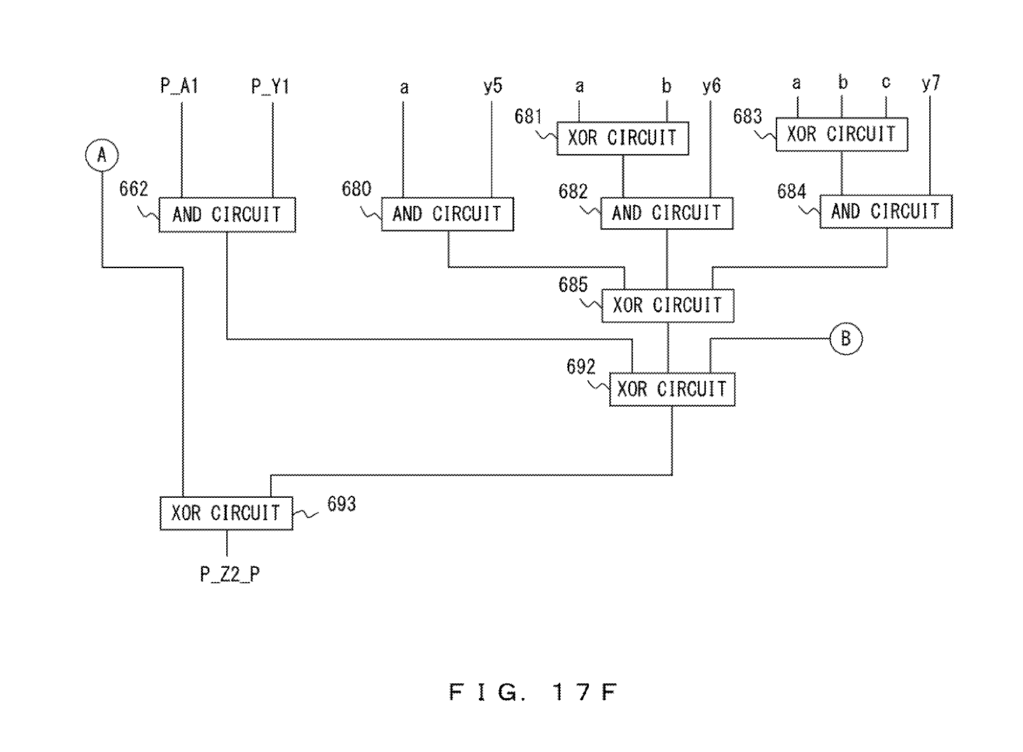

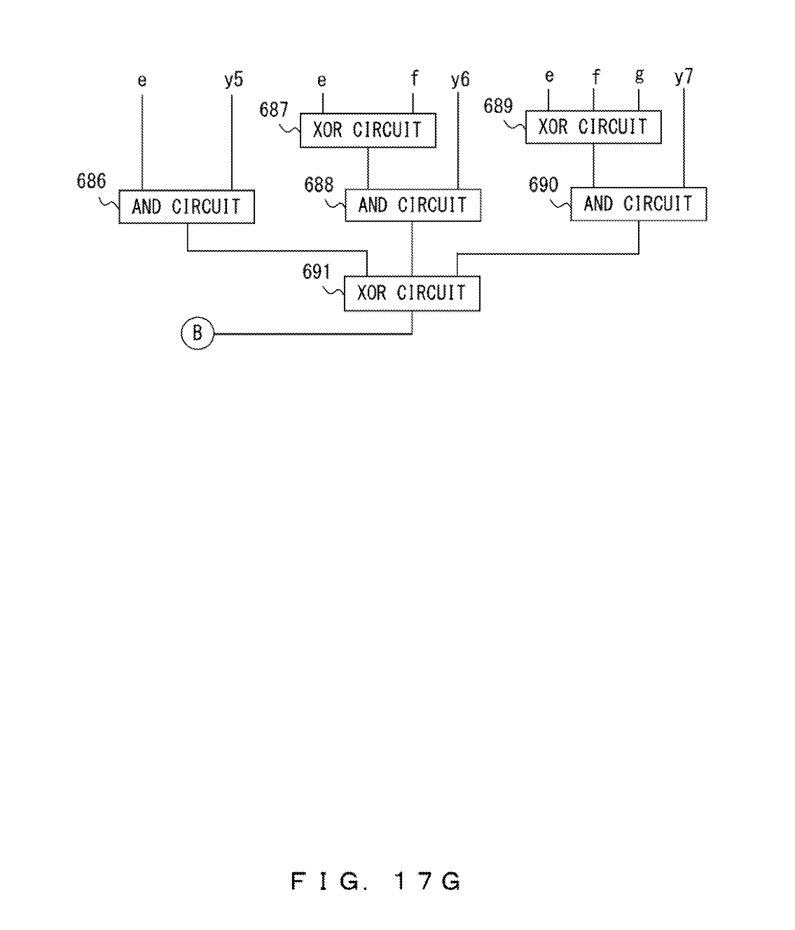

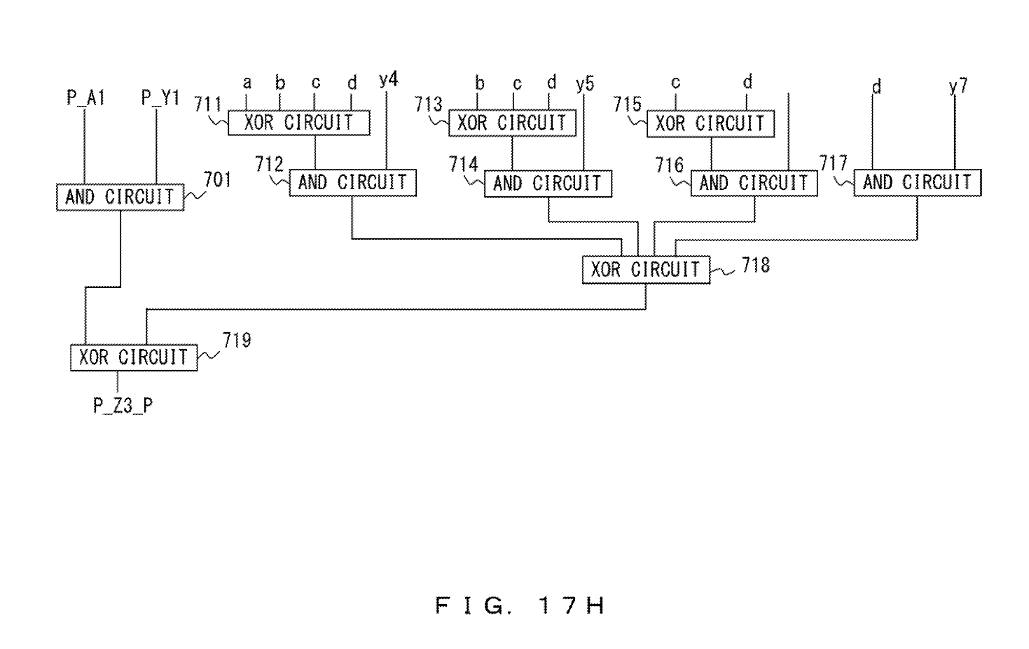

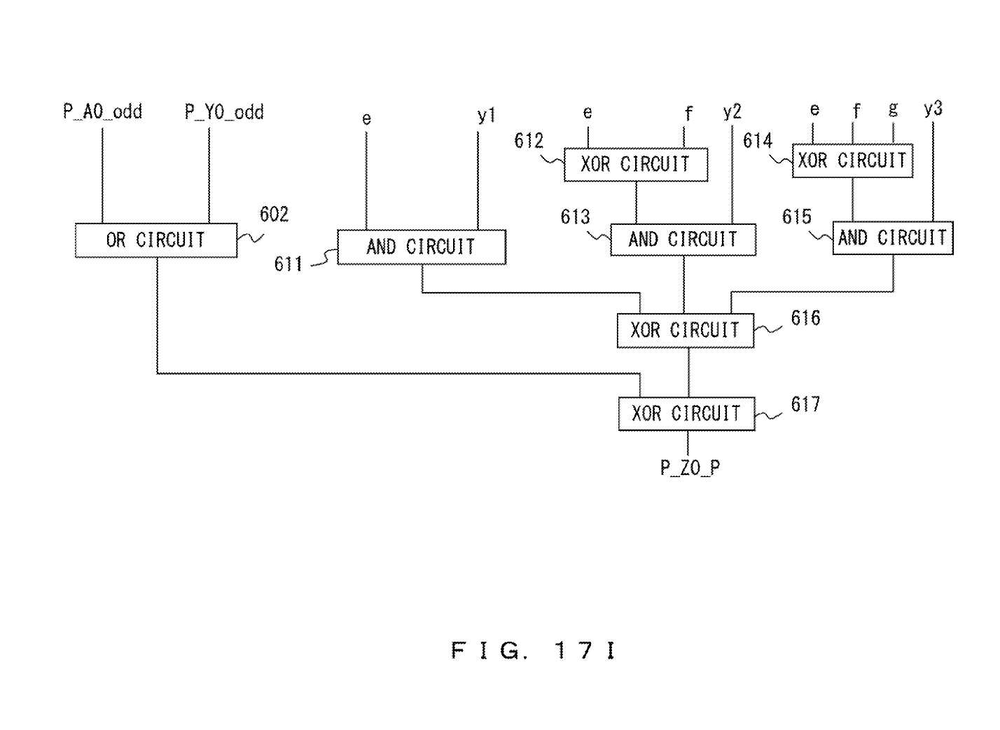

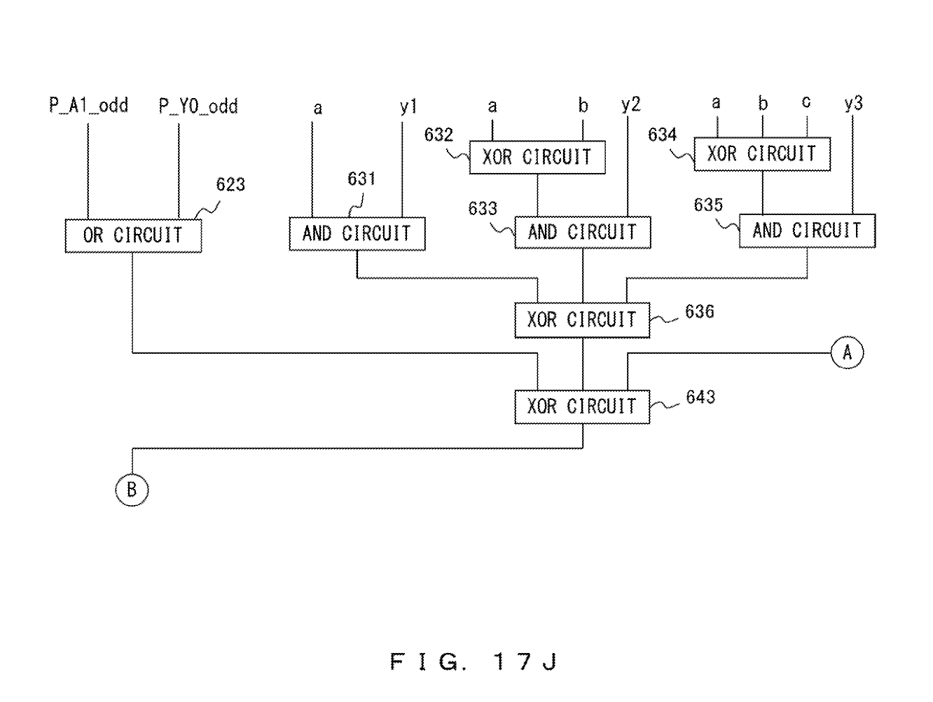

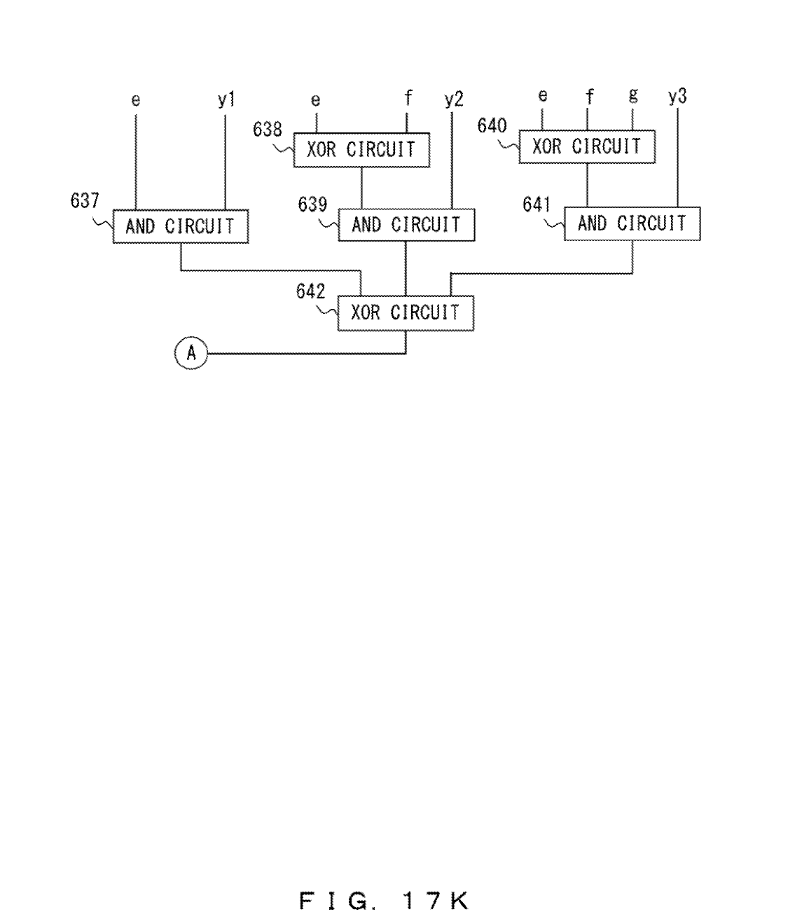

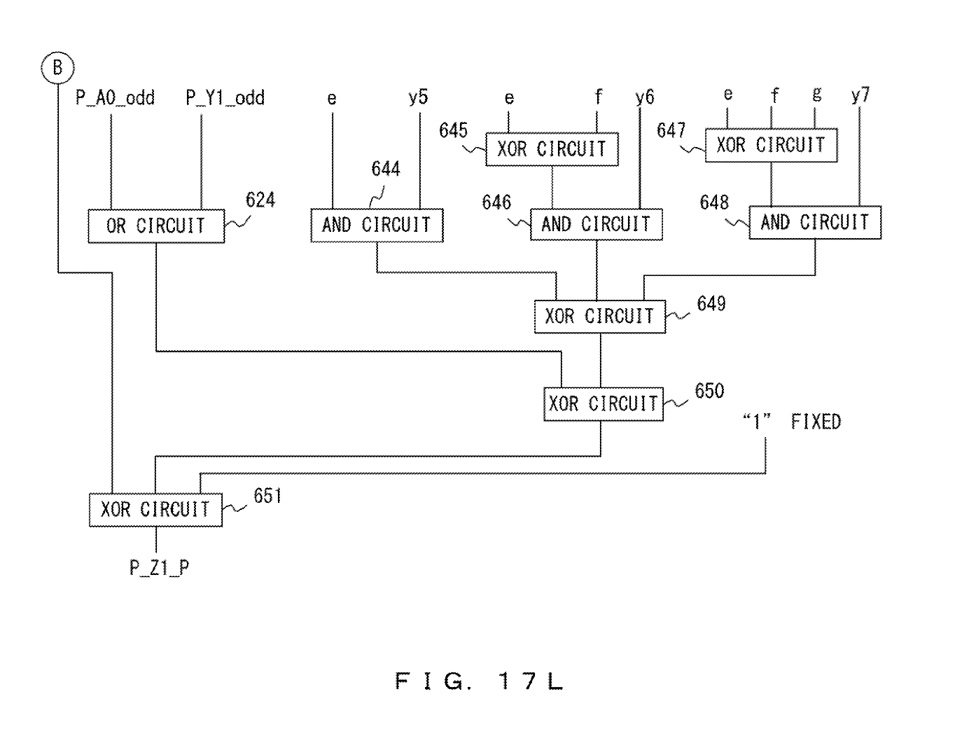

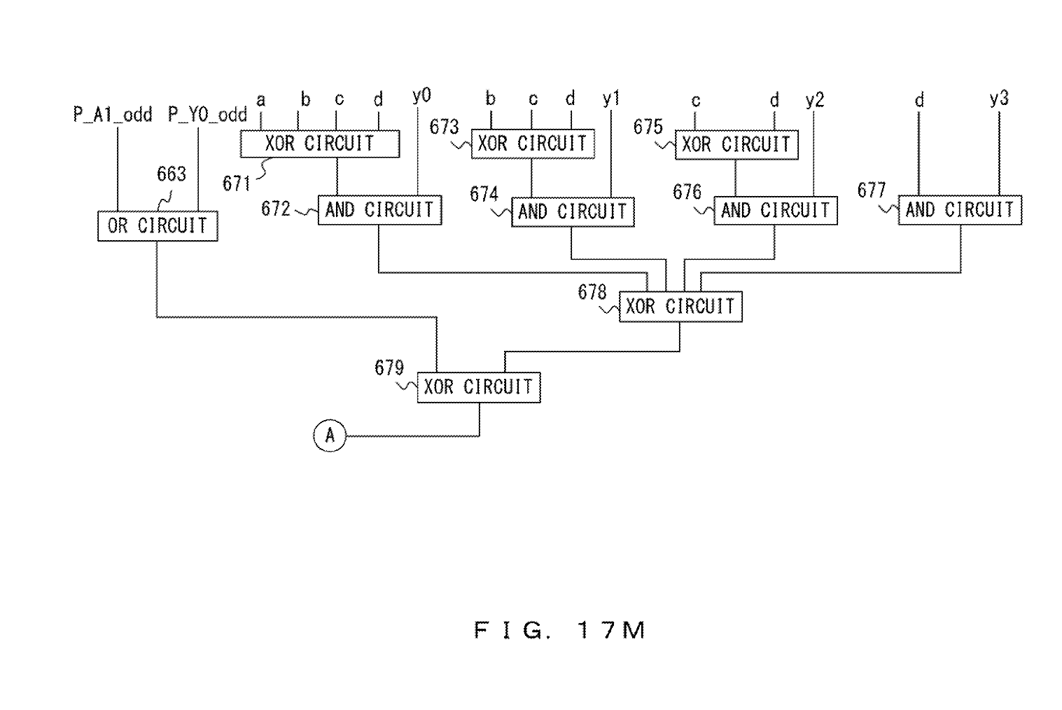

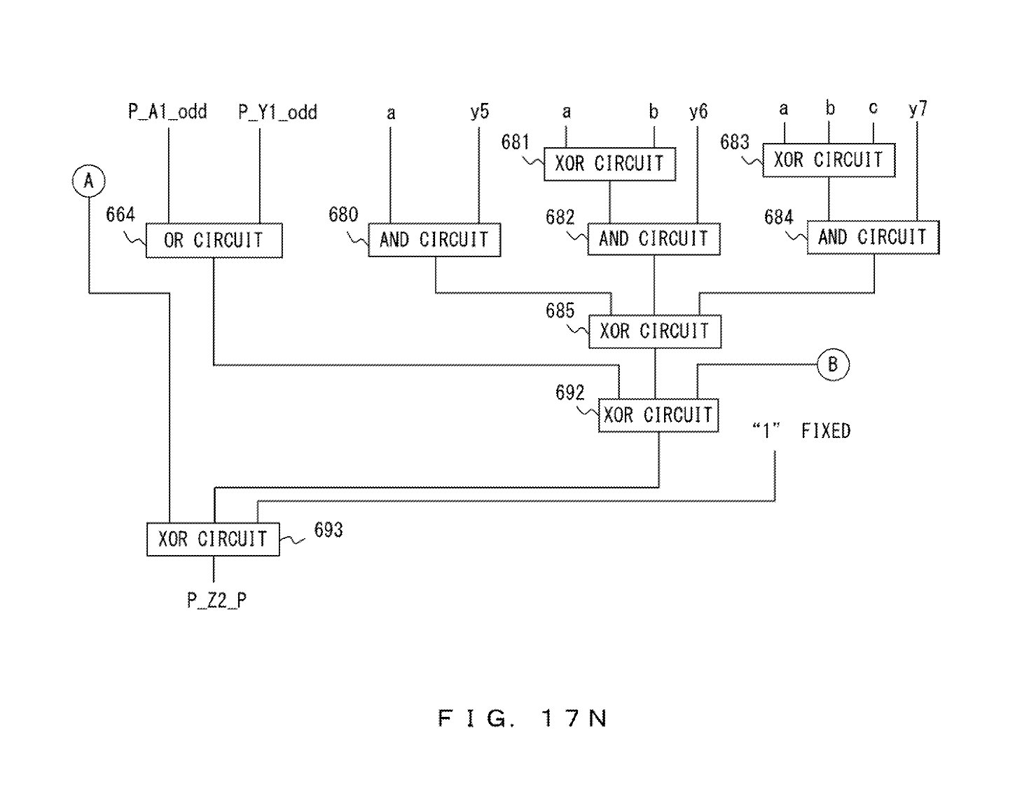

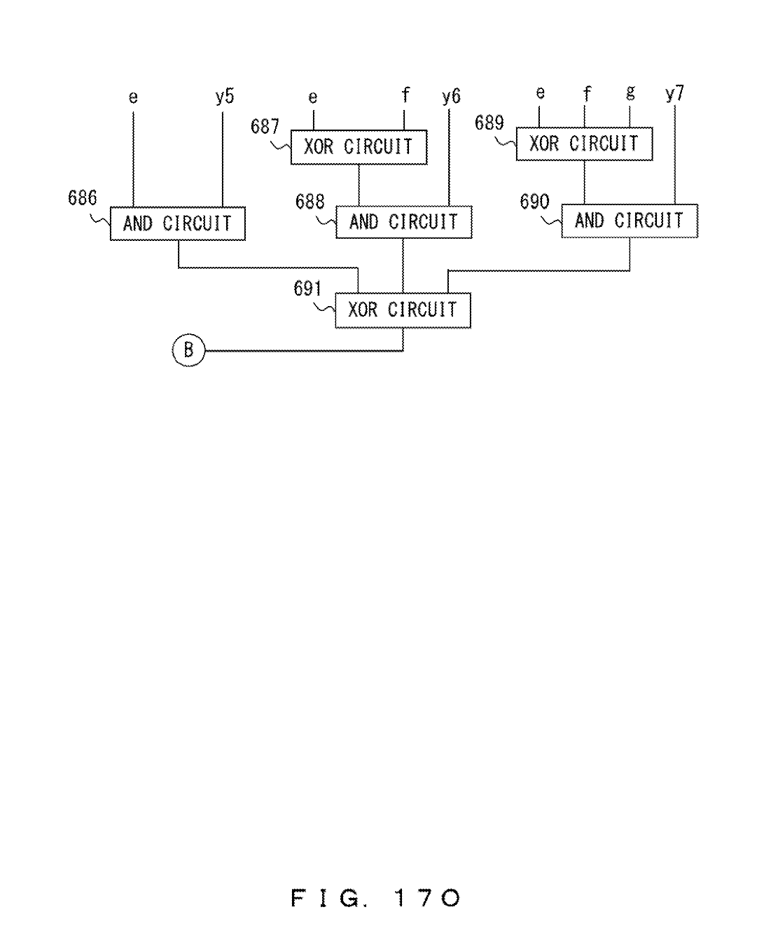

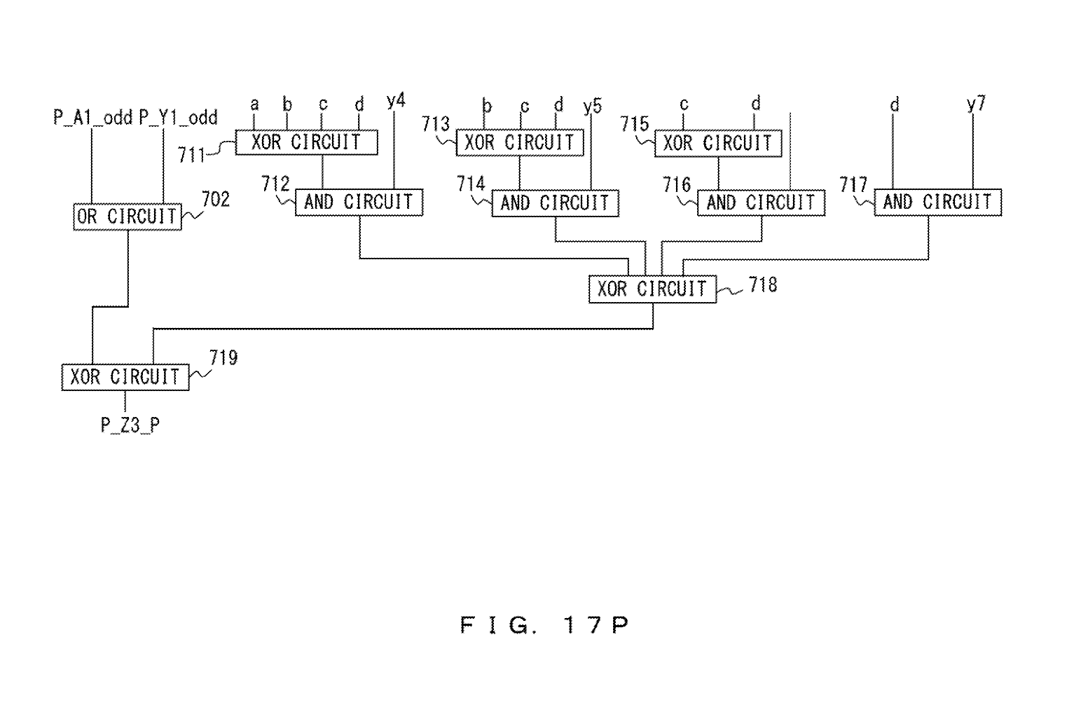

Next, the configuration of the Carry-Less multiplication parity prediction circuit 202 in FIG. 16 is explained. The specific circuit configuration of the Carry-Less multiplication parity prediction circuit 202 is illustrated in each diagram from FIG. 17A to FIG. 17P.

The circuit in the first example illustrated in each diagram from FIG. 17A through FIG. 17H is the circuit in which even-number parity is used as the parity value. Then, the circuit in the first example illustrated in each diagram from FIG. 17I through FIG. 17P is the circuit in which even-number parity is used as the parity value.

The circuit in FIG. 17A is a circuit that obtains the predicted value P_Z0_P of the parity value of the first data unit from the lower-order in the multiplication result Z that the Carry-Less multiplication circuit 201 outputs, from the each value of the multiplicand A and the multiplier Y and the parity value of each of their data units. The circuit in FIG. 17A is a circuit that performs the operation of the formula [20] (that is, the formula [13]).

In FIG. 17A, the AND circuit 601 is a circuit that performs the first term of the righthand side of the formula [13] connected by the “+” symbol. Meanwhile, the AND circuits 611, 613, and 615 and the XOR circuits 612 and 614 are circuits that perform the operation of each term from the second term through the fourth term of the righthand side of the formula [13]. Then, the XOR circuit 616 and 617 are a circuit that performs the operation of the XOR of the values of the respective terms from the first term through the fourth term of the righthand side of the formula [13] to obtain the parity predicted value P_Z0_P.

The circuit in FIG. 17B, FIG. 17C, and FIG. 17D is a circuit that obtains the predicted value P_Z1_P of the parity value of the second data unit from the lower-order in the multiplication result Z that the Carry-Less multiplication circuit 201 outputs, from the each value of the multiplicand A and the multiplier Y and the parity value of each of their data units. The circuit in FIG. 17A is a circuit that performs the operation of the formula [21] (that is, the formula [16] and the formula [17]).

In FIG. 17B, the AND circuit 621 is a circuit that performs the first term of the righthand side of the formula [16] connected by the “+” symbol. Meanwhile, the AND circuits 631, 633, and 635 and the XOR circuits 632 and 634 are circuits that perform the operation of each term from the second term through the fourth term of the righthand side of the formula [16]. Then, the XOR circuits 637, 639, 641 and the XOR circuit 638 and 640 are circuits that perform the operation of the XOR of the values of the respective terms from the fifth term through the seventh term of the righthand side of the formula [16]. Then, the XOR circuit 636 (FIG. 17B), 642 (FIG. 17C), 643 (FIG. 17B) are circuits that performs the operation of the XOR of the values of the respective terms from the first term through the seventh term of the righthand side of the formula [16], to obtain the value of P_ZB in the formula [16].

Meanwhile, in FIG. 17D, the AND circuit 622 is a circuit that performs the first term of the righthand side of the formula [17] connected by the “+” symbol. Meanwhile, the AND circuits 641, 646, and 648 and the XOR circuits 645 and 647 are circuits that perform the operation of each term from the second term through the fourth term of the right-hand side of the formula [17]. Then, the XOR circuits 649 and 650 are a circuit that performs the operation of the XOR of the values of the respective terms from the first term through the fourth term of the righthand side of the formula [17] to obtain the value of P_ZC of the formula [17].

Then, the XOR circuit 651 in FIG. 17D is a circuit that performs the operation of the XOR of the formula [21] to obtain the parity predicted value P_Z1_P.

The circuit in FIG. 17E, FIG. 17F, and FIG. 17G is a circuit that obtains the predicted value P_Z1_P of the parity value of the third data unit from the lower-order in the multiplication result Z that the Carry-Less multiplication circuit 201 outputs, from the each value of the multiplicand A and the multiplier Y and the parity value of each of their data units. The circuit is a circuit that performs the operation of the formula [22] (that is, the formula [14] and the formula [19]).

In FIG. 17E, the AND circuit 621 is a circuit that performs the first term of the righthand side of the formula [14] connected by the “+” symbol. Meanwhile, the AND circuits 671, 673, and 675 and the XOR circuits 678 and 679 are circuits that perform the operation of each term from the second term through the fifth term of the righthand side of the formula [14]. Then, the XOR circuits 678 and 679 are a circuit that performs the operation of the XOR of the values of the respective terms from the first term through the fifth term of the righthand side of the formula [14] to obtain the value of P_ZD of the formula [14].

In FIG. 17F, the AND circuit 622 is a circuit that performs the first term of the righthand side of the formula [19] connected by the “+” symbol. Meanwhile, the AND circuits 680, 682, and 684 and the XOR circuits 681 and 683 are circuits that perform the operation of each term from the second term through the fourth term of the righthand side of the formula [19]. Furthermore, in FIG. 17G, the AND circuits 686, 688, and 690 and the XOR circuits 687 and 689 are circuits that perform the operation of each term from the fifth term through the seventh term of the righthand side of the formula [19]. Then, the XOR circuits 685 (FIG. 17F), 691 (FIG. 17G) and 692 (FIG. 17F) are circuit that perform the operation of the XOR of the values of the respective terms from the first term through the seventh term of the righthand side of the formula [19] to obtain the value of P_ZE of the formula [19].

Then, the XOR circuit 693 in FIG. 17F is a circuit that performs the operation of the XOR of the formula [22] to obtain the parity predicted value P_Z2_P b.

The circuit in FIG. 17H is a circuit that obtains the predicted value P_Z3_P of the parity value of the data following the third data unit from the lower-order in the multiplication result Z that the Carry-Less multiplication circuit 201 outputs, from the each value of the multiplicand A and the multiplier Y and the parity value of each of their data units. The circuit in FIG. 17H is a circuit that performs the operation of the formula [23] (that is, the formula [18]).

In FIG. 17H, the AND circuit 701 is a circuit that performs the first term of the righthand side of the formula [18] connected by the “+” symbol. Meanwhile, the AND circuits 711, 713, and 715 and the AND circuits 712, 714, 716 and 717 are circuits that perform the operation of each term from the second term through the fifth term of the righthand side of the formula [18]. Then, the XOR circuits 718 and 719 are circuit that performs the operation of the XOR of the values of the respective terms from the first term through the fifth term of the righthand side of the formula [18] to obtain the value of P_Z3_P.

The circuit in FIG. 17I is a circuit that obtains the predicted value P_Z0_P of the parity value of the data following the third data unit from the lower-order in the multiplication result Z that the Carry-Less multiplication circuit 201 outputs, from the each value of the multiplicand A and the multiplier Y and the parity value of each of their data units. The circuit in FIG. 17H is a circuit that performs the operation of the formula [38] (that is, the formula [32]).

In the circuit in FIG. 17I, the AND circuit 601 in FIG. 17A is replaced with the OR circuit 602. The OR circuit 602 is a circuit that performs operation of the first term of the righthand side of the formula [32], that is, P_A0_odd̂P_Y0_odd. Therefore, the XOR circuits 616 and 617 are the circuit that performs the operation of the XOR of the respective values from the first term to the fourth term of the righthand side of the formula [32] to obtain the parity predicted value P_Z0_P.

The circuit in FIG. 17J, FIG. 17K, and FIG. 17L is a circuit that obtains the predicted value P_Z1_P of the parity value of the second data unit from the lower-order in the multiplication result Z that the Carry-Less multiplication circuit 201 outputs, from the each value of the multiplicand A and the multiplier Y and the parity value of each of their data units. The circuit is a circuit that performs the operation of the formula [39].

In the circuit FIG. 17J, FIG. 17K, and FIG. 17L, the AND circuit 621 in FIG. 17B, the AND circuit 622 in FIG. 17D are replaced with the OR circuit 623 (FIG. 17J) and the OR circuit 624 (FIG. 17L) respectively, and the input of the value “1” is added to the XOR circuit 651 in FIG. 17L. Here, the OR circuit 623 is a circuit that performs operation of the first term of the righthand side of the formula [34], that is, P_A1_odd̂P_Y0_odd. Therefore, the XOR circuit 616 and 617 are the circuit that performs the operation of the XOR of the respective values from the first term to the fourth term of the righthand side of the formula [32] to obtain the parity predicted value P_Z0_P. In addition, the OR circuit 624 is a circuit that performs operation of the first term of the righthand side of the formula [35], that is, P_A0_odd̂P_Y1_odd. Therefore, the XOR circuit 651 is, in FIG. 17L, the circuit that performs the operation of the XOR of the respective values from the first term to the third term of the righthand side of the formula [39] to obtain the parity predicted value P_Z1_P.

The circuit in FIG. 17M, FIG. 17N, and FIG. 17O is a circuit that obtains the predicted value P_Z1_P of the parity value of the third data unit from the lower-order in the multiplication result Z that the Carry-Less multiplication circuit 201 outputs, from the each value of the multiplicand A and the multiplier Y and the parity value of each of their data units. The circuit is a circuit that performs the operation of the formula [40].

In the circuit FIG. 17M, FIG. 17N, and FIG. 17O), the AND circuit 661 in FIG. 17E, the AND circuit 662 in FIG. 17F are replaced with the OR circuit 663 (FIG. 17M) and the OR circuit 664 (FIG. 17N) respectively, and the input of the value “1” is added to the XOR circuit 693 in FIG. 17N. Here, the OR circuit 634 is a circuit that performs operation of the first term of the righthand side of the formula [37], that is, P_A1_odd̂P_Y1_odd. Therefore, the XOR circuit 693 is the circuit that performs the operation of the XOR of the respective values from the first term to the third term of the righthand side of the formula [40] to obtain the parity predicted value P_Z0_P. In addition, the OR circuit 624 is a circuit that performs operation of the first term of the righthand side of the formula [35], that is, P_A0_odd̂P_Y1_odd. Therefore, the XOR circuit 651 is, in FIG. 17L, the circuit that performs the operation of the XOR of the respective values from the first term to the third term of the righthand side of the formula [39] to obtain the parity predicted value P_Z2_P.

The circuit in FIG. 17P is a circuit that obtains the predicted value P_Z3_P of the parity value of the data following the third data unit from the lower-order in the multiplication result Z that the Carry-Less multiplication circuit 201 outputs, from the each value of the multiplicand A and the multiplier Y and the parity value of each of their data units. The circuit in FIG. 17H is a circuit that performs the operation of the formula [41] (that is, the formula [36]).

In the circuit in FIG. 17P, the AND circuit 701 in FIG. 17H is replaced with the OR circuit 702. The OR circuit 702 is a circuit that performs operation of the first term of the righthand side of the formula [36], that is, P_A1_odd̂P_Y1_odd. Therefore, the XOR circuits 718 and 719 are, in FIG. 17P, the circuit that performs the operation of the XOR of the respective values from the first term to the fifth term of the righthand side of the formula [36] to obtain the parity predicted value P_Z3_P.

### 3.4. The Configuration of the Carry-Less Multiplier in the Case in which the Size of the Multiplicand Data String and the Multiplier Data String is Generalized

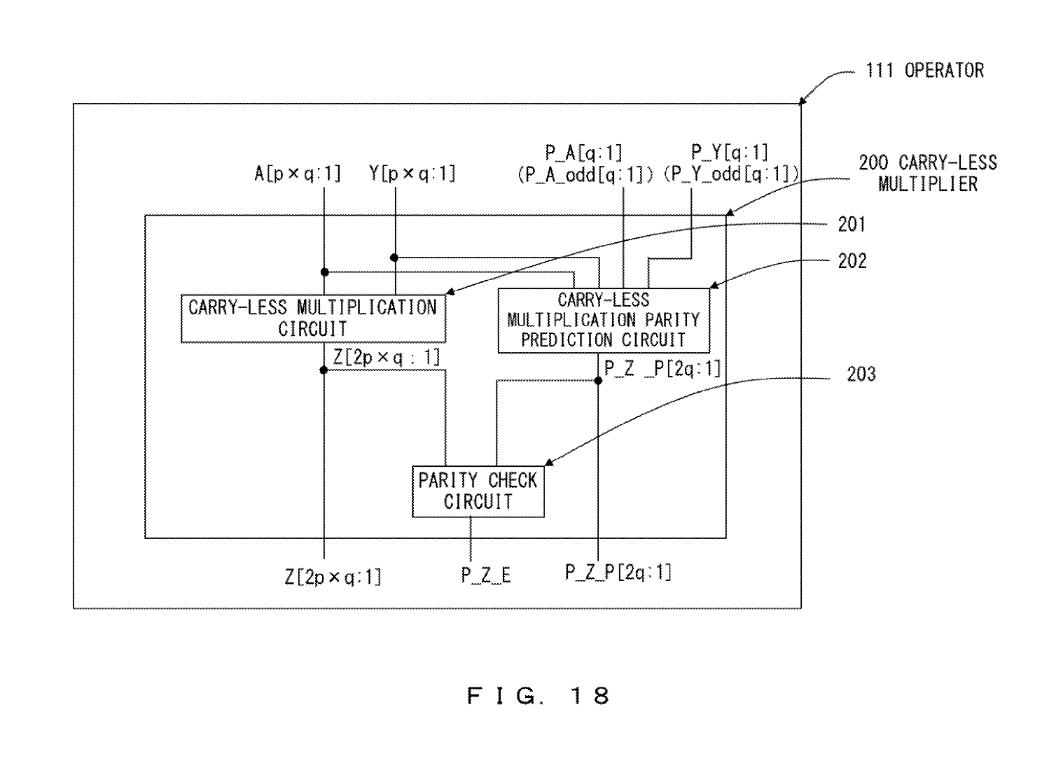

Next, FIG. 18 is explained. FIG. 18 is a configuration diagram of the fourth example of the Carry-Less multiplier provide as a part of the operator 111 in the arithmetic operation processing apparatus 100 in FIG. 8. The Carry-Less multiplier 200 has the malfunction detection explained in [2.3. Case in which the size of the multiplicand data string and the multiplier data string is generalized]

In FIG. 18, the Carry-Less multiplication parity prediction circuit 202 outputs the predicted values P_Z_P[1], . . . , P_Z_P[2q−1] of the respective data units from the first to 2q−1-th from the lower order in the multiplication result Z. Furthermore, the Carry-Less multiplication parity prediction circuit 202 also outputs the predicted value P_Z_P[2q] of the parity value of the following data. The Carry-Less multiplication parity prediction circuit 202 differs from the one in the third example illustrated in FIG. 16 in this regard.

The Carry-Less multiplication circuit 201 in FIG. 18 is a circuit that performs the Carry-Less multiplication of the multiplicand A and the multiplier Y to output the multiplication result Z. Here, the multiplicand A and the multiplier Y are both a data string in which q (here, q is a natural number) data units being p-bit data (here, p is a natural number equal to 2 or above). In addition, the multiplication result being the output of the Carry-Less multiplication circuit 201 is 2q×p−1-bit data. Meanwhile, since the method of the Carry-Less multiplication has already been explained, explanation on the detail configuration of the Carry-Less multiplication circuit in the fourth example in FIG. 18 is omitted.

The parity check circuit 203 in FIG. 18 is also configured in a similar manner as the one in the second example presented in FIG. 15A and FIG. 15B. That is, first, the parity value for each data unit in the multiplication result Z that the Carry-Less multiplication circuit 201 is obtained using the XOR circuit according to the definition of the parity value. Then, match/mismatch of the obtained parity value for each data unit and the parity predicted value for each data unit that the Carry-Less multiplication parity prediction circuit 202 outputs is judged using an XOR circuit, and the OR of the output of the judgment result is obtained using an OR circuit. The output of the OR circuit is the check result P_Z_E. The check result P_Z_E takes the value “0” or “1”, and when the value is “1”, it represents that the malfunction of the Carry-Less multiplier has been detected.

### 3.4.1. Configuration of the Carry-Less Multiplication Parity Prediction Circuit

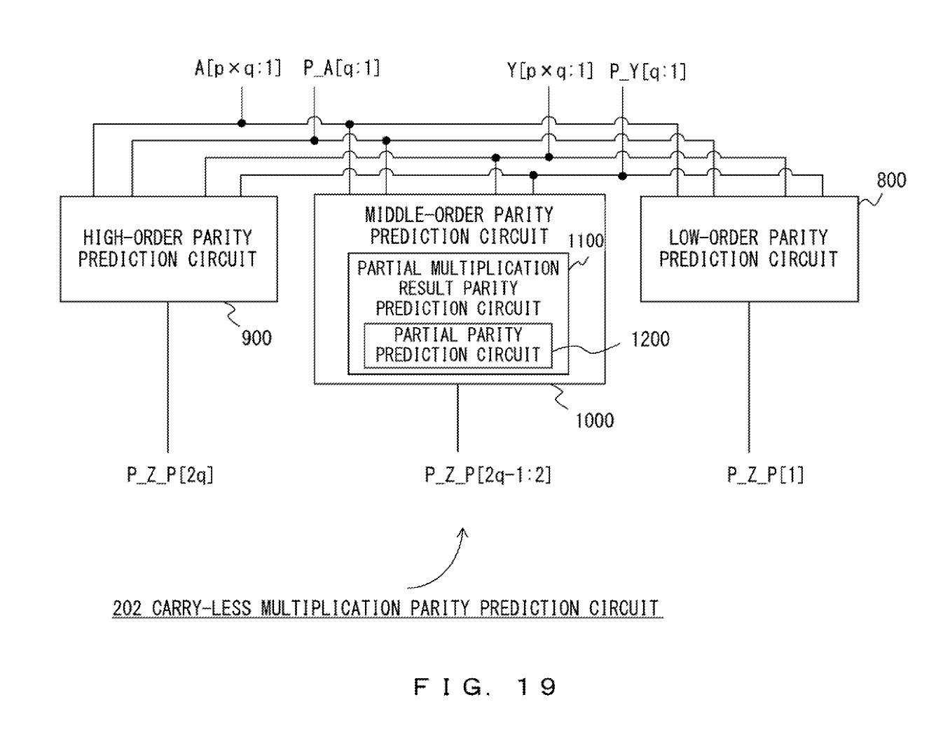

Next, the configuration of the Carry-Less multiplication parity prediction circuit 202 in FIG. 18 is explained. The configuration of the Carry-Less multiplication parity prediction circuit 202 is illustrated in FIG. 19.

The Carry-Less multiplication parity prediction circuit 202 had a low-order parity prediction circuit 800, a high-order parity prediction circuit 900, and a middle-order parity prediction circuit 1000.

The low-order parity prediction circuit 800 is a circuit that performs prediction of the low-order parity value as explained in [2.3.1. Prediction of low-order parity]. That is, the low-order parity prediction circuit 800 is a circuit that outputs the predicted value P_Z_P[1] of the parity value of the first data unit in the multiplication result Z. To the low-order parity prediction circuit 800, the value A[unit 1] and its parity value P_A[1] of the first multiplicand data unit, and the value Y[unit 1] and its parity value P_Y[1] of the first multiplier data unit are input.

The high-order parity prediction circuit 900 is a circuit that performs the prediction of the high-order parity value as explained in [2.3.2. Prediction of high-order parity]. That is, the high-order parity prediction circuit 900 is a circuit that outputs the predicted value P_Z_P[2q] of the data following the 2q−1 data unit from the lower order in the multiplication result Z (that is, data of the high-order p−1 bit of the multiplication result Z). To the high-order parity prediction circuit 900, the value Y[unit q] and its parity value P_Y[q] of the q-th multiplier data unit is input.

The middle-order parity prediction circuit 1000 is a circuit that performs prediction of the middle-order parity value as explained in [2.3.3. Prediction of middle-order parity]. That is, the middle-order parity prediction circuit 1000 is a circuit that outputs the predicted values P_Z_P[2], . . . , P_Z_P[2q−1] of the parity value for the respective data units from the second to 2q−1-th of the multiplication result Z.

To themiddle-orderparity prediction circuit 1000, thevalue A[unit 1], . . . , A[unit q] and their parity values P_A[1], . . . , P_A[q] of the first 1 multiplicand data unit through the q-th multiplicand data unit are input. Furthermore, to the middle-order parity prediction circuit 1000, the value Y[unit 1], . . . , Y[unit q] and their parity value P_Y[1], . . . , P_Y[q] of the first multiplier data unit to the q-th multiplier data unit are input.

Meanwhile, while the Carry-Less multiplication parity prediction circuit 202 in FIG. 18 has 2q−2 units of the middle-order parity prediction circuit 1000 that respectively output the parity predicted values P_Z_P[2], . . . , P_Z_P[2q−1], FIG. 19 presents only one of them.

The middle-order parity prediction circuit 1000 has a partial multiplication result parity prediction circuit 1100. The partial multiplication result parity prediction circuit 1100 is a circuit that performs prediction of the parity value for each data unit of the partial multiplication result described above as illustrated in [2.3.3.1. Prediction of the parity value for each data unit of the partial multiplication result].

Meanwhile, since the multiplier Y has q data units, the Carry-Less multiplication parity prediction circuit 202 in FIG. 18 has q units of the partial multiplication result parity prediction circuit 1100, while FIG. 19 presents only one of them.

The partial multiplication result parity prediction circuit 1100 has a partial parity prediction circuit 1200. The partial parity prediction circuit 1200 is a circuit that performs prediction explained in [2.3.3.1.1. Prediction of the parity value for the first partial]], [2.3.3.1.2. Prediction of the parity value for the q+1-th partial], [2.3.3.1.3. Prediction of the parity value for the middle partial]. That is, the partial parity prediction circuit 1200 is a circuit that outputs the predicted value of the parity value for each data unit of the partial multiplication result. Meanwhile, since the partial multiplication result consists of q+1 data units from the first partial through q+1-th partial, the partial multiplication result parity prediction circuit 1100 has q+1 units of the partial parity prediction circuit 1200, while FIG. 19 presents only one of them.

### 3.4.1.1. Configuration of the Low-Order Parity Prediction Circuit

Next, the configuration of the low-order parity prediction circuit 800 in FIG. 19 is explained.

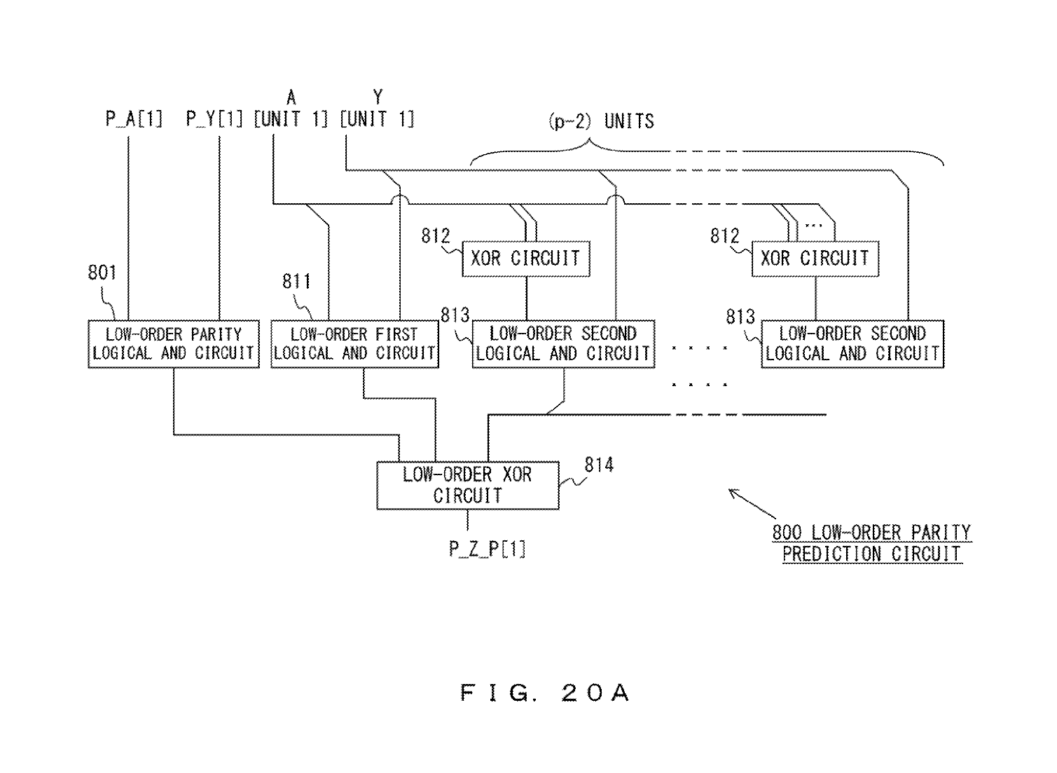

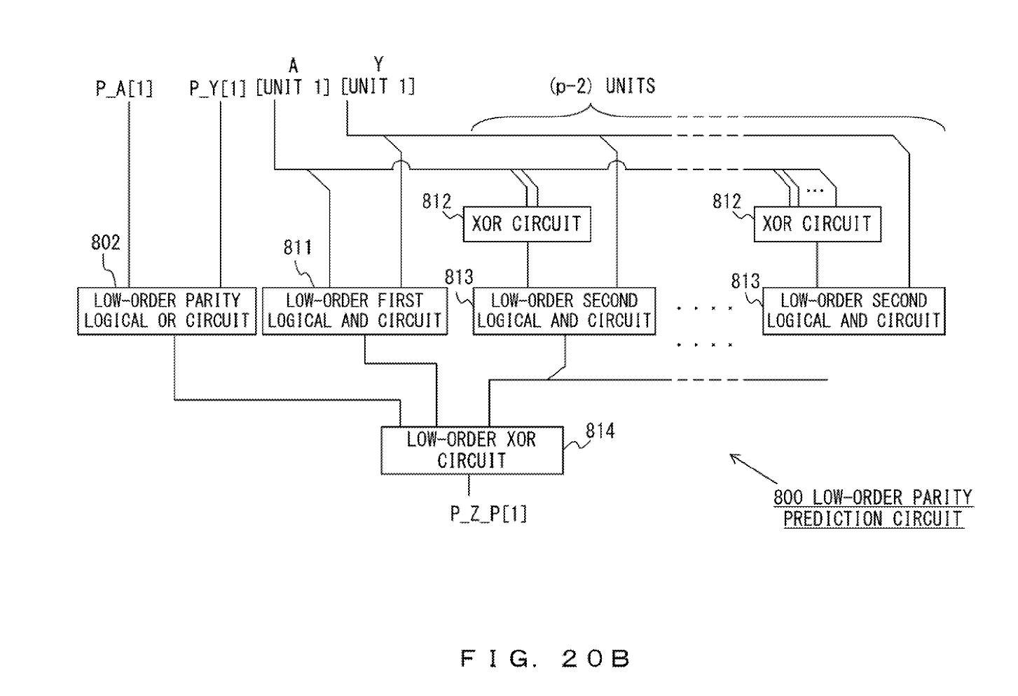

The configuration of the first example of the low-order parity prediction circuit 800 in FIG. 19 is illustrated in FIG. 20A. The configuration of the first example is for a case using even-number parity as the parity value.

The low-order parity prediction circuit 800 is a low-order parity logical AND circuit 801, a low-order first logical AND circuit 811, an XOR circuit 812, a low-order second logical AND circuit 813, and a low-order XOR circuit 814. Among them, the low-order parity prediction circuit 800 has p−2 units of both the XOR circuit 812 and the low-order second logical AND circuit.

The low-order parity logical AND circuit 801 is a circuit to which the parity value P_A[1] of the first multiplicand data unit and the parity value P_Y[1] of the first multiplier data unit are input and which outputs the value of the logical AND (the low-order parity logical AND described above) of their parity values.

The low-order first logical AND circuit 811 is a circuit to which the value of the highest-order bit of the first multiplicand data unit and the value of the bit at the second digit from the lower order in the first multiplier data unit are input and which outputs the value of the logical AND (the low-order first logical AND described above) of their logical AND.

The p−2 units of the XOR circuit 812 and the low-order second logical AND circuit 813 respectively performs an operation according to different values of i (here, i is a natural number from 2 through p−1). The XOR circuit 812 is a circuit to which the value of each bit for i digits from the higher order of the data unit is input and which outputs the value of their XOR. In addition, the low-order second logical AND circuit 813 is a circuit to which the output of the XOR circuit 812 and the value of i+1-th digit from the lower order in the first multiplier data unit are input and which outputs their logical AND (the low-order second logical AND described above).

The low-order XOR circuit 814 is a circuit to which the output of the low-order parity logical AND circuit 801, the output of the low-order parity logical AND circuit 811 and the output of each of the p−2 low-order second logical AND circuit 813 are input and which outputs the value of their XOR. The output of low-order XOR circuit 814 becomes the predicted value P_Z_P[1] of the multiplication result Z being the output of the low-order parity prediction circuit 800.

Next, FIG. 20B is illustrated. FIG. 20B illustrates the configuration of the second example of the low-order parity prediction circuit 800 in FIG. 19. The configuration of the second example is for a case of using odd-number parity as the parity value.

In the configuration in FIG. 20B, the low-order parity logical AND circuit 801 is replaced with a low-order parity logical OR circuit 802. The low-order parity logical OR circuit 802 is a circuit to which the parity value P_A[1] of the first multiplicand data unit and the parity value P_Y[1] of the value of the first multiplier data unit are input and which outputs the value of the OR (the lower-order parity OR described above) of their parity values.

The low-order XOR circuit 814 is a circuit to which the output of the low-order parity logical OR circuit 802, the low-order parity logical AND circuit 811 and the output of each of the p−2 units of the low-order second logical AND circuit 813 are input and which outputs the value of their XOR. The output of the low-order XOR circuit 814 becomes the predicted value P_Z_P[1] of the low-order parity value of the multiplication result Z being the output of the low-order parity prediction circuit 800.

### 3.4.1.2. Configuration of the High-Order Parity Prediction Circuit

Next, the configuration of the high-order parity prediction circuit 900 in FIG. 19 is explained.

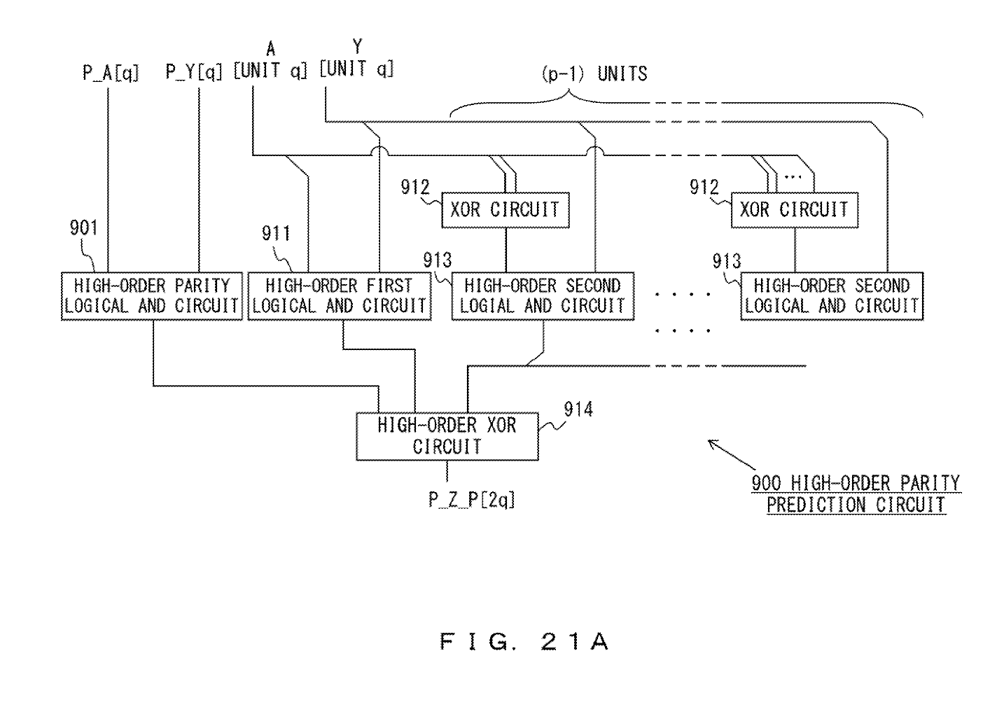

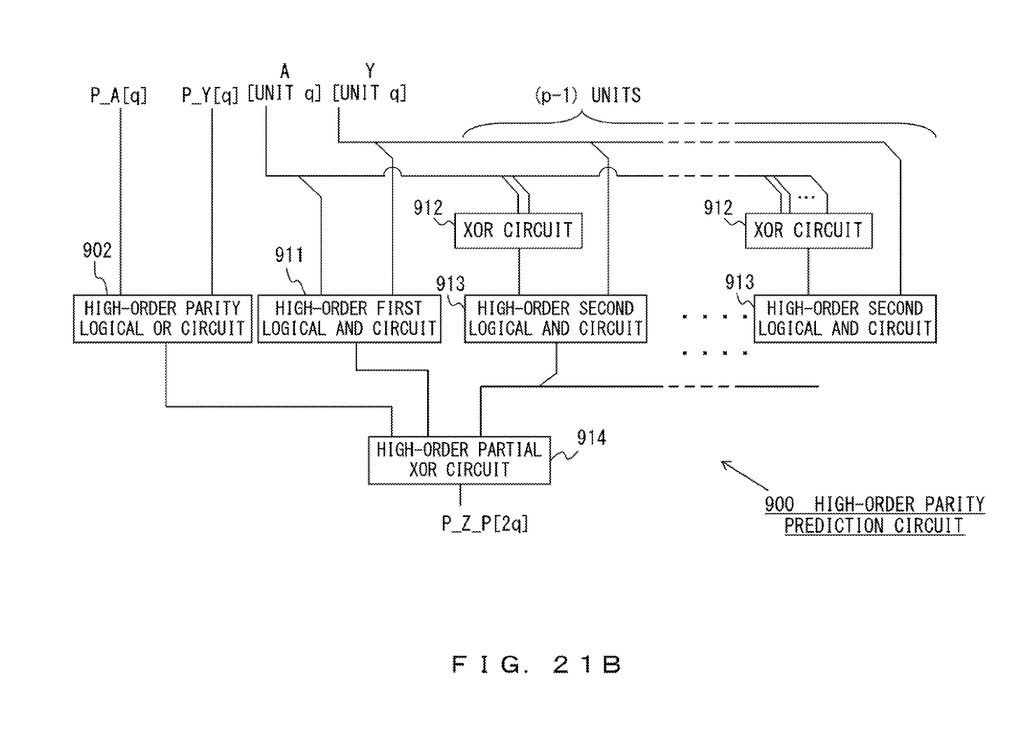

The configuration of the first example of the high-order parity prediction circuit 900 in FIG. 19 is illustrated in FIG. 21A. The configuration of the first example is for a case of using even-number parity as the parity value.

The high-order parity prediction circuit 900 has a high-order parity logical AND circuit 901, high-order first logical AND circuit 911, a XOR circuit 912, a high-order second logical AND circuit 913, and a high-order XOR circuit 914. The high-order parity prediction circuit 900 has p−1 units of both the XOR circuit 912 and the high-order second logical AND circuit 913 among them.

The high-order parity logical AND circuit 901 is a circuit to which the parity value P_A[q] of the q-th multiplicand data unit and the parity value P_Y[q] of the value of the q-th multiplier data unit are input and which outputs the value of the logical AND (the high-order parity logical AND described above) of their parity values.

The high-order first logical AND circuit 911 is a circuit to which the value of the lowest-order bit in the q-th multiplicand data unit and the value of the highest-order bit in the q-th multiplier data unit are input and which outputs the value of their logical AND (high-order first logical AND described above).

The p−1 units of the XOR circuit 912 and the high-order second logical AND circuit 913 respectively perform an operation according to different values of j (here, 2 is a natural number from 2 through p). The XOR circuit 912 is a circuit to which the value of each bit for j digits from the lower order in the q-th multiplicand data unit is input and which outputs their XOR. In addition, high-order second logical AND circuit 913 is a circuit to which the output of the XOR circuit 912 and the value of the bit at the j-th digit from the higher order in the q-th multiplier data unit are input and which outputs their logical AND (the high-order second logical AND described above).

The high-order XOR circuit 914 is a circuit to which the output of the high-order parity logical AND circuit 901, the output of the high-order parity logical AND circuit 911 and the output of each of the p−1 units of the high-order first logical AND circuit 913 are input and which outputs the value of their XOR. The output of the high-order XOR circuit 914 becomes the predicted value P_Z_P[2q] of the high-order parity value of the multiplication result Z being the high-order parity prediction circuit 900.

Next, FIG. 21B is explained. FIG. 21B illustrated the configuration of the second example of the high-order parity prediction circuit 900 in FIG. 19. The configuration of the second example is for a case of using odd-number parity as the parity value.

In the configuration in FIG. 21B, the high-order parity logical AND circuit 901 in the configuration of FIG. 21A is replaced with the high-order parity logical OR circuit 902. The high-order parity logical OR circuit 902 is a circuit to which the parity value P_A[q] of the q-th multiplicand data unit and the parity value P_Y[q] of the value of the q-th multiplier data unit are input and which outputs the value of the OR (the high-order parity OR described above) of their parity values.

The high-order XOR circuit 914 is a circuit to which the output of the high-order parity logical OR circuit 902, the output of the high-order parity logical AND circuit 911 and the output of each of the p−1 units of the high-order second logical AND circuit 913 are input and which outputs the value of their XOR. The output of the high-order XOR circuit 914 becomes the predicted value P_Z_P[2q] of the multiplication result Z being the output of the high-order parity prediction circuit 900.

### 3.4.1.3. Configuration of the Middle-Order Parity Prediction Circuit

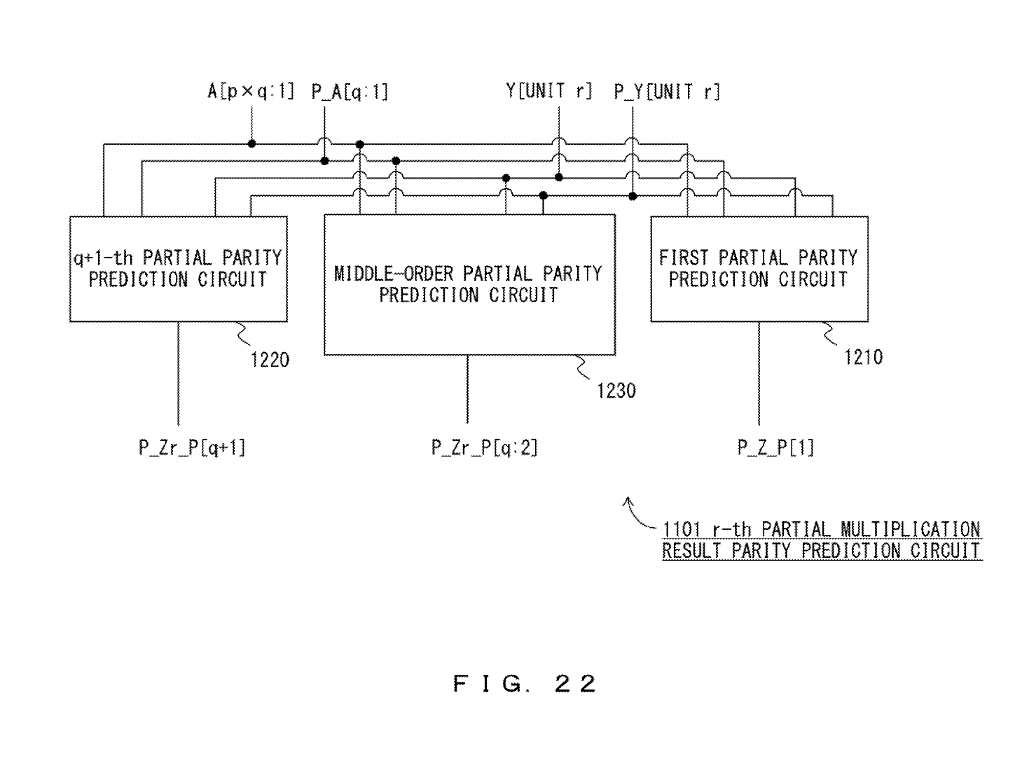

Next, the configuration of the partial multiplication result parity prediction circuit 1100 provided in the middle-order parity prediction circuit 1000 in FIG. 19 is explained with reference to FIG. 22. FIG. 22 illustrates the configuration of the r-th partial multiplication result parity prediction circuit 1101 being one of the q units of the partial multiplication result parity prediction circuit 1100 provided in the middle-order parity prediction circuit 1000 in FIG. 19.

It is assumed that the result of the Carry-Less multiplication of the multiplicand A and the r-th multiplier data unit (here, r is a natural number from 1 through q). The r-th partial multiplication result parity prediction circuit 1101 is a circuit that outputs the predicted values value P_Zr_P[1], P_Zr_P[q+1] of the parity value for each data unit of the r-th partial multiplication result.

The r-th partial multiplication result parity prediction circuit 1101 has, as a parity prediction circuit 1200, a first partial parity prediction circuit 1210, a q+1-th partial parity prediction circuit 1220, and a middle-order partial parity prediction circuit 1230.

The first partial parity prediction circuit 1210 is a circuit that performs prediction of the parity value of the first partial as explained in [2.3.3.1.1. Prediction of the parity value for the first partial]. That is, the first partial parity prediction circuit 1210 is a circuit that outputs the predicted value P_Zr_P[1] of the parity value of the first data unit from the lower order in the r-th partial multiplication result. To the first partial parity prediction circuit 1210, the value A[unit 1] and its parity value p_A[1] of the first multiplicand data unit and the value Y[unit r] and its parity value P_Y[r] of the r-th multiplier data unit are input.

The q+1-th partial parity prediction circuit 1220 is a circuit that performs prediction of the parity value of the q+1-th partial as explained in [2.3.3.1.2. Prediction of the parity value for the q+1-th partial]. That is, the q+1-th partial parity prediction circuit 1220 is a circuit that outputs the predicted value P_Zr_P[q+1] of the parity value of data following the q-th data unit from the lower order in the r-th partial multiplication result (data of the high-order p−1 bit in the r-th partial multiplication result data string). To the q+1-th partial parity prediction circuit 1220, the value A[unit q] and its parity value P_A[q] of the q-th multiplicand data unit and the value Y[unit r] of and its parity value P_Y[r] of the r-th multiplier data unit.

The middle-order partial parity prediction circuit 1230 is a circuit that performs the prediction of the middle-order partial parity value as explained in [2.3.3.1.3. prediction of the party value of the middle-order partial]. That is, the middle-order partial parity prediction circuit 1230 is a circuit that outputs the predicted values P_Zr_P[2], . . . , P_Zr_P[q] of the parity value of the respective data units from second through q-th from the lower order in the r-th partial multiplication result.

To the middle-order partial parity prediction circuit 1230, the value A[unit 1], . . . , A[unit q] of the respective data units from the first multiplicand data unit through the q-th multiplicand data unit. Furthermore, to the middle-order parity prediction circuit 1000, the value Y[unit r] of the r-th multiplier data unit and its parity value P_Y[r] are also input.

Meanwhile, while the r-th partial multiplication result parity prediction circuit 1101 has q−1 units of the middle-order partial parity prediction circuit 1230 that respectively output the parity predicted values P_Zr_P[2], . . . , P_Zr_P[q], FIG. 22 presents only one of them.

### 3.4.1.3.2. Configuration of the First Partial Parity Prediction Circuit

Next, the configuration of the first partial parity prediction circuit 1210 in FIG. 22 is explained.

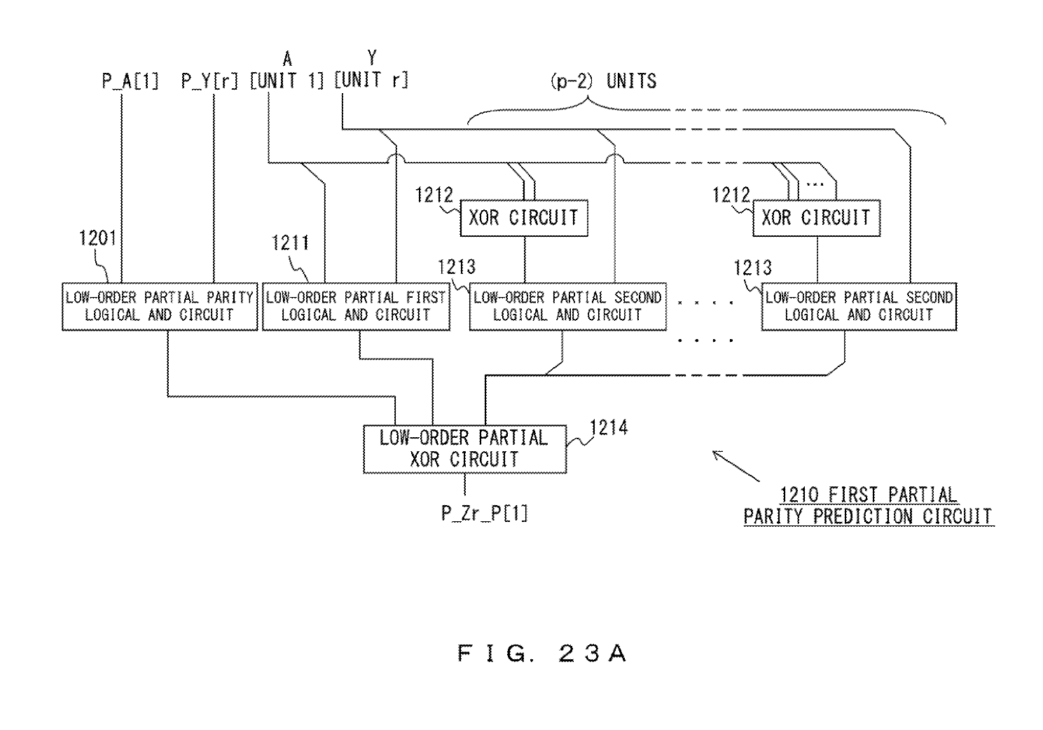

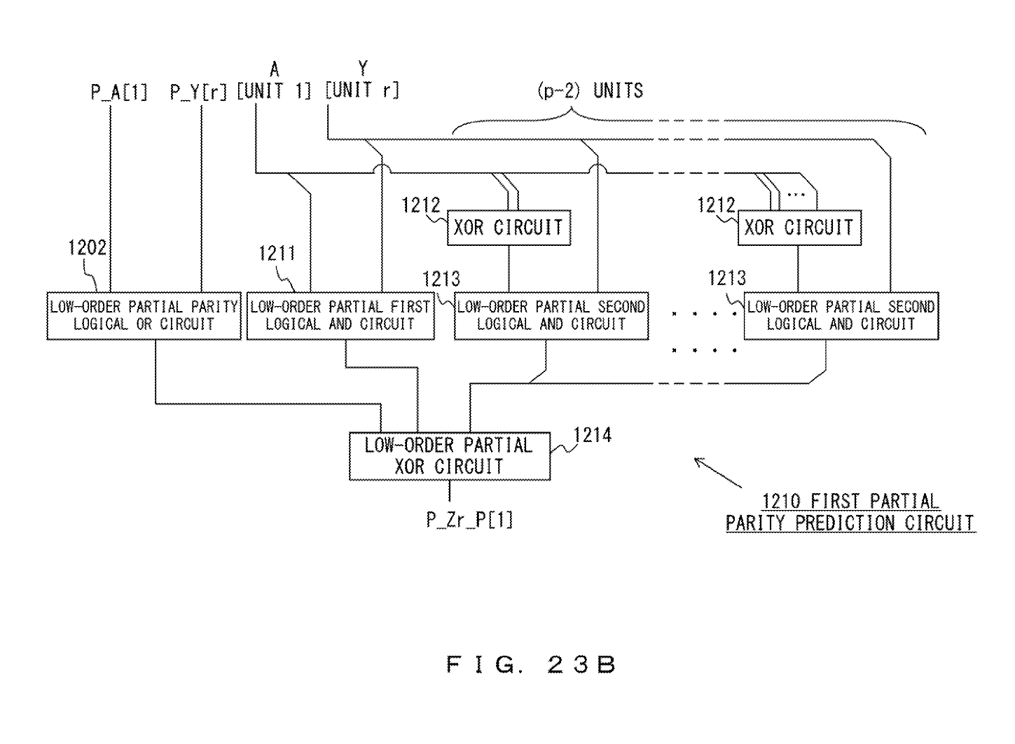

The configuration of the first example of the first partial parity prediction circuit 1210 in FIG. 22 is illustrated in FIG. 23. The configuration of the first example is for a case of using even-number parity as the parity value.

The first partial parity prediction circuit 1210 has a low-order partial parity logical AND circuit 1201, a low-order partial first logical AND circuit 1211, an XOR circuit 1212, a low-order partial second logical AND circuit 1213, and a low-order partial XOR circuit 1214. Among them, the first partial parity prediction circuit 1210 has p−2 units of both the XOR circuit 1212 and the low-order partial second logical AND circuit 1213.

The low-order partial parity logical AND circuit 1201 is a circuit to which the parity value P_A[1] of the first multiplicand data unit and the value of the parity value P_Y[r] of the r-th multiplier are input and which outputs the value of the logical AND (low-order partial parity logical AND described above) of their parity values.

The low-order partial first logical AND circuit 1211 is a circuit to which the value of the highest-order bit of the first multiplicand data unit and the value of the bit at the second digit from the lower order in the r-th multiplier data unit are input and which outputs the value of their logical AND (low-order partial first logical AND described above).

The p−2 units of the XOR circuit 1212 and the low-order partial second logical AND circuit 1213 respectively perform operations according to different values of g (here, g is a natural number from 2 through p−1). The XOR circuit 1212 is a circuit to which the value of each bit for g digits from the higher order in the first multiplicand data unit is input and which outputs the value or their XOR. In addition, the low-order partial second logical AND circuit 1213 is a circuit to which the output of the XOR circuit 1212 and the value of the g+1 bit from the lower order in the r-th multiplier data unit are input and which outputs their logical AND (the low-order partial second logical AND described above).

The low-order partial XOR circuit 1214 is a circuit to which the output of the low-order partial parity logical AND circuit 1201, the output of the low-order partial parity logical AND circuit 1211 and the output of each of the p−2 units of low-order partial second logical AND circuit 1213 are input and which outputs the value of their XOR. The output of the low-order partial XOR circuit 1214 becomes the predicted value P_Zr_P[1] of the parity value of the first partial being the output of first partial parity prediction circuit 1210.

Next, FIG. 23B is explained. FIG. 23B illustrates the configuration of the second example of the first partial parity prediction circuit 1210 in FIG. 22. The configuration of the second example is for a case of using odd-number parity as the parity value.

In the configuration in FIG. 23B, the low-order partial parity logical AND circuit 1201 is replaced by the low-order partial parity OR circuit 1202. The low-order partial parity OR circuit 1202 is a circuit to which the parity value P_A[1] of the first multiplicand data unit and the value of the parity value P_Y[r] of the r-th multiplier data unit are input and which outputs the value of their OR (the low-order partial parity OR) of the parity values.

The low-order partial XOR circuit 1214 is a circuit to which the output of the low-order partial parity OR circuit 1202, the output of the low-order partial parity logical AND circuit 1211 and the output of each of the p−2 units of the low-order partial second logical AND circuit 1213 are input and which outputs the value of their XOR. The output of the low-order partial XOR circuit 1214 becomes the predicted value P_Zr_P[1] of the first partial of the r-th partial multiplication result being the output of the first partial parity prediction circuit 1210.

### 3.4.1.3.3. Configuration of the q+1-th Partial Parity Prediction Circuit

Next, the configuration of the q+1-th partial parity prediction circuit 1220 in FIG. 22 is explained.

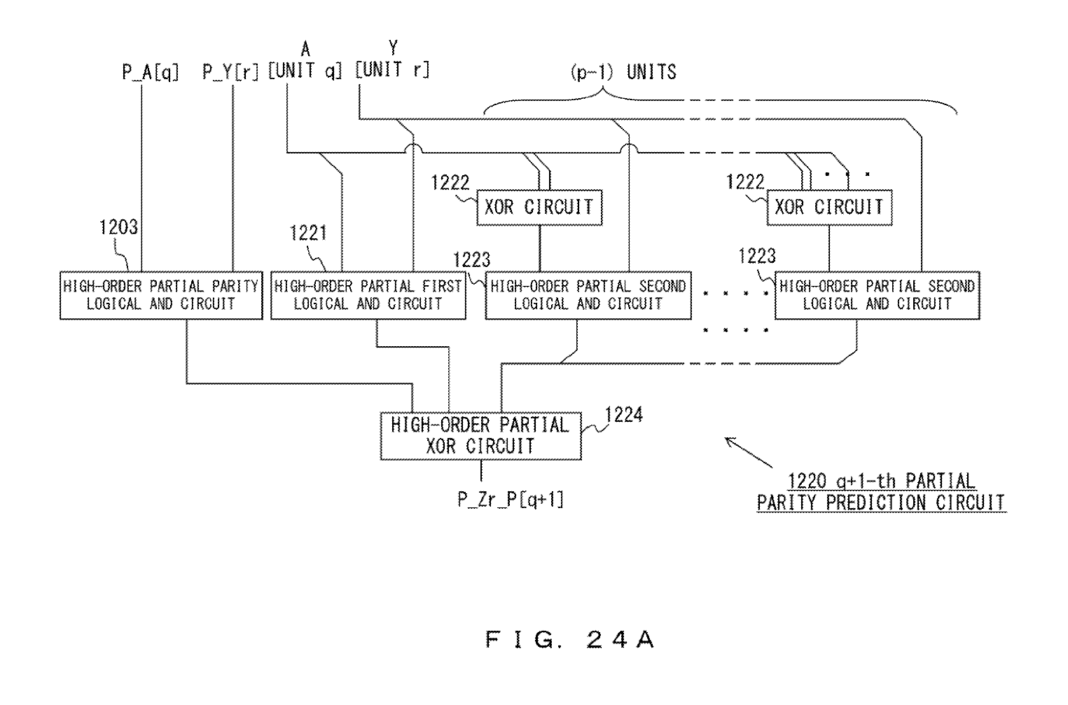

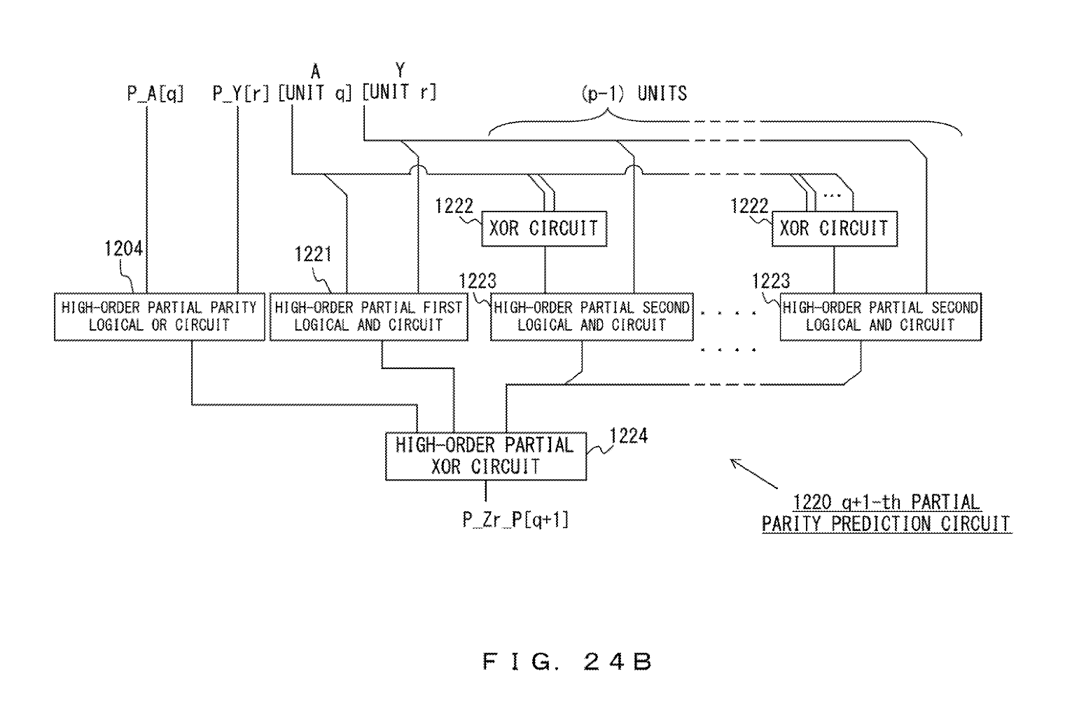

The configuration of the q+1-th partial parity prediction circuit 1220 in FIG. 22 is illustrated in FIG. 24A. The configuration of the first example is for a case of using even-number parity as the parity value.

The q+1-th partial parity prediction circuit 1220 has a high-order partial parity logical AND circuit 1203, a high-order partial first logical AND circuit 1221, the XOR circuit 1222, a high-order partial second logical AND circuit 1223, and a high-order partial XOR circuit 1224. The q+1-th partial parity prediction circuit 1220 hasp−1 units of both the XOR circuit 1222 and the high-order partial second logical AND circuit 1223.

The high-order partial parity logical AND circuit 1203 is a circuit to which the parity value P_A[q] of the q-th multiplicand data unit and the parity value P_Y[r] of the r-th multiplier data unit are input and which outputs the value of the logical AND (the high-order partial parity logical AND described above) of their parity values.

The high-order partial first logical AND circuit 1221 is a circuit to which the value of the lowest-order bit in the q-th multiplicand data unit and the value of the highest-order bit in the r-th multiplier data unit are input and which outputs the value of their logical AND (the high-order partial first logical AND described above).

The p−1 units of the XOR circuit 1222 and the high-order partial second logical AND circuit 1223 respectively perform operations according to difference values of h (here, h is a natural number from 2 through p). The XOR circuit 1222 is a circuit to which the value of each bit for h digits from the lower order in the q-th multiplicand data unit is input and which outputs their XOR. In addition the high-order partial second logical AND circuit 1223 is a circuit to which the output of the XOR circuit 1222 and the value of the bit at the h-th digit from the higher order in the r-th multiplier data unit are input and which outputs the logical AND (the high-order partial second logical AND described above).

The high-order partial XOR circuit 1224 is a circuit to which the output of the high-order partial parity logical AND circuit 1203, the output of the high-order partial parity logical AND circuit 1221 and the output of each of the p−1 units of the high-order partial first logical AND circuit 1223 are input and which outputs the value of their XOR. The output of the high-order partial XOR circuit 1224 becomes the predicted value P_Zr_P[q+1] of the q+1-th partial of the r-th partial multiplication result being the output of the q+1-th partial parity prediction circuit 1220.

Next, FIG. 24B is explained. FIG. 24B illustrates the configuration of the second example of the q+1-th partial parity prediction circuit 1220 in FIG. 22. The configuration of the second example is for a case of using odd-number parity as the parity value.

In the configuration in FIG. 24B, the high-order partial parity logical AND circuit 1203 is replaced by the high-order partial parity OR circuit 1204. The high-order partial parity OR circuit 1204 is a circuit to which the parity value parity value P_A[q] of the q-th multiplicand data unit and the value of the parity value P_Y[r] of the r-th multiplier data unit are input and which outputs the value of the OR (the high-order partial parity OR) of their parity values.

The high-order partial XOR circuit 1224 is a circuit to which the output of high-order partial parity logical OR circuit 1204, the output of the high-order partial parity logical AND circuit 1221 and the output of each of the p−1 high-order partial second logical AND circuit 1223 are input and which outputs the value of their XOR. The output of the high-order partial XOR circuit 1224 becomes the predicted value P_Zr_P[q+1] of the q+1-th partial of the r-th partial multiplication result being the output of the first partial parity prediction circuit 1210.

### 3.4.1.3.4. Configuration of the Middle-Order Partial Parity Prediction Circuit

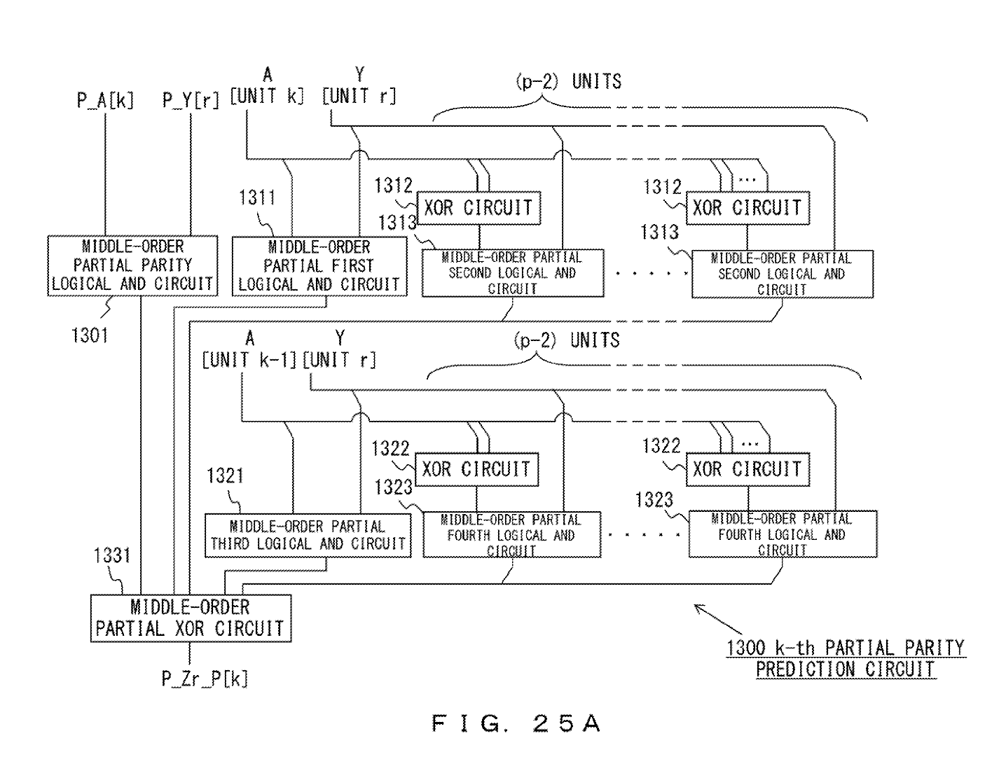

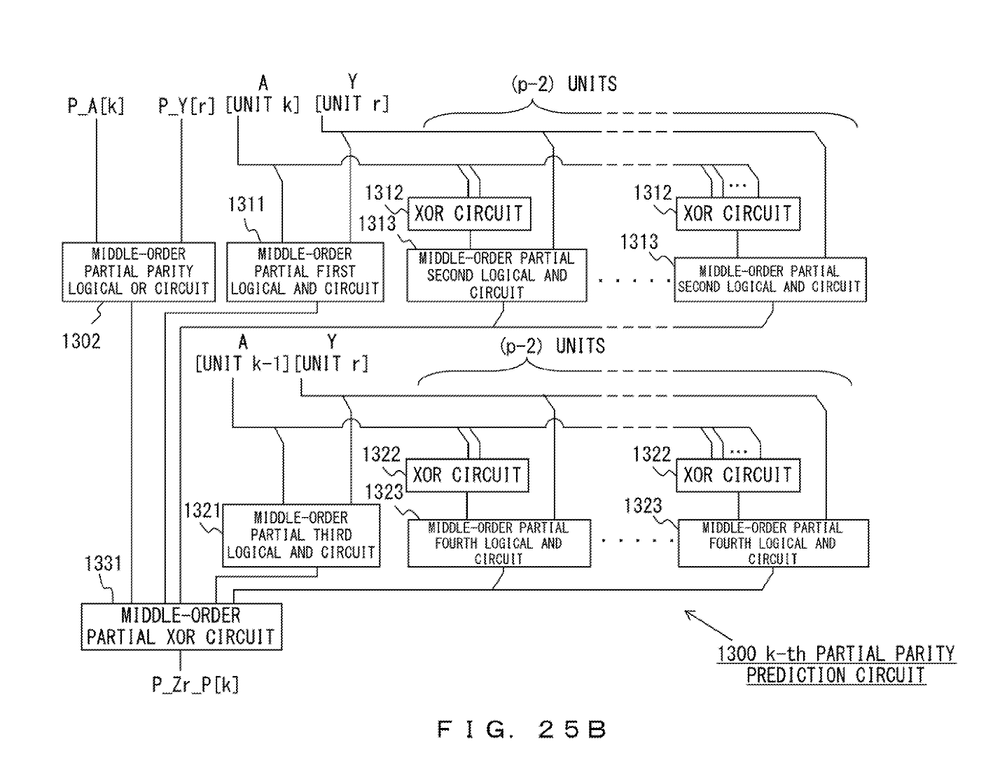

Next, the configuration of the middle-order partial parity prediction circuit 1230 in FIG. 22 is explained. FIG. 25A illustrates the configuration of the first example of the k-th partial parity prediction circuit 1300 being one of the q−1 units of middle-order partial parity prediction circuit 1230 provided in the r-th partial multiplication result parity prediction circuit 1101.

The k-th partial parity prediction circuit 1300 is a circuit that outputs the predicted value P_Zr_P[k] of the k-th (here, k is a natural number from 2 through q) data unit (the k-th partial described above) from the lower order in the r-th partial multiplication result.

To the k-th partial parity prediction circuit 1300, the value A[unit k] and its parity value P_A[k] of the k-th multiplicand data unit, and the value Y[unit r] and its parity value P_Y[r] of the r-th multiplier data unit are input. Furthermore, to the k-th partial parity prediction circuit 1300, the value A[unit k−1] of the k−1-th multiplicand data unit is also input.

The k-th partial parity prediction circuit 1300 has a middle-order partial parity logical AND circuit 1301, a middle-order partial first logical AND circuit 1311, an XOR circuit 1312, and a middle-order partial second logical AND circuit 1313. The k-th partial parity prediction circuit 1300 has p−2 units of both the XOR circuit 1312 and the middle-order partial second logical AND circuit 1313 among them.

The middle-order partial parity logical AND circuit 1301 is a circuit to which the parity value P_A[k] of the k-th multiplicand data unit and the parity value P_Y[r] of the value of the r-th multiplier data unit are input and which outputs the value of the logical AND of their parity value (the middle-order partial parity logical AND described above).

The middle-order partial first logical AND circuit 1311 is a circuit to which the value of the highest-order bit in the k-th multiplicand data unit and the value of the bit at the second digit from the lower order in the r-th multiplier data unit are input and which outputs the value of their logical AND (the middle-order partial first logical AND described above).

The p−2 units of the XOR circuit 1312 and the middle-order partial second logical AND circuit 1313 respectively perform operations according to difference values of m (here, m is a natural number from 2 through p−1). The XOR circuit 1312 is a circuit to which the value of each bit for m digits from the higher order in the k-th multiplicand data unit is input and which outputs the value of their XOR. In addition, middle-order partial second logical AND circuit 1313 is a circuit to which the output of the XOR circuit 1312 and the value of the bit at the m+1-th digit from the lower order in the r-th multiplier data unit are input and which outputs the logical AND (the middle-order partial second logical AND described above).

The middle-order partial third logical AND circuit 1321 is a circuit to which the value of the highest-order bit in the k−1-th 1 multiplicand data unit and the value of the bit at the second digit from the lower order in the r-th multiplier data unit are input and which outputs the value of their logical AND (the middle-order partial third logical AND described above).

The p−2 units of the XOR circuit 1322 and the middle-order partial fourth logical AND circuit 1323 respectively perform operations according to difference values of n (here, n is a natural number from 2 through p−1). The XOR circuit 1322 is a circuit to which the value of each bit for n digits from the higher order in the k−1-th multiplicand data unit is input and outputs the value of their XOR. In addition, the middle-order partial fourth logical AND circuit 1323 is a circuit to which the output of the XOR circuit 1322 and the value of the bit at the n+1-th digit from the lower order in the r-th multiplier data unit are input and which outputs the logical AND (the middle-order partial fourth logical AND described above).

The middle-order partial XOR circuit 1331 is a circuit to which the middle-order partial parity logical AND, the middle-order partial first logical AND, the middle-order partial second logical AND, middle-order partial third logical AND and the middle-order partial fourth logical AND are input and which outputs the value of their XOR. The output of the middle-order partial XOR circuit 1331 becomes the predicted value P_Zr_P[k] of the parity value of the k-th partial of the r-th partial multiplication result being the output of the k-th partial parity prediction circuit 1300.

Next, FIG. 25B is explained. FIG. 25B illustrates the configuration of the second example of the k-th partial parity prediction circuit 1300 being one of q−1 units of the middle-order partial parity prediction circuit 1230 provided in the r-th partial multiplication result parity prediction circuit 1101. The configuration of the second example is for the case of using odd-number parity as the parity value.

In the configuration in FIG. 25B, the middle-order partial parity logical AND circuit 1301 in the configuration in FIG. 25A is replaced by the middle-order partial parity OR circuit 1302. The middle-order partial parity OR circuit 1302 is a circuit to which the parity value parity value P_A[q] of the q-th multiplicand data unit and the parity value P_Y[r] of the value of the r-th multiplier data unit are input and which outputs the value of the OR (the middle-order partial parity OR described above) of the parity values

The middle-order partial XOR circuit 1331 is a circuit to which the middle-order partial parity OR, the middle-order partial first logical AND, the middle-order partial second logical AND, the middle-order partial third logical AND, and the middle-order partial fourth logical AND are input and which outputs the value of their XOR. The output of the middle-order partial XOR circuit 1331 becomes the predicted value P_Zr_P[k] of the k-th partial of the r-th partial multiplication result being the output of the k-th partial parity prediction circuit 1300.

By the configuration described above, all of the predicted values P_Zr_P[1], . . . , P_Zr_P[q+1] for each data unit of the r-th partial multiplication result are obtained for all the values that r (r is a natural number from 1 through q) may take are obtained.

### 3.4.1.3.5. Specific Configuration of the Middle-Order Parity Prediction Circuit

Next, the specific configuration of the middle-order parity prediction circuit 1000 in FIG. 19 is explained.

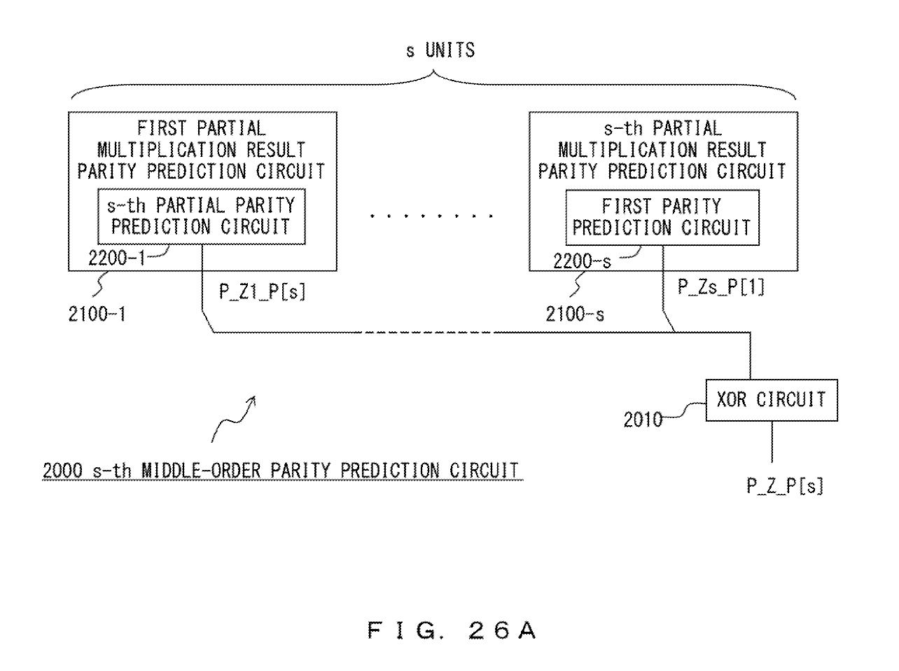

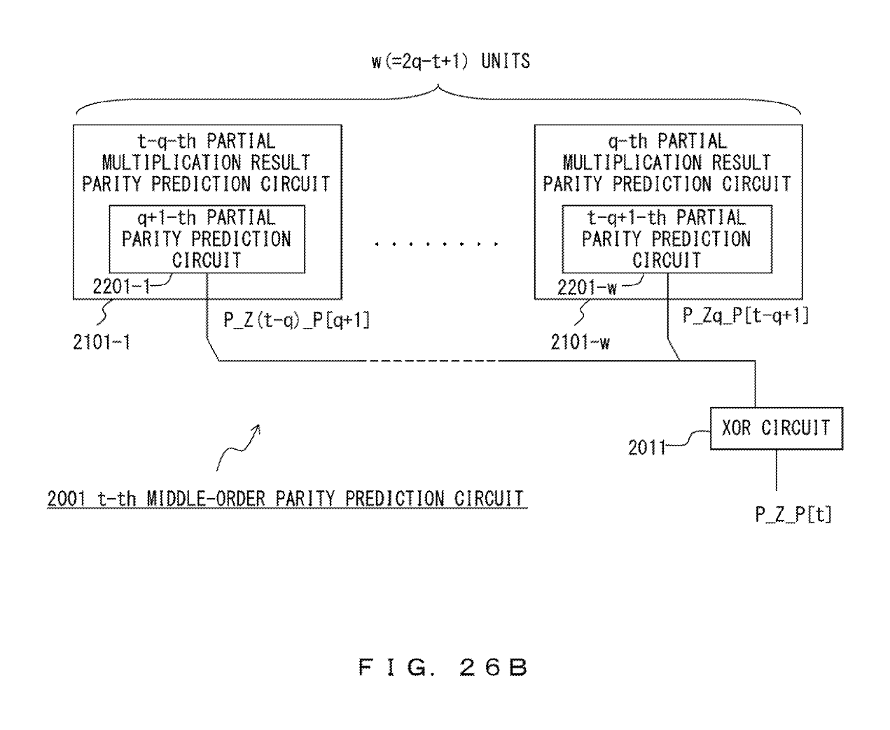

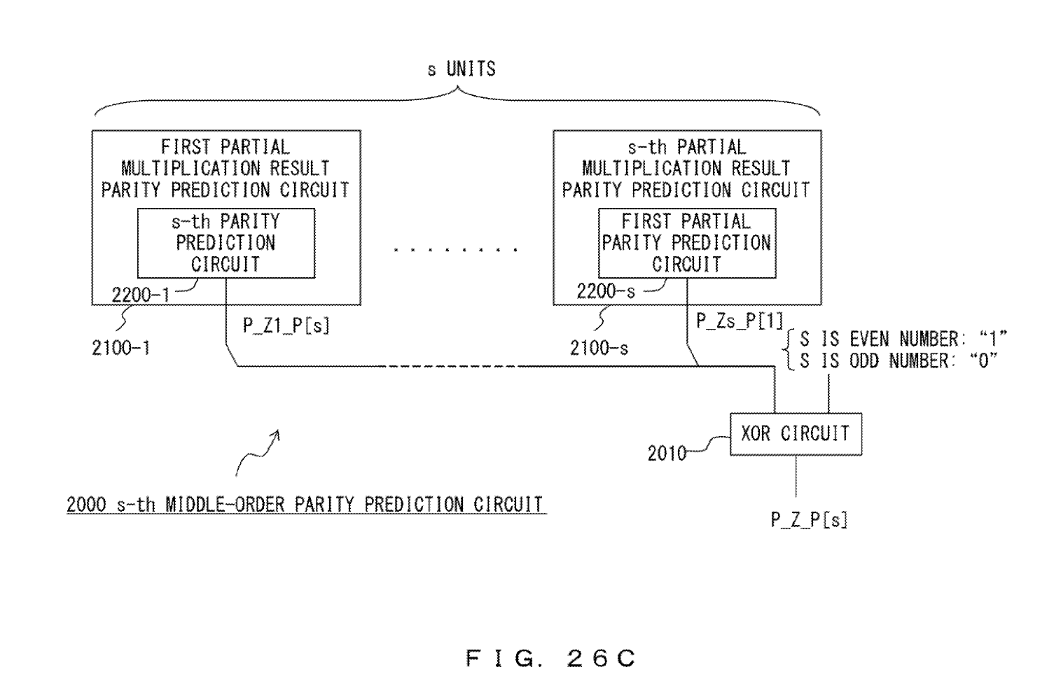

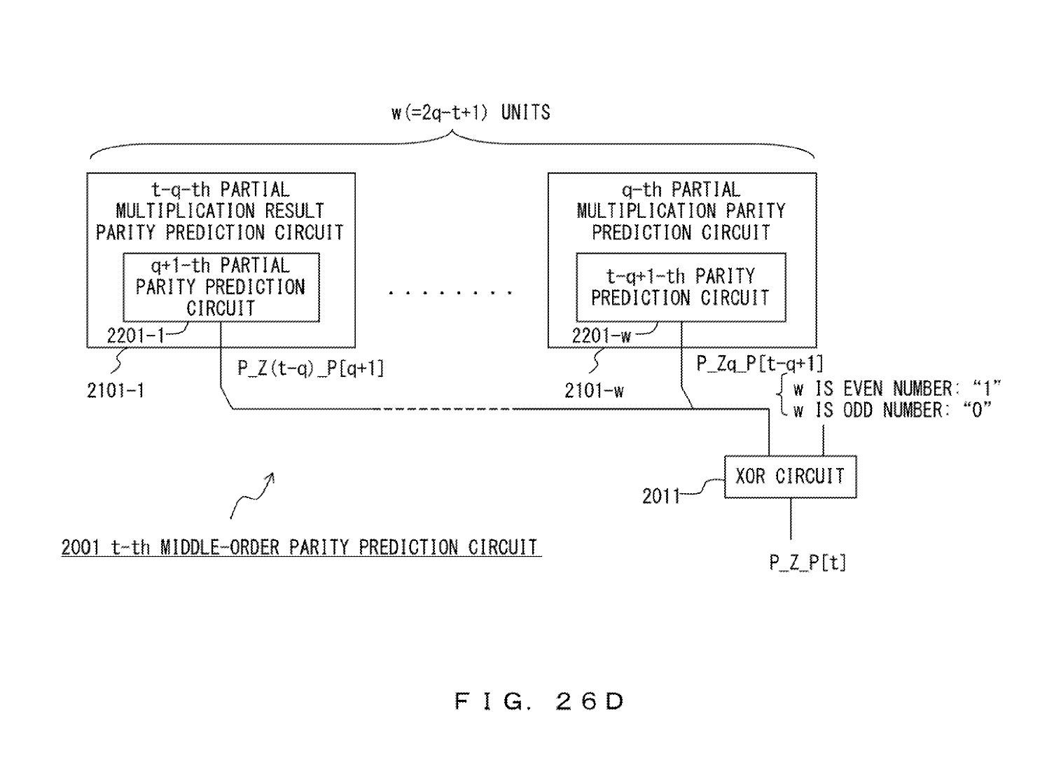

As described above, the Carry-Less multiplication parity prediction circuit 202 in FIG. 18 as 2q−2 units of the middle-order parity prediction circuit 1000 that respectively output the [symbol] , parity predicted values P_Z_P[2], . . . , P_Z_P[2q−1]. FIG. 26A and FIG. 26B respectively illustrates the first example of the s-th middle-order parity prediction circuit and the first example of the t-th middle-order parity prediction circuit being one of the middle-order parity prediction circuit 1000. Meanwhile, the configuration of these first examples is for a case of using even-number parity as the parity value.

The s-th middle-order parity prediction circuit 2000 is a circuit that outputs the predicted value P_Z_P[2], . . . , P_Z_P[q] of the parity value of the s-th data unit (here, s is a natural number from 2 through q) from the lower order in the multiplication result Z. In addition, the multiplication result Z is a circuit that outputs the predicted values P_Z_P[q+1], . . . , P_Z_P[2q−1] of the t-th data unit (here, t is a natural number from q+1 through 2q−1) from the lower order in the multiplication result Z.

In FIG. 26A, the s-th partial parity prediction circuit 2200-1 that the first partial multiplication result parity prediction circuit 2100-1 has outputs the parity predicted value P_Z1_P[s] of the s-th partial of the first partial multiplication result. In addition, the first partial parity prediction circuit 2200-s that the s-th partial multiplication result parity prediction circuit 2100-s has outputs the parity predicted value P_Zs_P[1] of the first partial of the s-th partial multiplication result.

To the XOR circuit 2010, the parity predicted values that the s-u+1-th (here, u is a natural number from 1 through s) partial parity prediction circuits that the u-th partial multiplication result parity prediction circuits are input, and the XOR circuit 2010 outputs the XOR of the s parity predicted values. The output of the XOR circuit 2010 becomes the predicted value P_Z_P[s] of the parity value of the s-th data unit from the lower order in the multiplication result Z being the output of the s-th middle-order parity prediction circuit 2000.

In addition, in FIG. 26B, the q+1-th partial parity prediction circuit 2201-1 that the t-q-th partial multiplication result parity prediction circuit 2101-1 has outputs the parity predicted value P_Z(t-q)_P[q+1] of the q+1-th partial of the t-q-th partial multiplication result. In addition, assuming w=2q-t+1, the t-q+1-th partial parity prediction circuit 2201-w that the q-th partial multiplication result parity prediction circuit 2101-w has outputs the parity predicted value P_Zq_P[t-q+1] of the t-q+1-th partial of the q-th partial multiplication result.

To the XOR circuit 2011 output, the parity predicted values output from the t-v+1-th partial parity prediction circuits that the v-th (here, v is a natural number from t-q through q) partial multiplication result parity prediction circuits have, and outputs the XOR of the w parity predicted values. The output of the XOR circuit 2011 becomes the predicted value P_Z_P[t] of the parity value of the t-th data unit from the lower order in the multiplication result Z.

Next, FIG. 26C and FIG. 26D are explained. FIG. 26C and FIG. 26D respectively illustrates the second example of the s-th middle-order parity prediction circuit 2000 and the second example of the t-th middle-order parity prediction circuit 2001 being one of the middle-order parity prediction circuit 1000 in FIG. 19. The configuration of these second examples is for a case of using odd-number parity as the parity value.

In the configuration of the s-th middle-order parity prediction circuit 2000 in FIG. 26C, one input of a value of constant is added to the XOR circuit 2010 in the configuration in FIG. 26A. The value of constant is set to the value “1” when s is an even number, and set to the value “0” when s is an odd number.

Meanwhile, when using odd-number parity as the parity value, instead of configuring the s-th middle-order parity prediction circuit 2000 as in FIG. 26C, the s-th middle-order parity prediction circuit 2000 may be configured by adding a negative circuit to the configuration in FIG. 26A. That is, in the configuration in FIG. 26A, the configuration may be made so that only when s is an even number, the output of the XOR circuit 2010 whose logic is inverted using the negative circuit becomes the predicted value P_Z_P[s] of the parity value of the s-th data unit from the lower order in the multiplication result Z.

In addition, in the configuration of the t-th middle-order parity prediction circuit 2001 in FIG. 26D, one input of a value of constant is added to the XOR circuit 2011 in the configuration in FIG. 26B. The value of constant is set to the value “1” when w (=2q-t+1) is an even number, and set to the value “0” when w is an odd number.

Meanwhile, when using odd-number parity as the parity value, instead of configuring the t-th middle-order parity prediction circuit 2001 as in FIG. 26D, the t-th middle-order parity prediction circuit 2001 may be configured by adding a negative circuit to the configuration in FIG. 26B. That is, in the configuration in FIG. 26B, the configuration may be made so that only when s is an even number, the output of the XOR circuit 2011 whose logic is inverted using the negative circuit becomes the predicted value P_Z_P[t] of the parity value of the t-th data unit from the lower order in the multiplication result Z.

By the configuration described above, the parity predicted values P_Z_P[2], . . . , P_Z_P[2q−1] of the respective data units from the second through 2q−1 from the lower order in the multiplication result Z are output from the middle-order parity prediction circuit 1000. Therefore, by the middle-order parity prediction circuit 1000 and the low-order parity prediction circuit 800 and the high-order parity prediction circuit 900, the parity predicted values P_Z_P[1], . . . , P_Z_P[2q] of the respective data units of the multiplication result Z are obtained.

Thus, in any of the embodiments described above, the malfunction of the Carry-Less multiplication circuit 201 may be detected using the Carry-Less multiplication parity prediction circuit 202.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A parity predictor configured to predict a parity value of a Carry-Less multiplication result of a multiplicand data string and a multiplier data string being two data strings in which q (q is a natural number) data units being p-bit (p is a natural number equal to two or above) data, the parity predictor comprising:
a low-order parity prediction unit configured to predict a parity value of a first data unit from lower order in a multiplication result data string representing the Carry-Less multiplication result based on a value and a parity value of a first data unit being a first data unit from lower order in each of the multiplicand data string and the multiplier data string; and
a high-order parity prediction unit configured to predict a parity value for data at a high-order p−1 bit of the multiplication result data string being data following 2q−1-th data unit from lower order in the multiplication result data string, based on a value and a parity value for a q-th data unit being a q-th data unit from lower order in each of the multiplicand data string and the multiplier data string.

2. A parity predictor according to claim 1, further comprising
a middle-order parity prediction unit configured to predict, when the multiplicand data string and the multiplier data string are respectively a data string in which a plurality of the data units are lined up, a parity value of respective data units from second through 2q−1-th from lower order in the multiplication result data string, based on a value and a parity value of respective data units from a first data unit being a first data unit from lower order through a q-th data unit being q-th unit from lower order in each of the multiplicand data string and the multiplier data string.

3. A parity predictor according to claim 1, wherein
the parity value is even-number parity, and
the low-order parity prediction unit includes:
a low-order parity logical AND circuit configured to output a logical AND of a parity value of a first data unit of each of the multiplicand data string and the multiplier data string;
a low-order first logical AND circuit configured to output a logical AND of a value of a highest-order bit in the first data unit of the multiplicand data string and a value of a bit at a second digit from lower order in the first data unit of the multiplier data string;
p−2 units of a low-order second logical AND circuit configured to respectively output a logical AND of an XOR of values of respective bits for i (i is a natural number from 2 through p−1) digits from higher order in the first data unit in the multiplicand data string and a value of a bit at a i+1 digit from lower order in the first data unit of the multiplier data string; and
a low-order XOR circuit configured to output an XOR of an output of the low-order parity logical AND circuit, an output of the low-order first logical AND circuit and an output of all the p−2 units of the low-order second logical AND circuits, as a prediction result by the low-order parity prediction unit.

4. The parity predictor according to claim 1, wherein
the parity value is even-number parity, and
the high-order parity prediction unit includes:
a high-order parity logical AND circuit configured to output a logical AND of a parity value of a q-th data unit of each of the multiplicand data string and the multiplier data string;
a high-order first logical AND circuit configured to output a value of the lowest-order bit in the q-th data unit of the multiplicand data string and a value of the highest-order bit in the q-th data unit of the multiplier data string;
p−1 units of a high-order second logical AND circuit configured to respectively output a logical AND of an XOR of values of respective bits for j (j is a natural number from 2 through q) digits from lower order in the q-th data unit in the multiplicand data string and a value of a bit at a j-th digit from higher order in the q-th data unit of the multiplier data string; and
a high-order XOR circuit configured to output an XOR of an output of the high-order parity logical AND circuit, an output of the high-order first logical AND circuit and an output of all of the p−1 units of the high-order second logical AND circuits as a prediction result by the high-order parity prediction unit.

5. The parity predictor according to claim 2, wherein
the middle-order parity prediction unit includes a partial multiplication result parity prediction unit configured to predict a parity value of each data unit of a partial multiplication result data string being a data unit constituting the multiplicand data string and the multiplier data string, and
the middle-order parity prediction unit predicts a parity value of respective data units from second through 2q−1-th from lower order in the multiplication result data string, based on a prediction result by the partial multiplication result parity prediction.

6. The parity predictor according to claim 5, wherein
the partial multiplication result parity prediction unit includes an r-th partial multiplication result parity prediction unit configured to predict a parity value of each data unit of the partial multiplication result data string assuming an r-th multiplier data unit being an r-th (r is a natural number from 1 through q) data unit from lower order in the multiplier data string as the partial multiplier data, and
and the r-th partial multiplication result parity prediction includes:
a first partial parity prediction unit configured to predict a parity value of a first data unit from lower order in the partial multiplication result data string, based on a value and parity value for the first data unit of the multiplicand data string and a valve and a parity value for the r-th multiplier data unit;
a q+1-th partial parity prediction unit configured to predict a parity value for data of a high-order p−1 bit of the partial multiplication result data string being data following a q-th data unit from lower order in the partial multiplication result data string, based on a value and a parity value of the q-th data unit in the multiplicand data string and a value and a parity value of the r-th multiplier data unit; and
a middle-order partial parity prediction unit configured to predict a parity value respective data units from second through q-th from lower order in the partial multiplication result data string, based on a value and a parity value of respective data units from the first data unit through the q-th data unit and a value and a parity value of the r-th multiplier data unit.

7. The parity predictor according to claim 6, wherein
the parity value is even-number parity, and
the first partial parity prediction unit includes:
a low-order partial parity logical AND circuit configured to output a logical of a parity value of a first data unit in the first partial parity prediction unit and a parity value of the r-th multiplier data unit;
a low-order partial first logical AND circuit configured to output a logical AND of a value of a highest-order bit in the first data unit of the multiplicand data string and a value of a bit at a second digit from lower order in the r-th multiplier data unit;
p−2 units of a low-order partial second logical AND circuit configured to respectively output a logical AND of an XOR of values of respective bits for g (g is a natural number from 2 through p−1) digits from high order in the first data unit of the multiplicand data string and a value of a bit at a g+1 digit from lower order in the r-th multiplier data unit; and
a low-order partial XOR circuit configured to output an XOR of an output of the low-order partial parity logical AND circuit, an output of the low-order partial first logical AND circuit and an output of all of the p−2 units of the low-order partial second logical AND circuit as a prediction result by the first partial parity prediction unit.

8. The parity predictor according to claim 6, wherein
the parity value is even-number parity, and
the q+1-th partial parity prediction unit includes:
a high-order partial parity logical AND circuit configured to output a logical AND of a parity value of the q-th data unit in the multiplicand data string and a parity value of the r-th multiplier data unit;
a high-order partial first logical AND circuit configured to output a logical AND of a value of a lowest-order bit in the q-th data unit in the multiplicand data string and a value of a highest-order bit of the r-th multiplier data unit;
p−1 units of a high-order partial second logical AND circuit configured to respectively output a logical AND of an XOR of respective bits for h (h is a natural number from 2 through p) digits from lower order in the q-th data unit in the multiplicand data string and a value of a bit at an h-th digit from higher order in the r-th multiplier data unit; and
a high-order partial XOR circuit configured to output an output of the high-order partial parity logical AND circuit, an output of the high-order partial first logical AND circuit, an output of all of the p−1 units of high-order partial second logical AND circuit, as a prediction result by the q+1-th partial parity prediction unit.

9. The parity predictor according to claim 6, wherein
the parity value is even-number parity, and
the middle-order partial parity prediction unit includes a k-th partial parity prediction unit configured to predict a parity value of a k-th (k is a natural number from 2 through q) from lower order in the partial multiplication result data string, and
the k-th partial parity prediction includes:
a middle-order partial parity logical AND circuit configured to output a logical AND of a parity value of the k-th data unit of the multiplicand data string and a parity value of the r-th multiplier data unit;
a middle-order partial first logical AND circuit configured to output a highest-order bit in the k-th data unit of the multiplicand data string and a value of a bit at a second digit from lower order in the r-th data;
p−2 units of a middle-order partial second logical AND circuit configured to respectively output a logical AND of an XOR of values of respective bits form (m is a natural number from 2 through p−1) digits from higher order in the k-th data unit in the multiplicand data string and a value of a bit at an m+1 digit from lower order in the r-th multiplier data unit;
a middle-order partial third logical AND circuit configured to output a logical AND of a value of a highest-order bit in a k−1-th data unit of the multiplicand data string and a value of a bit at a second digit from lower order in the r-th multiplier data unit;
p−2 units of a middle-order partial fourth logical AND circuit configured to respectively output a logical AND of an XOR of values of respective bits for n (n is a natural number from 2 through p−1) digits from higher order in the k−1-th data unit of the multiplicand data string and a value of a bit at an n+1 digit from lower order in the r-th multiplier data unit; and
a middle-order partial XOR circuit configured to output an XOR of an output of the middle-order partial parity logical AND circuit, an output of the middle-order partial first logical AND circuit, an output of all of the p−2 units of the middle-order partial second logical AND circuit, an output of the middle-order partial third logical AND circuit, and an output of all of the p−2 units of the middle-order partial fourth logical AND circuit, as a prediction result by the k-th parity prediction unit.

10. The parity predictor according to claim 9, wherein
the middle-order parity prediction unit includes
an s-th middle-order parity prediction unit configured to predict a parity value of an s-th (s is a natural number from 2 through q) data unit from lower order in the multiplication result data string; and
a t-th middle-order parity prediction unit configured to predict a parity value of a t-th (t is a natural number from 2 through 2q−1) data unit from lower order in the multiplication result data string, and
the s-th middle-order parity prediction unit includes an XOR circuit configured to output an XOR of a prediction result of a parity value by s-u+1-th (u is a natural number from 1 through s) partial parity prediction unit owned by a u-th partial multiplication result parity prediction unit, as a prediction result of a parity value of an s-th data unit, and
the t-th middle-order parity prediction unit includes an XOR circuit configured to output an XOR of a prediction result of a parity value by a t-v+1-th (v is a natural number from t-q through q) partial parity prediction unit owned by a v-th partial multiplication result parity prediction unit, as a prediction result of a parity value of a t-th data unit from lower order in the multiplication result data string.

11. The parity predictor according to claim 1, wherein
the parity value is odd-number parity, and
the low-order parity prediction unit includes:
a low-order parity OR circuit configured to output an OR of a parity value of each first data unit of the multiplicand data string and the multiplier data string;
a low-order first logical AND circuit configured to output an logical AND of a value of a highest-order bit in the first data unit of the multiplicand data string and a value of a bit at a second digit from lower order in the first data unit in the multiplier data string;
p−2 units of a low-order second logical AND circuit configured to respectively output a logical AND of an XOR of values of respective bits for i (i is a natural number from 2 through p−1) digits from higher order in the first data unit of the multiplicand data string and a value of a bit at an i+1 digit from lower order in the first data unit in the multiplier data string; and
a low-order XOR circuit configured to output an XOR of an output of the low-order parity OR circuit, an output of the low-order first logical AND circuit and an output of all of the p−2 units of the low-order second logical AND circuit, as a prediction result by the low-order parity prediction unit.

12. The parity predictor according to claim 1, wherein
the parity value is odd-number parity, and
the high-order parity prediction unit includes:
a high-order parity OR circuit configured to output an OR of a parity value of a q-th data unit of each of the multiplicand data string and the multiplier data string;
a high-order first logical AND circuit configured to output a logical AND of a value of a lowest-order bit in the q-th data unit of the multiplicand data string and a value of a highest-order bit in the q-th data unit in the multiplier data string;
p−1 units of a high-order second logical AND circuit configured to respectively output a logical AND of an XOR of respective bits for j (j is a natural number from 2 through p) digits from lower order in the q-th data unit of the multiplicand data string and a value of a bit at a j-th digit from higher order in the q-th data unit of the multiplier data string; and
a high-order XOR circuit configured to output an outpour of the high-order parity OR circuit, an output of the high-order first logical AND circuit and an output of all of the p−1 units of the high-order second logical AND circuit as a prediction result by the high-order parity prediction unit.

13. The parity predictor according to claim 6, wherein
the parity value is odd-number parity, and
the first partial parity prediction unit includes:
a low-order partial parity OR circuit configured to output an OR of a parity value of the first data unit in the multiplicand data string and a parity value of the r-th multiplier data unit;
a low-order partial first logical AND circuit configured to output a logical AND of a value of a highest order bit in the first data unit of the multiplicand data string and a value of a bit at a second digit from lower order in the r-th multiplier data unit;
p−2 units of a low-order partial second logical AND circuit configured to respectively output a logical AND of an XOR of values of respective bits for g (g is a natural number from 2 through p−1) from higher order in the first data unit of the multiplicand data string and a value of a bit at a g+1 digit from lower order in the r-th multiplier data unit; and
a low-order partial XOR circuit configured to output an output of the low-order partial parity OR circuit, and low-order partial first logical AND circuit and an output of all of the p−2 units of the low-order partial second logical AND circuit as a prediction result by the first partial parity prediction unit.

14. The parity predictor according to claim 6, wherein
the parity value is odd-number parity, and
the q+1-th partial parity prediction unit includes:
a high-order partial parity OR circuit configured to output an OR of a parity value of the q-th data unit in the multiplicand data string and a parity value of the r-th multiplier data unit;
a high-order partial first logical AND circuit configured to output a logical AND of a value of a lowest order bit in the q-th data unit in the multiplicand data string and a value of a highest order bit in the r-th multiplier data unit;
p−1 units of a high-order partial second logical AND circuit configured to respectively output a logical AND of an XOR or values of respective bits for h (h is a natural number from 2 through p) digits from lower order in the q-th data unit in the multiplicand data string and a value of a bit at an h-th digit from higher order in the r-th multiplier data unit; and
a high-order partial XOR circuit configured to output an XOR of an output of the high-order partial parity OR circuit, an output of the high-order partial first logical AND circuit and an output of all of the p−1 high-order partial second logical AND circuit, as a prediction result by the q+1-th partial parity prediction.

15. The parity predictor according to claim 6, wherein
the parity value is odd-number parity, and
the middle-order partial parity prediction unit includes a k-th partial parity prediction unit configured to predict a parity value of a k-th (k is a natural number from 2 through q) data unit from lower order in the partial multiplication result data string, and
the k-th partial parity prediction unit includes:
a middle-order partial parity OR circuit configured to output an OR of a parity value of the k-th data unit in the multiplicand data string and a parity value of the r-th multiplier data unit;
a middle-order partial first logical AND circuit configured to output a value of a highest-order bit in the k-th data unit in the multiplicand data string and a value of a bit at a second digit from lower order in the r-th data;
p−2 units of a middle-order partial second logical AND circuit configured to respectively output a logical AND of an XOR of values of respective bits form (m is a natural number from 2 through p−1) digits from higher order in the k-th data unit in the multiplicand data string and a value of a bit at an m+1 digit from lower order in the r-th multiplier data unit;
a middle-order partial third logical AND circuit configured to output a logical AND of a value of a highest-order bit in the k−1-th data unit of the multiplicand data string and a value of a bit at a second digit from lower order in the r-th multiplier data unit;
p−2 units of a middle-order partial fourth logical AND circuit configured to respectively output a logical AND of an XOR of values of respective bits for n (n is a natural number from 2 through p−1) digits from higher order in the k−1-th data unit in the multiplicand data string and a value of a bit at an n+1 digit from lower order in the r-th multiplier data unit; and
a middle-order partial XOR circuit configured to outpour an XOR of an output of the middle-order partial parity OR circuit, an output of the middle-order partial first logical AND circuit, an output of all of the p−2 units of the middle-order partial second logical AND circuit, an output of the middle-order partial third logical AND circuit and an output of all of the p−2 units of the middle-order partial fourth logical AND circuit, as a prediction result by the k-th parity prediction unit.

16. The parity predictor according to claim 15, wherein
the middle-order parity prediction unit includes:
an s-th middle-order parity prediction unit configured to predict a parity value of an s-th (s is a natural number from 2 through q) data unit from lower order in the multiplication result data string; and
a t-th middle-order parity prediction unit configure to predict a parity value of a t-th (t is a natural number from q+1 through 2q−1) data unit from lower order in the multiplication result data string, and
the s-th middle-order parity prediction unit includes an XOR circuit configured to output an XOR of a prediction result of a parity value by an s-u+1-th (u is a natural number from 1 through s) partial parity prediction unit that a u-th partial multiplication result parity prediction unit has and a first value of constant as a prediction result of a parity value of the s-th data unit from lower order in the multiplication result data string,
the first value of constant is “1” when a value of s is an even number and “0” when the value of s is an odd number,
the t-th t middle-order parity prediction unit includes an XOR circuit configured to output an XOR of a prediction result of a parity value by an t-v+1-th (v is a natural number from t-q through q) partial parity prediction unit that a v-th partial multiplication result parity prediction unit has and a second value of constant as a prediction result of a parity value of the t-th data unit from lower order in the multiplication result data string, and
the first value of constant is “1” when a value of 2q-t+1 is an even number and “0” when the value of 2q-t+1 is an odd number.

17. A Carry-Less multiplier configured to perform Carry-Less multiplication of a multiplicand data string and a multiplier data string being two data strings in which q (q is a natural number) data units being p-bit (p is a natural number equal to two or above) data, the Carry-Less multiplier comprising:
a multiplication circuit configured to perform the Carry-Less multiplication; and
a parity predictor configured to predict a parity value of a result of the Carry-Less multiplication of the multiplicand data string and the multiplier data string by the multiplication circuit, the parity predictor including:
a low-order parity prediction unit configured to predict a parity value of a first data unit from lower order in a multiplication result data string representing the Carry-Less multiplication result based on a value and a parity value of a first data unit being a first data unit from lower order in each of the multiplicand data string and the multiplier data string; and
a high-order parity prediction unit configured to predict a parity value for data at a high-order p−1 bit of the multiplication result data string being data following 2q−1-th data unit from lower order in the multiplication result data string, based on a value and a parity value for a q-th data unit being a q-th data unit from lower order in each of the multiplicand data string and the multiplier data string.

18. The Carry-Less multiplier according to claim 17, wherein
the parity predictor further includes a middle-order parity prediction unit configured to predict, when the multiplicand data string and the multiplier data string are respectively a data string in which a plurality of the data units are lined up, a parity value of respective data units from second through 2q−1-th from lower order in the multiplication result data string, based on a value and a parity value of respective data units from a first data unit being a first data unit from lower order through a q-th data unit being q-th unit from lower order in each of the multiplicand data string and the multiplier data string.

19. An arithmetic operation processing apparatus comprising a Carry-Less multiplier configured to perform Carry-Less multiplication of a multiplicand data string and a multiplier data string being two data strings in which q (q is a natural number) data units being p-bit (p is a natural number equal to two or above) data, the Carry-Less multiplier comprising:
a multiplication circuit configured to perform the Carry-Less multiplication; and
a parity predictor configured to predict a parity value of a result of the Carry-Less multiplication of the multiplicand data string and the multiplier data string by the multiplication circuit, the parity predictor including:
a low-order parity prediction unit configured to predict a parity value of a first data unit from lower order in a multiplication result data string representing the Carry-Less multiplication result based on a value and a parity value of a first data unit being a first data unit from lower order in each of the multiplicand data string and the multiplier data string; and
a high-order parity prediction unit configured to predict a parity value for data at a high-order p−1 bit of the multiplication result data string being data following 2q−1-th data unit from lower order in the multiplication result data string, based on a value and a parity value for a q-th data unit being a q-th data unit from lower order in each of the multiplicand data string and the multiplier data string.

20. The arithmetic operation processing apparatus according to claim 19, wherein
the parity predictor further includes a middle-order parity prediction unit configured to predict, when the multiplicand data string and the multiplier data string are respectively a data string in which a plurality of the data units are lined up, a parity value of respective data units from second through 2q−1-th from lower order in the multiplication result data string, based on a value and a parity value of respective data units from a first data unit being a first data unit from lower order through a q-th data unit being q-th unit from lower order in each of the multiplicand data string and the multiplier data string.
